(19) United States
(12) Patent Application Publication
(10) Pub. No.: US 2021/0061821 A1
(43) Pub. Date: Mar. 4, 2021

(54) PYRROMETHENE BORON COMPLEX, COLOR CONVERSION COMPOSITION, COLOR CONVERSION FILM, LIGHT SOURCE UNIT, DISPLAY, ILLUMINATION APPARATUS, AND LIGHT-EMITTING DEVICE

(71) Applicant: Toray Industries, Inc., Tokyo (JP)

(72) Inventors: Kazuki Kobayashi, Otsu-shi, Shiga (JP); Yasunori Ichihashi, Otsu-shi, Shiga (JP)

(73) Assignee: Toray Industries, Inc., Tokyo (JP)

(21) Appl. No.: 16/963,613

(22) PCT Filed: Dec. 20, 2018
(86) PCT No.: PCT/JP2018/047120

§ 371 Date: Jul. 21, 2020

(30) Foreign Application Priority Data
Jan. 26, 2018 (JP) 2018-011165

(51) Int. Cl. C07F 5/02; H01L 33/50; H01L 33/30; G09G 3/34

(52) U.S. Cl. CPC C07F 5/02; H01L 33/502; H01L 51/5012; G09G 3/3413; H01L 33/305

(57) ABSTRACT

A pyrromethene boron complex represented by the general formula (1) is described that satisfies at least one of conditions (A) and (B) as defined. The pyrromethene boron complex is used in a color conversion composition, and a color conversion film is used in a light source unit, a display, an illumination apparatus, and a light-emitting device, where in the general

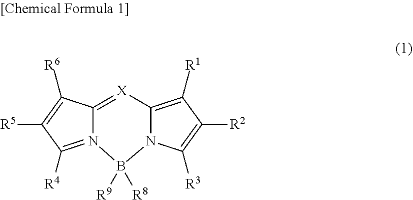

formula (1), X is C—R⁷ or N; and R¹ to R⁹ are as defined.

### CROSS REFERENCE TO RELATED APPLICATIONS

This is the U.S. National Phase application of PCT/JP2018/047120, filed Dec. 20, 2018, which claims priority to Japanese Patent Application No. 2018-011165, filed Jan. 26, 2018, the disclosures of these applications being incorporated herein by reference in their entireties for all purposes.

### FIELD OF THE INVENTION

The present invention relates to a pyrromethene boron complex, a color conversion composition, a color conversion film, a light source unit, a display, an illumination apparatus, and a light-emitting device.

### BACKGROUND OF THE INVENTION

Multicolor techniques using color conversion systems have been studied actively to expand their application to liquid crystal displays, organic EL displays, illumination apparatuses, etc. Color conversion is the conversion of an emission from an emitter into a light with a longer wavelength, and means, for example, the conversion of blue emission to green emission or red emission.

Compositions having such a color conversion function (hereinafter, referred to as the “color conversion compositions”) are formed into films and combined with, for example, a blue light source to allow the blue light source to produce three primary colors, i.e., blue, green, and red colors, thus enabling the production of white light. Full color displays can be manufactured by combining a blue light source with films having a color conversion function (hereinafter, referred to as the “color conversion films”) to form a light source unit that is a white light source, and combining such light source units with liquid crystal drive components and color filters. Furthermore, the white light source may be used as such without liquid crystal drive components, and may be applied as a white light source in, for example, LED illumination or the like.

An example challenge of liquid crystal displays is the enhancement in color reproducibility. The color reproducibility is effectively enhanced by narrowing the full width at half maximum in each of emission spectra of blue light, green light, and red light from a light source unit to increase the color purities of the blue, green, and red colors. A technique that has been proposed in order to solve this employs quantum dots of inorganic semiconductor microparticles as a component of a color conversion composition (see, for example, Patent Literature 1). This technique using quantum dots indeed realizes narrow the full width at half maximum in each of emission spectra of green and red colors and enhances the color reproducibility. On the other hand, however, quantum dots are labile to heat, and water and oxygen in the air, and are not satisfactory in durability.

Furthermore, techniques are also proposed that use, in place of quantum dots, organic light-emitting materials as components in color conversion compositions. In exemplary techniques which use organic light-emitting materials as components in color conversion compositions, the use of pyrromethene derivatives is disclosed (see, for example, Patent Literatures 1 to 5).

### PATENT LITERATURE

Patent Literature 1: Japanese Laid-open Patent Publication No. 2011-241160

Patent Literature 2: Japanese Laid-open Patent Publication No. 2014-136771

Patent Literature 3: WO 2016/108411

Patent Literature 4: Korean Laid-open Patent Publication No. 2017/0049360

Patent Literature 5: WO 2017/155297

### SUMMARY OF THE INVENTION

Unfortunately, color conversion compositions prepared using such organic light-emitting materials are still unsatisfactory from the point of view of enhancements in color reproducibility, emission efficiency and durability. In particular, techniques cannot sufficiently concurrently satisfy high efficiency emission and high durability, or techniques cannot sufficiently concurrently satisfy green emission with high color purity, and high durability.

An object of the present invention is to provide an organic light-emitting material that is suited as a color conversion material for use in displays such as liquid crystal displays, illumination apparatuses such as LED illumination, or light-emitting devices, and to concurrently satisfy enhanced color reproducibility and high durability.

To solve the problem described above and to achieve the object, a pyrromethene boron complex according to the present invention includes a compound represented by the general formula (1) below,

the pyrromethene boron complex satisfying at least one of condition (A) and condition (B) described below:

Condition (A): in the general formula (1), R1 to R6 are each a group containing no fluorine atom, at least one of R1, R3, R4, and R6 is a substituted or unsubstituted alkyl group or a substituted or unsubstituted cycloalkyl group, and R2 and R5 are each a group including no fused bicyclic or polycyclic heteroaryl group;
Condition (B): in the general formula (1), at least one of R1, R3, R4, and R6 is a substituted or unsubstituted aryl group or a substituted or unsubstituted heteroaryl group, and when X is C—R7, R7 is a group including no bicyclic or polycyclic heteroaryl group,

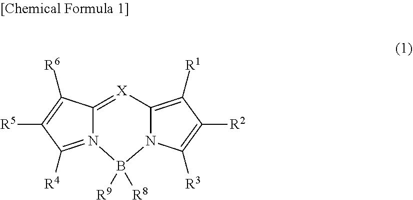

where in the general formula (1), X is C—R⁷ or N; and R¹ to R⁹ are the same as or different from one another and are each selected from the candidate group consisting of hydrogen atom, alkyl group, cycloalkyl group, heterocyclic group, alkenyl group, cycloalkenyl group, alkynyl group, hydroxy group, thiol group, alkoxy group, alkylthio group, aryl ether group, aryl thioether group, aryl group, heteroaryl group, halogen, cyano group, aldehyde group, carbonyl group, carboxy group, acyl group, ester group, amide group, carbamoyl group, amino group, nitro group, silyl group, siloxanyl group, boryl group, sulfo group, sulfonyl group, phosphine oxide group, and fused ring and aliphatic ring formed with an adjacent substituent; with the proviso that at least one of R⁸ and R⁹ is a cyano group, and R² and R⁵ are each a group selected from the groups belonging to the above-described candidate group excluding substituted or unsubstituted aryl groups and substituted or unsubstituted heteroaryl groups.

In the pyrromethene boron complex according to the present invention, the condition (A) is satisfied, and at least one of R¹ to R⁷ in the general formula (1) is an electron withdrawing group.

In the pyrromethene boron complex according to the present invention, the condition (A) is satisfied, and at least one of R¹ to R⁶ in the general formula (1) is an electron withdrawing group.

In the pyrromethene boron complex according to the present invention, the condition (A) is satisfied, and at least one of R² and R⁵ in the general formula (1) is an electron withdrawing group.

In the pyrromethene boron complex according to the present invention, the condition (A) is satisfied, and R² and R⁵ in the general formula (1) are each an electron withdrawing group.

In the pyrromethene boron complex according to the present invention, the electron withdrawing group is a substituted or unsubstituted acyl group, a substituted or unsubstituted ester group, a substituted or unsubstituted amide group, a substituted or unsubstituted sulfonyl group, or a cyano group.

In the pyrromethene boron complex according to the present invention, the condition (B) is satisfied, and R⁷ in the general formula (1) is a substituted or unsubstituted aryl group.

In the pyrromethene boron complex according to the present invention, the compound represented by the general formula (1) is a compound represented by the general formula (2) below:

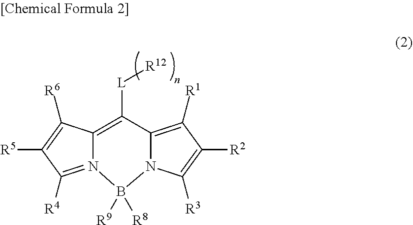

where in the general formula (2), R¹ to R⁶, R⁸, and R⁹ are the same as described in the general formula (1); R¹² is a substituted or unsubstituted aryl group, or a substituted or unsubstituted heteroaryl group; L is a substituted or unsubstituted arylene group, or a substituted or unsubstituted heteroarylene group; and n is an integer of 1 to 5.

In the pyrromethene boron complex according to the present invention, R⁸ and R⁹ in the general formula (1) are each a cyano group.

In the pyrromethene boron complex according to the present invention, R² and R⁵ in the general formula (1) are each a hydrogen atom.

In the pyrromethene boron complex according to the present invention, the compound represented by the general formula (1), when excited by excitation light, shows emission having a peak wavelength observed in a region of not less than 500 nm and not more than 580 nm.

In the pyrromethene boron complex according to the present invention, the compound represented by the general formula (1), when excited by excitation light, shows emission having a peak wavelength observed in a region of not less than 580 nm and not more than 750 nm.

A color conversion composition according to the present invention is a color conversion composition that converts incident light to light having a longer wavelength than the incident light. The color conversion composition includes: the pyrromethene boron complex according to any one of the above-described inventions; and a binder resin.

A color conversion film according to the present invention includes: a layer including the color conversion composition according to the above-described invention, or a cured product of the color conversion composition.

A light source unit according to the present invention includes: a light source, and the color conversion film according to the above-described invention.

A display according to the present invention includes: the color conversion film according to the above-described invention.

An illumination apparatus according to the present invention includes: the color conversion film according to the above-described invention.

A light-emitting device according to the present invention includes an organic layer present between an anode and a cathode, and emitting light using electric energy. The organic layer includes the pyrromethene boron complex according to any one of the above-described inventions.

In the light-emitting device according to the present invention, the organic layer includes an emission layer, and the emission layer includes the pyrromethene boron complex according to any one of the above-described inventions.

In the light-emitting device according to the present invention, the emission layer includes a host material and a dopant material, and the dopant material includes the pyrromethene boron complex according to any one of the above-described inventions.

In the light-emitting device according to the present invention, the host material includes an anthracene derivative or a naphthacene derivative.

The color conversion film and the light-emitting device which each use the pyrromethene boron complex or the color conversion composition according to the present invention concurrently satisfy emission with high color purity, and high durability, and thus can advantageously concurrently satisfy enhanced color reproducibility and high durability. The light source unit, the display, and the illumination apparatus according to the present invention each use such a color conversion film, and thus can advantageously concurrently satisfy enhanced color reproducibility and high durability.

### BRIEF DESCRIPTION OF DRAWINGS

FIG. 1 is a schematic sectional view illustrating a first example of a color conversion film according to an embodiment of the present invention.

FIG. 2 is a schematic sectional view illustrating a second example of a color conversion film according to an embodiment of the present invention.

FIG. 3 is a schematic sectional view illustrating a third example of a color conversion film according to an embodiment of the present invention.

FIG. 4 is a schematic sectional view illustrating a fourth example of a color conversion film according to an embodiment of the present invention.

### DETAILED DESCRIPTION OF EMBODIMENTS OF THE INVENTION

Hereinbelow, preferred embodiments of pyrromethene boron complexes, color conversion compositions, color conversion films, light source units, displays, illumination apparatuses and light-emitting devices according to the present invention will be described in detail. However, the present invention is not limited to those embodiments described below, and may be carried out with various modifications in accordance with purposes or use applications.

[symbol] Pyrromethene Boron Complexes

[symbol]

A pyrromethene boron complex according to an embodiment of the present invention will be described in detail. The pyrromethene boron complex according to an embodiment of the present invention is a color conversion material which constitutes a color conversion composition, a color conversion film, etc. Specifically, the pyrromethene boron complex is a compound represented by the general formula (1) below, and satisfies at least one of the condition (A) and the condition (B) described below.

Condition (A): In the general formula (1), R² to R⁶ are each a group containing no fluorine atom, at least one of R², R³, R⁴, and R⁶ is a substituted or unsubstituted alkyl group or a substituted or unsubstituted cycloalkyl group, and R² and R⁵ are each a group including no fused bicyclic or polycyclic heteroaryl group.
Condition (B): In the general formula (1), at least one of R², R³, R⁴, and R⁶ is a substituted or unsubstituted aryl group or a substituted or unsubstituted heteroaryl group, and when X is C—R⁷, R⁷ is a group including no bicyclic or polycyclic heteroaryl group.

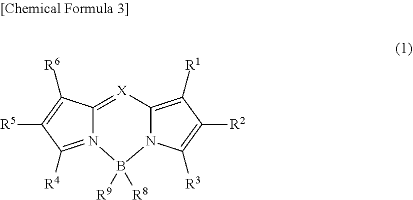

In the general formula (1), X is C—R⁷ or N. R² to R⁹ may be the same as or different from one another and are each selected from the candidate group consisting of hydrogen atom, alkyl group, cycloalkyl group, heterocyclic group, alkenyl group, cycloalkenyl group, alkynyl group, hydroxy group, thiol group, alkoxy group, alkylthio group, aryl ether group, aryl thioether group, aryl group, heteroaryl group, halogen, cyano group, aldehyde group, carbonyl group, carboxy group, acyl group, ester group, amide group, carbamoyl group, amino group, nitro group, silyl group, siloxanyl group, boryl group, sulfo group, sulfonyl group, phosphine oxide group, and fused ring and aliphatic ring formed with an adjacent substituent. Here, at least one of R⁸ and R⁹ is a cyano group, and R² and R⁵ are each a group selected from the groups belonging to the above-described candidate group excluding the substituted or unsubstituted aryl groups and the substituted or unsubstituted heteroaryl groups.

In all the groups described above, hydrogen may be deuterium. The same applies to the compounds and partial structures thereof which will be described hereinbelow. Furthermore, in the following description, for example, a substituted or unsubstituted aryl group with 6 to 40 carbon atoms is an aryl group having a total number of carbon atoms of 6 to 40 including any carbon atoms contained in a substituent on the aryl group. The same applies to other substituents having a specified number of carbon atoms.

Furthermore, in all the groups described above, the substituents in substituted groups are preferably alkyl groups, cycloalkyl groups, heterocyclic groups, alkenyl groups, cycloalkenyl groups, alkynyl groups, hydroxy groups, thiol groups, alkoxy groups, alkylthio groups, aryl ether groups, aryl thioether groups, aryl groups, heteroaryl groups, halogens, cyano groups, aldehyde groups, carbonyl groups, carboxy groups, oxycarbonyl groups, carbamoyl groups, amino groups, nitro groups, silyl groups, siloxanyl groups, boryl groups and phosphine oxide groups, and more preferably specific substituents which are described as preferable in the description of the respective substituents. Furthermore, these substituents may be further substituted with the substituents described above.

The term “unsubstituted” in “substituted or unsubstituted” means that the substituents are hydrogen atoms or deuterium atoms. The same applies when the compounds or partial structures thereof which will be described later are “substituted or unsubstituted”.

Among all the groups described above, the alkyl groups indicate, for example, saturated aliphatic hydrocarbon groups such as methyl group, ethyl group, n-propyl group, isopropyl group, n-butyl group, sec-butyl group, and tert-butyl group, and may have or may not have a substituent.

When they are substituted, the additional substituents are not particularly limited, with examples including alkyl groups, halogens, aryl groups and heteroaryl groups, and the same applies hereinbelow. Furthermore, the number of carbon atoms in the alkyl groups is not particularly limited, but, from the points of view of availability and cost, is preferably in the range of not less than 1 and not more than 20, more preferably not less than 1 and not more than 8.

The cycloalkyl groups indicate, for example, saturated alicyclic hydrocarbon groups such as cyclopropyl group, cyclohexyl group, norbornyl group, and adamantyl group, and may have or may not have a substituent. The number of carbon atoms in the alkyl group moieties is not particularly limited, but is preferably in the range of not less than 3 and not more than 20.

The heterocyclic groups indicate, for example, aliphatic rings having an atom other than carbon in the ring, such as pyran ring, piperidine ring and cyclic amides, and may have or may not have a substituent. The number of carbon atoms in the heterocyclic groups is not particularly limited, but is preferably in the range of not less than 2 and not more than 20.

The alkenyl groups indicate, for example, unsaturated aliphatic hydrocarbon groups containing a double bond, such as vinyl group, allyl group, and butadienyl group, and may have or may not have a substituent. The number of carbon atoms in the alkenyl groups is not particularly limited, but is preferably in the range of not less than 2 and not more than 20.

The cycloalkenyl groups indicate, for example, unsaturated alicyclic hydrocarbon groups containing a double bond, such as cyclopentenyl group, cyclopentadienyl group, and cyclohexenyl group, and may have or may not have a substituent.

The alkynyl groups indicate, for example, unsaturated aliphatic hydrocarbon groups containing a triple bond, such as ethynyl group, and may have or may not have a substituent. The number of carbon atoms in the alkynyl groups is not particularly limited, but is preferably in the range of not less than 2 and not more than 20.

The alkoxy groups indicate, for example, functional groups which are aliphatic hydrocarbon groups bonded through an ether bond, such as methoxy group, ethoxy group and propoxy group, and the aliphatic hydrocarbon groups may have or may not have a substituent. The number of carbon atoms in the alkoxy groups is not particularly limited, but is preferably in the range of not less than 1 and not more than 20.

The alkylthio groups are groups resulting from the substitution of alkoxy groups with a sulfur atom in place of the oxygen atom in the ether bond. The hydrocarbon groups in the alkylthio groups may have or may not have a substituent. The number of carbon atoms in the alkylthio groups is not particularly limited, but is preferably in the range of not less than 1 and not more than 20.

The aryl ether groups indicate, for example, functional groups which are aromatic hydrocarbon groups bonded through an ether bond, such as phenoxy group, and the aromatic hydrocarbon groups may have or may not have a substituent. The number of carbon atoms in the aryl ether groups is not particularly limited, but is preferably in the range of not less than 6 and not more than 40.

The aryl thioether groups are groups resulting from the substitution of aryl ether groups with a sulfur atom in place of the oxygen atom in the ether bond. The aromatic hydrocarbon groups in the aryl thioether groups may have or may not have a substituent. The number of carbon atoms in the aryl thioether groups is not particularly limited, but is preferably in the range of not less than 6 and not more than 40.

The aryl groups indicate, for example, aromatic hydrocarbon groups such as phenyl group, biphenyl group, terphenyl group, naphthyl group, fluorenyl group, benzofluorenyl group, dibenzofluorenyl group, phenanthryl group, anthracenyl group, benzophenanthryl group, benzoanthracenyl group, chrysenyl group, pyrenyl group, fluoranthenyl group, triphenylenyl group, benzofluoranthenyl group, dibenzoanthracenyl group, perylenyl group and helicenyl group. In particular, phenyl group, biphenyl group, terphenyl group, naphthyl group, fluorenyl group, phenanthryl group, anthracenyl group, pyrenyl group, fluoranthenyl group and triphenylenyl group are preferable. The aryl groups may have or may not have a substituent. The number of carbon atoms in the aryl groups is not particularly limited, but is preferably in the range of not less than 6 and not more than 40, and more preferably not less than 6 and not more than 30.

When R¹ to R⁹ are substituted or unsubstituted aryl groups, the aryl group is preferably a phenyl group, a biphenyl group, a terphenyl group, a naphthyl group, a fluorenyl group, a phenanthryl group or an anthracenyl group, more preferably a phenyl group, a biphenyl group, a terphenyl group or a naphthyl group, still more preferably a phenyl group, a biphenyl group or a terphenyl group, and particularly preferably a phenyl group.

In the case where the substituents are each further substituted with an aryl group, the aryl group is preferably a phenyl group, a biphenyl group, a terphenyl group, a naphthyl group, a fluorenyl group, a phenanthryl group or an anthracenyl group, more preferably a phenyl group, a biphenyl group, a terphenyl group or a naphthyl group, and particularly preferably a phenyl group.

The heteroaryl groups indicate, for example, cyclic aromatic groups having one or a plurality of atoms other than carbon in the ring, such as pyridyl group, furanyl group, thienyl group, quinolinyl group, isoquinolinyl group, pyrazinyl group, pyrimidyl group, pyridazinyl group, triazinyl group, naphthyridinyl group, cinnolinyl group, phthalazinyl group, quinoxalinyl group, quinazolinyl group, benzofuranyl group, benzothienyl group, indolyl group, dibenzofuranyl group, dibenzothienyl group, carbazolyl group, benzocarbazolyl group, carbolinyl group, indolocarbazolyl group, benzofurocarbazolyl group, benzothienocarbazolyl group, dihydroindenocarbazolyl group, benzoquinolinyl group, acridinyl group, dibenzoacridinyl group, benzimidazolyl group, imidazopyridyl group, benzoxazolyl group, benzothiazolyl group and phenanthrolinyl group. Here, the naphthyridinyl group indicates any of 1,5-naphthyridinyl group, 1,6-naphthyridinyl group, 1,7-naphthyridinyl group, 1,8-naphthyridinyl group, 2,6-naphthyridinyl group and 2,7-naphthyridinyl group. The heteroaryl groups may have or may not have a substituent. The number of carbon atoms in the heteroaryl groups is not particularly limited, but is preferably in the range of not less than 2 and not more than 40, and more preferably not less than 2 and not more than 30.

When R¹ to R⁹ are substituted or unsubstituted heteroaryl groups, the heteroaryl group is preferably a pyridyl group, a furanyl group, a thienyl group, a quinolinyl group, a pyrimidyl group, a triazinyl group, a benzofuranyl group, a benzothienyl group, an indolyl group, a dibenzofuranyl group, a dibenzothienyl group, a carbazolyl group, a benzimidazolyl group, an imidazopyridyl group, a benzoxazolyl group, a benzothiazolyl group or a phenanthrolinyl group, more preferably a pyridyl group, a furanyl group, a thienyl group or a quinolinyl group, and particularly preferably a pyridyl group.

In the case where the substituents are each further substituted with a heteroaryl group, the heteroaryl group is preferably a pyridyl group, a furanyl group, a thienyl group, a quinolinyl group, a pyrimidyl group, a triazinyl group, a benzofuranyl group, a benzothienyl group, an indolyl group, a dibenzofuranyl group, a dibenzothienyl group, a carbazolyl group, a benzimidazolyl group, an imidazopyridyl group, a benzoxazolyl group, a benzothiazolyl group or a phenanthrolinyl group, more preferably a pyridyl group, a furanyl group, a thienyl group or a quinolinyl group, and particularly preferably a pyridyl group.

The halogen indicates an atom selected from fluorine, chlorine, bromine, and iodine. Furthermore, the carbonyl group, the carboxy group, the oxycarbonyl group and the carbamoyl group may have or may not have a substituent. Here, examples of the substituents include alkyl groups, cycloalkyl groups, aryl groups and heteroaryl groups. The substituents may be further substituted.

The ester groups indicate, for example, functional groups such as alkyl groups, cycloalkyl groups, aryl groups and heteroaryl groups each bonded through an ester bond. The substituents may be further substituted. The number of carbon atoms in the ester groups is not particularly limited, but is preferably in the range of not less than 1 and not more than 20. More specifically, examples of the ester groups include methyl ester groups such as methoxycarbonyl group, ethyl ester groups such as ethoxycarbonyl group, propyl ester groups such as propoxycarbonyl group, butyl ester groups such as butoxycarbonyl group, isopropyl ester groups such as isopropoxymethoxycarbonyl group, hexyl ester groups such as hexyloxycarbonyl group, and phenyl ester groups such as phenoxycarbonyl group.

The amide groups indicate, for example, functional groups which are substituents such as alkyl groups, cycloalkyl groups, aryl groups and heteroaryl groups each bonded through an amide bond. The substituents may be further substituted. The number of carbon atoms in the amide groups is not particularly limited, but is preferably in the range of not less than 1 and not more than 20. More specifically, examples of the amide groups include methylamide group, ethylamide group, propylamide group, butylamide group, isopropylamide group, hexylamide group and phenylamide group.

The amino groups are substituted or unsubstituted amino groups. The amino groups may have or may not have a substituent. When they are substituted, examples of the substituents include aryl groups, heteroaryl groups, linear alkyl groups and branched alkyl groups. Preferred aryl groups and heteroaryl groups are phenyl group, naphthyl group, pyridyl group and quinolinyl group. The substituents may be further substituted. The number of carbon atoms is not particularly limited, but is preferably in the range of not less than 2 and not more than 50, more preferably not less than 6 and not more than 40, and particularly preferably not less than 6 and not more than 30.

The silyl groups indicate, for example, alkylsilyl groups such as trimethylsilyl group, triethylsilyl group, tert-butyldimethylsilyl group, propyldimethylsilyl group and vinyldimethylsilyl group, and arylsilyl groups such as phenyldimethylsilyl group, tert-butyldiphenylsilyl group, triphenylsilyl group and trinaphthylsilyl group. The substituents on silicon may be further substituted. The number of carbon atoms in the silyl groups is not particularly limited, but is preferably in the range of not less than 1 and not more than 30.

The siloxanyl groups indicate, for example, silicon compound groups having an ether bond, such as trimethylsiloxanyl group. The substituents on silicon may be further substituted. Furthermore, the boryl groups are substituted or unsubstituted boryl groups. The boryl groups may have or may not have a substituent. When they are substituted, examples of the substituents include aryl groups, heteroaryl groups, linear alkyl groups, branched alkyl groups, aryl ether groups, alkoxy groups and hydroxy groups. In particular, aryl groups and aryl ether groups are preferable.

Furthermore, the phosphine oxide groups are groups represented by —P(═O)R¹⁰R¹¹. R¹⁰ and R¹¹ are selected from the same candidate group as R¹ to R⁹.

The acyl groups indicate, for example, functional groups which are substituents such as alkyl groups, cycloalkyl groups, aryl groups and heteroaryl groups each bonded through a carbonyl bond. The substituents may be further substituted. The number of carbon atoms in the acyl groups is not particularly limited, but is preferably in the range of not less than 1 and not more than 20. More specifically, examples of the acyl groups include acetyl group, propionyl group, benzoyl group and acrylyl group.

The sulfonyl groups indicate, for example, functional groups which are substituents such as alkyl groups, cycloalkyl groups, aryl groups and heteroaryl groups each bonded through a —S(═O)₂— bond. The substituents may be further substituted.

The arylene groups indicate divalent or polyvalent groups derived from aromatic hydrocarbon groups such as benzene, naphthalene, biphenyl, terphenyl, fluorene and phenanthrene, and may have or may not have a substituent. Divalent or trivalent arylene groups are preferable. Specifically, examples of the arylene groups include phenylene group, biphenylene group and naphthylene group.

The heteroarylene groups indicate divalent or polyvalent groups which are derived from aromatic groups having one or a plurality of atoms other than carbon in the ring, such as pyridine, quinoline, pyrimidine, pyrazine, triazine, quinoxaline, quinazoline, dibenzofuran and dibenzothiophene, and may have or may not have a substituent. Divalent or trivalent heteroarylene groups are preferable. The number of carbon atoms in the heteroarylene groups is not particularly limited, but is preferably in the range of 2 to 30. Specifically, examples of the heteroarylene groups include 2,6-pyridylene group, 2,5-pyridylene group, 2,4-pyridylene group, 3,5-pyridylene group, 3,6-pyridylene group, 2,4,6-pyridylene group, 2,4-pyrimidinylene group, 2,5-pyrimidinylene group, 4,6-pyrimidinylene group, 2,4,6-pyrimidinylene group, 2,4,6-triazinylene group, 4,6-dibenzofuranylene group, 2,6-dibenzofuranylene group, 2,8-dibenzofuranylene group and 3,7-dibenzofuranylene group.

The compound represented by the general formula (1) has a pyrromethene boron complex skeleton. The pyrromethene boron complex skeleton is a rigid skeleton with high planarity. For this reason, the compound having a pyrromethene boron complex skeleton exhibits a high emission quantum yield, and the compound has a small full width at half maximum in an emission spectrum. Thus, the compound represented by the general formula (1) can achieve highly efficient color conversion and high color purity.

Furthermore, in the general formula (1), at least one of R⁸ and R⁹ is a cyano group. A color conversion composition according to an embodiment of the present invention, that is, a color conversion composition containing the compound represented by the general formula (1) as a component converts the color of light as the result of the pyrromethene boron complex contained therein being excited by excitation light and emitting a light with different wavelength from the excitation light.

If R⁸ and R⁹ in the general formula (1) are not cyano groups at the same time, repeated cycles of the above excitation and emission cause the pyrromethene boron complex in the color conversion composition to interact with oxygen and consequently the pyrromethene boron complex is oxidized and is quenched. Thus, the oxidation of the pyrromethene boron complex is a factor which deteriorates the durability of the compound represented by the general formula (1). In contrast, cyano groups have strong electron withdrawing properties, and the introduction of a cyano group as a substituent on the boron atom in the pyrromethene boron complex skeleton makes it possible to lower the electron density of the pyrromethene boron complex skeleton. As a result of this, the compound represented by the general formula (1) attains still enhanced stability against oxygen, and consequently the durability of the compound can be further enhanced.

Furthermore, in the general formula (1), it is preferable that R⁸ and R⁹ be both cyano groups. In this case, the introduction of two cyano groups on the boron atom in the pyrromethene boron complex skeleton can further lower the electron density of the pyrromethene boron complex skeleton. As a result of this, the compound represented by the general formula (1) attains a further enhancement in the stability against oxygen, and consequently the durability of the compound can be markedly enhanced.

From the foregoing, the compound represented by the general formula (1), by virtue of its having a pyrromethene boron complex skeleton and a cyano group in the molecule, can achieve highly efficient emission (color conversion), high color purity and high durability.

Furthermore, in the general formula (1), R² and R⁵ are each selected from the groups belonging to the aforementioned candidate group excluding the substituted or unsubstituted aryl groups and the substituted or unsubstituted heteroaryl groups.

In the general formula (1), the positions substituted with R² and R⁵ are positions which significantly affect the electron density of the pyrromethene boron complex skeleton. If these positions are substituted with aromatic groups, the conjugation is extended to cause a widening of the full width at half maximum in an emission spectrum. If a film containing such a compound is used as a color conversion film in a display, the color reproducibility is lowered.

Thus, R² and R⁵ in the general formula (1) are each selected from the groups belonging to the aforementioned candidate group excluding the substituted or unsubstituted aryl groups and the substituted or unsubstituted heteroaryl groups. As a result of this, the extension of the conjugation in the whole molecule of the pyrromethene boron complex skeleton can be limited, and consequently the full width at half maximum in an emission spectrum can be narrowed. When a film containing such a compound is used as a color conversion film in a liquid crystal display, the color reproducibility can be enhanced.

In the present invention, the compounds (the pyrromethene boron complexes) represented by the general formula (1) satisfy at least one of the condition (A) and the condition (B) described hereinabove. Hereinafter, the pyrromethene boron complexes which satisfy, among the condition (A) and the condition (B), only the condition (A) will be described as pyrromethene boron complexes according to an embodiment 1A, and the pyrromethene boron complexes which satisfy only the condition (B) will be described as pyrromethene boron complexes according to an embodiment 1B.

### Embodiment 1A

In the embodiment 1A, the compound represented by the general formula (1) is such that all of R¹ to R⁶ are groups containing no fluorine atom. That is, R¹ to R⁶ are each selected from the groups belonging to the aforementioned candidate group excluding groups containing a fluorine atom.

A pyrromethene boron complex, when excited by irradiation, is energetically unstable and tends to interact with other molecules. If groups which contain a fluorine atom with high electronegativity are introduced as R¹ to R⁶, the whole of the pyrromethene boron complex skeleton comes to have significant polarization, and consequently the pyrromethene boron complex shows higher interaction with other molecules. When, on the other hand, R¹ to R⁶ are groups containing no fluorine atom, the polarization of the pyrromethene boron complex skeleton is not significant. In this case, the pyrromethene boron complex is less interactive with resins and other molecules, and thus the pyrromethene boron complex does not form complexes therewith. Thus, excitation and inactivation can occur in single molecules of the pyrromethene boron complex, and the pyrromethene boron complex can maintain a high emission quantum yield.

Furthermore, in the embodiment 1A, at least one of R¹, R³, R⁴, and R⁶ in the general formula (1) is either a substituted or unsubstituted alkyl group, or a substituted or unsubstituted cycloalkyl group. A reason for this is because when at least one of R¹, R³, R⁴, and R⁶ is either of the above groups, the compound represented by the general formula (1) exhibits better thermal stability and photo stability than when R¹, R³, R⁴, and R⁶ are all hydrogen atoms.

In the embodiment 1A, in the case that at least one of R¹, R³, R⁴, and R⁶ in the general formula (1) is a substituted or unsubstituted alkyl group, or a substituted or unsubstituted cycloalkyl group, the compound represented by the general formula (1) can achieve emission with excellent color purity. In this case, the alkyl group is preferably an alkyl group having 1 to 6 carbon atoms such as a methyl group, an ethyl group, an n-propyl group, an isopropyl group, an n-butyl group, a sec-butyl group, a tert-butyl group, a pentyl group or a hexyl group. Furthermore, the cycloalkyl group is preferably a saturated alicyclic hydrocarbon group such as a cyclopropyl group, a cyclohexyl group, a norbornyl group or an adamantyl group. The cycloalkyl group may have or may not have a substituent. In the cycloalkyl group, the number of carbon atoms in the alkyl group moiety is not particularly limited, but is preferably in the range of not less than 3 and not more than 20. Furthermore, from the point of view of excellent thermal stability, the alkyl group in the embodiment 1A is preferably a methyl group, an ethyl group, an n-propyl group, an isopropyl group, an n-butyl group, a sec-butyl group, or a tert-butyl group. Furthermore, from the points of view of preventing concentration quenching and enhancing the emission quantum yield, the alkyl group is more preferably a sterically bulky tert-butyl group. Furthermore, from the points of view of easy synthesis and the availability of raw materials, a methyl group is also preferably used as the alkyl group. The alkyl group in the embodiment 1A means both a substituted or unsubstituted alkyl group, and an alkyl group moiety in a substituted or unsubstituted cycloalkyl group.

In the embodiment 1A, R², R³, R⁴, and R⁶ in the general formula (1) may be all the same as or different from one another, and are preferably each a substituted or unsubstituted alkyl group, or a substituted or unsubstituted cycloalkyl group. A reason for this is because the compound represented by the general formula (1) in the above case exhibits good solubility with respect to a binder resin or a solvent. The alkyl group in the embodiment 1A is preferably a methyl group from the points of view of easy synthesis and the availability of raw materials.

Furthermore, in the embodiment 1A, R² and R⁵ in the general formula (1) are each a group including no fused bicyclic or polycyclic heteroaryl group. A fused bicyclic or polycyclic heteroaryl group absorbs visible light. When a fused bicyclic or polycyclic heteroaryl group is excited by absorbing visible light, the conjugation in the excited state tends to have a local uneven distribution of electrons because of the fact that the skeleton thereof contains a heteroatom as a constituent. If fused bicyclic or polycyclic heteroaryl groups are present at the positions of R² and R⁵ which significantly affect the conjugation of the pyrromethene boron complex, the fused bicyclic or polycyclic heteroaryl groups absorb visible light and are excited to give rise to an uneven distribution of electrons in the fused bicyclic or polycyclic heteroaryl groups. As a result of this, electron transfer occurs between the heteroaryl groups and the pyrromethene boron complex skeleton, and consequently the electron transition within the pyrromethene boron complex skeleton is inhibited. This causes a decrease in the emission quantum yield of the pyrromethene boron complex.

When, however, R² and R⁵ are groups including no fused bicyclic or polycyclic heteroaryl groups, there is no electron transfer between the pyrromethene boron complex, and R² and R⁵, and excitation and inactivation by electron transition can occur in the pyrromethene boron complex skeleton. Thus, a high emission quantum yield that is a characteristic of pyrromethene boron complexes can be obtained.

Incidentally, the phenomenon described above in which the electron transition in the pyrromethene boron complex skeleton is inhibited occurs when the substituents contained in R² and R⁵ absorb visible light. When the substituents contained in R² and R⁵ are monocyclic heteroaryl groups, these heteroaryl groups do not absorb visible light and are not excited. Thus, no electron transfer occurs between the heteroaryl groups and the pyrromethene boron complex skeleton. Consequently, the emission quantum yield of the pyrromethene boron complex is not decreased.

Furthermore, in the embodiment 1A, it is preferable that R¹ and R⁶ in the general formula (1) be each not a fluorine-containing aryl group or a fluorine-containing alkyl group. As a result of this, the emission quantum yield of the compound (the pyrromethene boron complex) represented by the general formula (1) can be further enhanced. When a film containing such a compound is used as a color conversion film in a display, the display can attain a further enhancement in emission efficiency.

Furthermore, in the embodiment 1A, it is preferable that at least one of R¹ to R⁷ in the general formula (1) be an electron withdrawing group. In the compound represented by the general formula (1) in the embodiment 1A, the introduction of an electron withdrawing group as at least one of R¹ to R⁷ in the pyrromethene boron complex skeleton makes it possible to lower the electron density of the pyrromethene boron complex skeleton. As a result of this, the compound represented by the general formula (1) in the embodiment 1A attains enhanced stability against oxygen, and consequently the durability of the compound can be enhanced. More preferably, the compound represented by the general formula (1) in the embodiment 1A is such that at least one of R¹ to R⁶ is an electron withdrawing group.

The electron withdrawing group is an atomic group which is also called an electron accepting group and which in the organic electronic theory, attracts an electron from an atomic group substituted therewith by the inductive effect and the resonance effect. Examples of the electron withdrawing groups include those which have a positive value of substituent constant (σp (para)) of the Hammett rule. The substituent constants (σp (para)) of the Hammett rule can be quoted from KAGAKU BINRAN (Chemical Handbook), Basic Edition, 5th revised version (page II-380). Incidentally, the phenyl group is described as having a positive value of the above constant in some examples, but the phenyl group is not included in the electron withdrawing groups in the present invention.

Examples of the electron withdrawing groups include, for example, —F (σp: +0.06), —Cl (σp: +0.23), —Br (σp: +0.23), —I (σp: +0.18), —CO₂R¹³ (σp: +0.45 when R¹³ is an ethyl group), —CONH₂ (σp: +0.38), —COR¹³ (σp: +0.49 when R¹³ is a methyl group), —CF₃ (σp: +0.50), —SO₂R¹³ (σp: +0.69 when R¹³ is a methyl group) and —NO₂ (σp: +0.81). R¹³ denotes a hydrogen atom, a substituted or unsubstituted aromatic hydrocarbon group having 6 to 30 ring-forming carbon atoms, a substituted or unsubstituted heterocyclic group having 5 to 30 ring-forming atoms, a substituted or unsubstituted alkyl group having 1 to 30 carbon atoms, or a substituted or unsubstituted cycloalkyl group having 1 to 30 carbon atoms. Specific examples of these groups include those described hereinabove.

Some preferred electron withdrawing groups are substituted or unsubstituted acyl groups, substituted or unsubstituted ester groups, substituted or unsubstituted amide groups, substituted or unsubstituted sulfonyl groups, and cyano group. A reason for this is because these groups are less prone to chemical decomposition.

Some more preferred electron withdrawing groups are substituted or unsubstituted acyl groups, substituted or unsubstituted ester groups, and cyano group. A reason for this is because these groups effectively prevent concentration quenching and enhance the emission quantum yield. In particular, substituted or unsubstituted ester groups are particularly preferable as the electron withdrawing groups.

Preferred examples of R¹³ contained in the electron withdrawing groups described above include substituted or unsubstituted aromatic hydrocarbon groups having 6 to 30 ring-forming carbon atoms, substituted or unsubstituted alkyl groups having 1 to 30 carbon atoms, and substituted or unsubstituted cycloalkyl groups having 1 to 30 carbon atoms. From the point of view of solubility, substituted or unsubstituted alkyl groups having 1 to 30 carbon atoms are more preferable as the substituents (R¹³). Specifically, examples of the above alkyl groups include methyl group, ethyl group, propyl group, butyl group, hexyl group, isopropyl group, isobutyl group, sec-butyl group, and tert-butyl group. Furthermore, an ethyl group is preferably used as the alkyl group from the points of view of easy synthesis and the availability of raw materials.

In particular, the pyrromethene boron complexes (the compounds represented by the general formula (1)) according to the embodiment 1A are preferably as described in the following first to third sub-embodiments.

In the first sub-embodiment of the pyrromethene boron complexes according to the embodiment 1A, at least one of R¹ and R⁶ in the general formula (1) is preferably an electron withdrawing group. A reason for this is because this configuration further enhances the stability against oxygen of the compound represented by the general formula (1), and consequently the durability can be further enhanced.

Furthermore, in the general formula (1), it is preferable that R¹ and R⁶ be both electron withdrawing groups. A reason for this is because this configuration still further enhances the stability against oxygen of the compound represented by the general formula (1), and consequently the durability can be markedly enhanced. R¹ and R⁶ may be the same as or different from one another. Preferred examples of R¹ and R⁶ include substituted or unsubstituted acyl groups, substituted or unsubstituted ester groups, substituted or unsubstituted amide groups, substituted or unsubstituted sulfonyl groups, and cyano group.

In the second sub-embodiment of the pyrromethene boron complexes according to the embodiment 1A, it is preferable that at least one of R³ and R⁴ in the general formula (1) be an electron withdrawing group. A reason for this is because this configuration further enhances the stability against oxygen of the compound represented by the general formula (1), and consequently the durability can be further enhanced.

Furthermore, in the general formula (1), it is preferable that R³ and R⁴ be both electron withdrawing groups. A reason for this is because this configuration still further enhances the stability against oxygen of the compound represented by the general formula (1), and consequently the durability can be markedly enhanced. R³ and R⁴ may be the same as or different from one another. Preferred examples of R³ and R⁴ include substituted or unsubstituted acyl groups, substituted or unsubstituted ester groups, substituted or unsubstituted amide groups, substituted or unsubstituted sulfonyl groups, and cyano group.

In the third sub-embodiment of the pyrromethene boron complexes according to the embodiment 1A, it is more preferable that at least one of R² and R⁵ in the general formula (1) be an electron withdrawing group. The positions of R² and R⁵ in the general formula (1) are substitution positions which significantly affect the electron density of the pyrromethene boron complex skeleton. The introduction of electron withdrawing groups as R² and R⁵ makes it possible to efficiently lower the electron density of the pyrromethene boron complex skeleton. As a result of this, the compound represented by the general formula (1) attains a further enhancement in the stability against oxygen, and consequently the durability can be further enhanced.

Furthermore, in the third sub-embodiment, it is more preferable that R² and R⁵ in the general formula (1) be both electron withdrawing groups. A reason for this is because this configuration still further enhances the stability against oxygen of the compound represented by the general formula (1), and consequently the durability can be markedly enhanced.

Preferred examples of the electron withdrawing groups in the embodiment 1A described above include substituted or unsubstituted acyl groups, substituted or unsubstituted ester groups, substituted or unsubstituted amide groups, substituted or unsubstituted sulfonyl groups, and cyano group. These groups allow the electron density of the pyrromethene boron complex skeleton to be efficiently lowered. As a result of this, the compound represented by the general formula (1) attains enhanced stability against oxygen, and consequently the durability can be further enhanced. For this reason, the above groups are preferable as the electron withdrawing groups.

Specific examples of the substituted or unsubstituted acyl groups, the substituted or unsubstituted ester groups, the substituted or unsubstituted amide groups, and the substituted or unsubstituted sulfonyl groups include, for example, the general formulae (3) to (6).

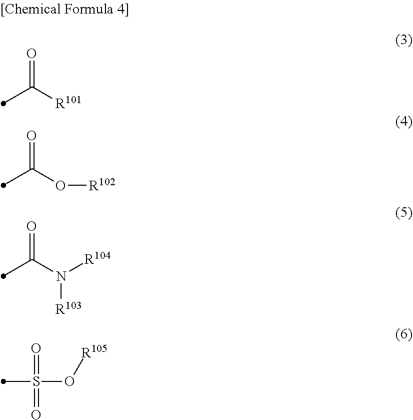

In the general formulae (3) to (6), R¹⁰¹ to R¹⁰⁵ are each independently hydrogen, a substituted or unsubstituted alkyl group, a substituted or unsubstituted cycloalkyl group, a substituted or unsubstituted aryl group, or a substituted or unsubstituted heteroaryl group.

Examples of the alkyl groups in the general formulae (3) to (6) include, for example, methyl group, ethyl group, n-propyl group, isopropyl group, n-butyl group, sec-butyl group, and tert-butyl group. Of these, ethyl group is more preferable as the alkyl group.

Examples of the cycloalkyl groups in the general formulae (3) to (6) include, for example, cyclopropyl group, cyclobutyl group, cyclopentyl group, cyclohexyl group, cycloheptyl group, norbornyl group, adamantyl group and decahydronaphthyl group.

Examples of the aryl groups in the general formulae (3) to (6) include, for example, phenyl group, biphenyl group, terphenyl group, naphthyl group, fluorenyl group, phenanthryl group, and anthracenyl group. Of these, phenyl group is more preferable as the aryl group.

Examples of the heteroaryl groups in the general formulae (3) to (6) include, for example, pyridyl group, furanyl group, thienyl group, quinolinyl group, isoquinolinyl group, pyrazinyl group, pyrimidyl group, pyridazinyl group, triazinyl group, naphthyridinyl group, cinnolinyl group, phthalazinyl group, quinoxalinyl group, quinazolinyl group, benzofuranyl group, benzothienyl group, indolyl group, dibenzofuranyl group, dibenzothienyl group, carbazolyl group, benzocarbazolyl group, carbolinyl group, indolocarbazolyl group, benzofurocarbazolyl group, benzothienocarbazolyl group, dihydroindenocarbazolyl group, benzoquinolinyl group, acridinyl group, dibenzoacridinyl group, benzimidazolyl group, imidazopyridyl group, benzoxazolyl group, benzothiazolyl group and phenanthrolinyl group.

Furthermore, from the point of view of enhancing the durability of the pyrromethene boron complex, R¹⁰¹ to R¹⁰⁵ in the general formulae (3) to (6) are preferably each a substituent represented by the general formula (7).

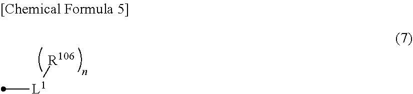

In the general formula (7), R¹⁰⁶ is an electron withdrawing group. By virtue of R¹⁰⁶ being an electron withdrawing group, the stability against oxygen is enhanced, and thus the compound (the pyrromethene boron complex) represented by the general formula (1) attains enhanced durability. Some preferred electron withdrawing groups as R¹⁰⁶ are substituted or unsubstituted acyl groups, substituted or unsubstituted ester groups, substituted or unsubstituted amide groups, substituted or unsubstituted sulfonyl groups, nitro group, silyl group, and cyano group. Cyano group is more preferable. In the general formula (7), n is an integer of 1 to 5. When n is 2 to 5, as many R¹⁰⁶ as indicated by n may be the same as or different from one another.

Furthermore, from the point of view of the photo stability of the pyrromethene boron complex, L¹ in the general formula (7) is preferably a substituted or unsubstituted arylene group, or a substituted or unsubstituted heteroarylene group. When L¹ is a substituted or unsubstituted arylene group, or a substituted or unsubstituted heteroarylene group, the aggregation of the molecules of the pyrromethene boron complex can be prevented. Consequently, the compound represented by the general formula (7) can attain enhanced durability. Specifically, preferred arylene groups are phenylene group, biphenylene group, naphthylene group and terphenylene group.

Furthermore, examples of the substituents when L¹ is substituted include, for example, substituted or unsubstituted alkyl groups, substituted or unsubstituted cycloalkyl groups, substituted or unsubstituted alkenyl groups, substituted or unsubstituted cycloalkenyl groups, substituted or unsubstituted alkynyl groups, hydroxy groups, thiol groups, alkoxy groups, substituted or unsubstituted alkylthio groups, substituted or unsubstituted aryl ether groups, substituted or unsubstituted aryl thioether groups, halogens, aldehyde groups, carbamoyl groups, amino groups, substituted or unsubstituted siloxanyl groups, substituted or unsubstituted boryl groups, and phosphine oxide groups.

Furthermore, from the point of view of enhancing the durability of the pyrromethene boron complex, it is more preferable that R¹⁰¹ to R¹⁰⁵ in the general formulae (3) to (6) be each a compound (a substituent) represented by the general formula (8).

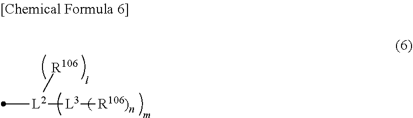

In the general formula (8), R¹⁰⁶ is the same as described in the general formula (7). L² is a substituted or unsubstituted alkylene group, a substituted or unsubstituted arylene group, or a substituted or unsubstituted heteroarylene group. L³ is a substituted or unsubstituted arylene group, or a substituted or unsubstituted heteroarylene group. Examples of the substituents when L² and L³ are substituted include, for example, substituted or unsubstituted alkyl groups, substituted or unsubstituted cycloalkyl groups, substituted or unsubstituted alkenyl groups, substituted or unsubstituted cycloalkenyl groups, substituted or unsubstituted alkynyl groups, hydroxy groups, thiol groups, alkoxy groups, substituted or unsubstituted alkylthio groups, substituted or unsubstituted aryl ether groups, substituted or unsubstituted aryl thioether groups, halogens, aldehyde groups, carbamoyl groups, amino groups, substituted or unsubstituted siloxanyl groups, substituted or unsubstituted boryl groups, and phosphine oxide groups.

Furthermore, in the general formula (8), n is an integer of 0 to 5, and m is an integer of 1 to 5. Here, the groups R¹⁰⁶ enclosed with n are independent from one another enclosed with m, and may be the same as or different from one another. When n is 2 to 5, as many R¹⁰⁶ as indicated by n may be the same as or different from one another. Furthermore, when m is 2 to 5, as many L³ as indicated by m may be the same as or different from one another. On the other hand, l is an integer of 0 to 4. When 1 is 2 to 4, as many R¹⁰⁶ as indicated by 1 may be the same as or different from one another.

From the point of view of enhancing the stability against oxygen of the compound and thereby enhancing the durability of the compound, the integers n and l in the general formula (8) preferably satisfy the mathematical expression (f1):

1≤n+l≤25 (f1)

That is, the compound represented by the general formula (8) preferably has one or more groups R¹⁰⁶ including an electron withdrawing group. This configuration can enhance the durability of the compound represented by the general formula (8). Furthermore, from the points of view of the availability of raw materials and the durability of the compound, the upper limit of n+l shown in the mathematical expression (f1) is preferably not more than 10, and more preferably not more than 8.

Furthermore, in the general formula (8), m is preferably an integer of 1 to 3. That is, the compound represented by the general formula (8) preferably has one, or two, or three groups L³-(R¹⁰⁶) n. The compound represented by the general formula (8) can attain enhanced durability by its containing one, or two, or three groups L³-(R¹⁰⁶) n including a bulky substituent or an electron withdrawing group.

Furthermore, in the general formula (8), it is preferable that 1=1 and m=2. That is, the compound represented by the general formula (8) preferably has one group R¹⁰⁶ including an electron withdrawing group, and two groups L³-(R¹⁰⁶) n including a bulky substituent or an electron withdrawing group. This configuration can further enhance the durability of the compound represented by the general formula (8). When m is 2, the two groups L³-(R¹⁰⁶) n may be the same as or different from one another.

Furthermore, in another sub-embodiment, it is preferable that in the general formula (8), 1=0 and m=2, and it is more preferable that 1=0 and m=3. That is, the compound represented by the general formula (8) preferably has two or three groups L³-(R¹⁰⁶) n including a bulky substituent or an electron withdrawing group. When, in particular, the compound represented by the general formula (8) has three groups L³-(R¹⁰⁶) n, the durability of the compound can be further enhanced. When m is 3, the three groups L³-(R¹⁰⁶) n may be the same as or different from one another.

On the other hand, L² in the general formula (8) is more preferably a compound (a substituent) represented by the general formula (9) from the point of view of enhancing the durability. That is, L² in the general formula (8) is preferably a phenylene group. The aggregation of molecules can be prevented by virtue of L² being a phenylene group. Consequently, the durability of the compound represented by the general formula (8) can be enhanced. In the compound represented by the general formula (9), R²⁰² to R²⁰⁵ are selected from R¹⁰⁶, L³-(R¹⁰⁶) n and hydrogen atom. That is, at least one of R²⁰¹ to R²⁰⁵ may be substituted with R¹⁰⁶, may be substituted with L³-(R¹⁰⁶) n, or may be a hydrogen atom (unsubstituted). R¹⁰⁶ and L³-(R¹⁰⁶)n are the same as described in the general formula (8).

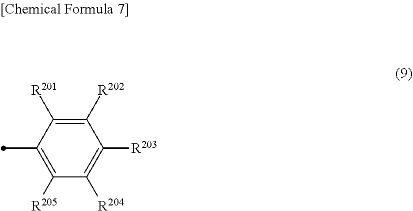

In the general formula (9), at least one of 8²⁰¹ and R²⁰⁵ is preferably L³-(R¹⁰⁶)n. By virtue of at least one of R²⁰¹ and R²⁰⁵ being substituted with L³-(R¹⁰⁶)n including a bulky substituent or an electron withdrawing group, the compound represented by the general formula (9) is less interactive with other molecules, and the aggregation of molecules can be prevented. As a result of this, the durability of the compound can be enhanced.

Furthermore, in the general formula (9), it is more preferable that R²⁰¹ and R²⁰⁵ be both L³-(R¹⁰⁶)n. By virtue of L³-(R¹⁰⁶)n which includes a bulky substituent or an electron withdrawing group being substituted as both R²⁰¹ and R²⁰⁵, the durability of the compound represented by the general formula (9) can be further enhanced. When L³-(R¹⁰⁶)n is substituted as both R²⁰¹ and R²⁰⁵, R²⁰¹ and R²⁰⁵ may be the same as or different from one another.

From the foregoing, the compound represented by the general formula (1) according to the embodiment 1A can concurrently satisfy highly efficient emission, high color purity and high durability by virtue of its containing a pyrromethene boron complex skeleton and an electron withdrawing group in the molecule. Furthermore, the compound represented by the general formula (1) according to the embodiment 1A exhibits a high emission quantum yield and shows a narrow full width at half maximum in an emission spectrum, and thus can achieve efficient color conversion and high color purity. Furthermore, the compound represented by the general formula (1) according to the embodiment 1A has appropriate substituents which are introduced at appropriate positions so as to make it possible to control various characteristics and properties such as emission efficiency, color purity, thermal stability, photo stability and dispersibility.

### Embodiment 1B

In the embodiment 1B, the general formula (1) is such that at least one of R¹, R³, R⁴, and R⁶ is a substituted or unsubstituted aryl group, or a substituted or unsubstituted heteroaryl group, and, of these, preferably a substituted or unsubstituted aryl group. In this case, the compound represented by the general formula (1) attains further enhanced photo stability. The aryl group in the embodiment 1B is preferably a phenyl group, a biphenyl group, a terphenyl group or a naphthyl group, in particular, more preferably a phenyl group or a biphenyl group, and particularly preferably a phenyl group. The heteroaryl group in the embodiment 1B is preferably a pyridyl group, a quinolinyl group or a thienyl group, in particular, more preferably a pyridyl group or a quinolinyl group, and particularly preferably a pyridyl group.

Furthermore, in the embodiment 1B, R¹, R³, R⁴, and R⁶ in the general formula (1) may be preferably all the same as or different from one another and each a substituted or unsubstituted aryl group, or a substituted or unsubstituted heteroaryl group. A reason for this is because in this case, the compound represented by the general formula (1) can attain better thermal stability and photo stability.

While some substituents offer enhancements in a plurality of properties, few substituents exhibit perfectly sufficient performance. In particular, it is difficult to concurrently satisfy high efficiency emission and high color purity. Thus, several types of substituents are introduced into the compound represented by the general formula (1) so as to allow the compound to achieve balanced properties such as emission characteristics and color purity.

When, in particular, R¹, R³, R⁴, and R⁶ may be all the same as or different from one another and are each a substituted or unsubstituted aryl group, it is preferable that the substituents introduced be of a plurality of types such as, for example, R¹≠ R⁴, R³≠ R⁶, R¹≠ R³, or R⁴≠ R⁶. Here, “≠” indicates that the groups have different structures. For example, R¹≠ R⁴ indicates that R¹ and R⁴ are groups with different structures. The introduction of a plurality of types of substituents as described above allows an aryl group which affects color purity, and an aryl group which affects emission efficiency to be contained at the same time, thus enabling delicate control.

In particular, from the point of view of enhancing the emission efficiency and the color purity in a well-balanced manner, it is preferable that R¹≠ R³, or R⁴≠ R⁶. In this case, one or more aryl groups which affect color purity may be introduced into each of the pyrrole rings on both sides of the compound represented by the general formula (1), and aryl groups which affect emission efficiency may be introduced into other positions, and both of these properties can be enhanced to the maximum. Furthermore, when R¹≠ R³, or R⁴≠ R⁶, it is more preferable that R¹ ═R⁴, and R³═R⁶ from the point of view of enhancing both heat resistance and color purity.

The aryl groups which mainly affect color purity are preferably aryl groups substituted with an electron donating group. Examples of the electron donating groups include alkyl groups and alkoxy groups. In particular, alkyl groups having 1 to 8 carbon atoms, or alkoxy groups having 1 to 8 carbon atoms are preferable, and methyl group, ethyl group, tert-butyl group and methoxy group are more preferable. From the point of view of dispersibility, tert-butyl group and methoxy group are particularly preferable; when these are used as the electron donating groups described above, it is possible to prevent the quenching of the compound represented by the general formula (1) due to the aggregation of the molecules. The position substituted with the substituent is not particularly limited, but the substituent is preferably bonded at a meta position or a para position relative to the position of bonding with the pyrromethene boron complex skeleton because the twisting of bonds needs to be small for the compound represented by the general formula (1) to attain enhanced photo stability. On the other hand, the aryl groups which mainly affect emission efficiency are preferably aryl groups having a bulky substituent such as a tert-butyl group, an adamantyl group or a methoxy group.

When R¹, R³, R⁴, and R⁶ may be all the same as or different from one another and are each a substituted or unsubstituted aryl group, these R¹, R³, R⁴, and R⁶ are preferably each selected from Ar-1 to Ar-6 illustrated below. Some preferred combinations of R¹, R³, R⁴, and R⁶ in this case are described in Table 1-1 to Table 1-11, but the combinations are not limited thereto.

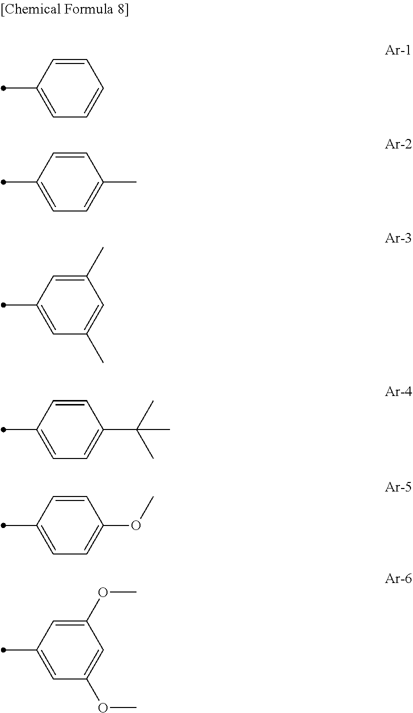

TABLE 1-1

| R1 | R3 | R4 | R6 | R1 | R3 | R4 | R6 |
|---|---|---|---|---|---|---|---|
| Ar-1 | Ar-1 | Ar-1 | Ar-1 | Ar-1 | Ar-1 | Ar-6 | Ar-1 |
| Ar-1 | Ar-1 | Ar-1 | Ar-2 | Ar-1 | Ar-1 | Ar-6 | Ar-2 |
| Ar-1 | Ar-1 | Ar-1 | Ar-3 | Ar-1 | Ar-1 | Ar-6 | Ar-3 |
| Ar-1 | Ar-1 | Ar-1 | Ar-4 | Ar-1 | Ar-1 | Ar-6 | Ar-4 |
| Ar-1 | Ar-1 | Ar-1 | Ar-5 | Ar-1 | Ar-1 | Ar-6 | Ar-5 |
| Ar-1 | Ar-1 | Ar-1 | Ar-6 | Ar-1 | Ar-1 | Ar-6 | Ar-6 |
| Ar-1 | Ar-1 | Ar-2 | Ar-1 | Ar-1 | Ar-2 | Ar-1 | Ar-2 |
| Ar-1 | Ar-1 | Ar-2 | Ar-2 | Ar-1 | Ar-2 | Ar-1 | Ar-3 |
| Ar-1 | Ar-1 | Ar-2 | Ar-3 | Ar-1 | Ar-2 | Ar-1 | Ar-4 |
| Ar-1 | Ar-1 | Ar-2 | Ar-4 | Ar-1 | Ar-2 | Ar-1 | Ar-5 |
| Ar-1 | Ar-1 | Ar-2 | Ar-5 | Ar-1 | Ar-2 | Ar-1 | Ar-6 |
| Ar-1 | Ar-1 | Ar-2 | Ar-6 | Ar-1 | Ar-2 | Ar-2 | Ar-1 |
| Ar-1 | Ar-1 | Ar-3 | Ar-1 | Ar-1 | Ar-2 | Ar-2 | Ar-2 |
| Ar-1 | Ar-1 | Ar-3 | Ar-2 | Ar-1 | Ar-2 | Ar-2 | Ar-3 |
| Ar-1 | Ar-1 | Ar-3 | Ar-3 | Ar-1 | Ar-2 | Ar-2 | Ar-4 |
| Ar-1 | Ar-1 | Ar-3 | Ar-4 | Ar-1 | Ar-2 | Ar-2 | Ar-5 |
| Ar-1 | Ar-1 | Ar-3 | Ar-5 | Ar-1 | Ar-2 | Ar-2 | Ar-6 |
| Ar-1 | Ar-1 | Ar-3 | Ar-6 | Ar-1 | Ar-2 | Ar-3 | Ar-1 |
| Ar-1 | Ar-1 | Ar-4 | Ar-1 | Ar-1 | Ar-2 | Ar-3 | Ar-2 |
| Ar-1 | Ar-1 | Ar-4 | Ar-2 | Ar-1 | Ar-2 | Ar-3 | Ar-3 |
| Ar-1 | Ar-1 | Ar-4 | Ar-3 | Ar-1 | Ar-2 | Ar-3 | Ar-4 |
| Ar-1 | Ar-1 | Ar-4 | Ar-4 | Ar-1 | Ar-2 | Ar-3 | Ar-5 |
| Ar-1 | Ar-1 | Ar-4 | Ar-5 | Ar-1 | Ar-2 | Ar-3 | Ar-6 |
| Ar-1 | Ar-1 | Ar-4 | Ar-6 | Ar-1 | Ar-2 | Ar-4 | Ar-1 |
| Ar-1 | Ar-1 | Ar-5 | Ar-1 | Ar-1 | Ar-2 | Ar-4 | Ar-2 |
| Ar-1 | Ar-1 | Ar-5 | Ar-2 | Ar-1 | Ar-2 | Ar-4 | Ar-3 |
| Ar-1 | Ar-1 | Ar-5 | Ar-3 | Ar-1 | Ar-2 | Ar-4 | Ar-4 |
| Ar-1 | Ar-1 | Ar-5 | Ar-4 | Ar-1 | Ar-2 | Ar-4 | Ar-5 |
| Ar-1 | Ar-1 | Ar-5 | Ar-5 | Ar-1 | Ar-2 | Ar-4 | Ar-6 |
| Ar-1 | Ar-1 | Ar-5 | Ar-6 | | | | |

TABLE 1-2

| R1 | R3 | R4 | R6 | R1 | R3 | R4 | R6 |
|---|---|---|---|---|---|---|---|
| Ar-1 | Ar-2 | Ar-5 | Ar-1 | Ar-1 | Ar-3 | Ar-4 | Ar-4 |
| Ar-1 | Ar-2 | Ar-5 | Ar-2 | Ar-1 | Ar-3 | Ar-4 | Ar-5 |
| Ar-1 | Ar-2 | Ar-5 | Ar-3 | Ar-1 | Ar-3 | Ar-4 | Ar-6 |
| Ar-1 | Ar-2 | Ar-5 | Ar-4 | Ar-1 | Ar-3 | Ar-5 | Ar-1 |
| Ar-1 | Ar-2 | Ar-5 | Ar-5 | Ar-1 | Ar-3 | Ar-5 | Ar-2 |
| Ar-1 | Ar-2 | Ar-5 | Ar-6 | Ar-1 | Ar-3 | Ar-5 | Ar-3 |
| Ar-1 | Ar-2 | Ar-6 | Ar-1 | Ar-1 | Ar-3 | Ar-5 | Ar-4 |
| Ar-1 | Ar-2 | Ar-6 | Ar-2 | Ar-1 | Ar-3 | Ar-5 | Ar-5 |
| Ar-1 | Ar-2 | Ar-6 | Ar-3 | Ar-1 | Ar-3 | Ar-5 | Ar-6 |
| Ar-1 | Ar-2 | Ar-6 | Ar-4 | Ar-1 | Ar-3 | Ar-6 | Ar-1 |
| Ar-1 | Ar-2 | Ar-6 | Ar-5 | Ar-1 | Ar-3 | Ar-6 | Ar-2 |
| Ar-1 | Ar-2 | Ar-6 | Ar-6 | Ar-1 | Ar-3 | Ar-6 | Ar-3 |
| Ar-1 | Ar-3 | Ar-1 | Ar-2 | Ar-1 | Ar-3 | Ar-6 | Ar-4 |
| Ar-1 | Ar-3 | Ar-1 | Ar-3 | Ar-1 | Ar-3 | Ar-6 | Ar-5 |
| Ar-1 | Ar-3 | Ar-1 | Ar-4 | Ar-1 | Ar-3 | Ar-6 | Ar-6 |
| Ar-1 | Ar-3 | Ar-1 | Ar-5 | Ar-1 | Ar-4 | Ar-1 | Ar-2 |
| Ar-1 | Ar-3 | Ar-1 | Ar-6 | Ar-1 | Ar-4 | Ar-1 | Ar-3 |
| Ar-1 | Ar-3 | Ar-2 | Ar-2 | Ar-1 | Ar-4 | Ar-1 | Ar-4 |
| Ar-1 | Ar-3 | Ar-2 | Ar-3 | Ar-1 | Ar-4 | Ar-1 | Ar-5 |
| Ar-1 | Ar-3 | Ar-2 | Ar-4 | Ar-1 | Ar-4 | Ar-1 | Ar-6 |
| Ar-1 | Ar-3 | Ar-2 | Ar-5 | Ar-1 | Ar-4 | Ar-2 | Ar-2 |
| Ar-1 | Ar-3 | Ar-2 | Ar-6 | Ar-1 | Ar-4 | Ar-2 | Ar-3 |
| Ar-1 | Ar-3 | Ar-3 | Ar-1 | Ar-1 | Ar-4 | Ar-2 | Ar-4 |
| Ar-1 | Ar-3 | Ar-3 | Ar-2 | Ar-1 | Ar-4 | Ar-2 | Ar-5 |
| Ar-1 | Ar-3 | Ar-3 | Ar-3 | Ar-1 | Ar-4 | Ar-2 | Ar-6 |
| Ar-1 | Ar-3 | Ar-3 | Ar-4 | Ar-1 | Ar-4 | Ar-3 | Ar-2 |
| Ar-1 | Ar-3 | Ar-3 | Ar-5 | Ar-1 | Ar-4 | Ar-3 | Ar-3 |
| Ar-1 | Ar-3 | Ar-3 | Ar-6 | Ar-1 | Ar-4 | Ar-3 | Ar-4 |
| Ar-1 | Ar-3 | Ar-4 | Ar-1 | Ar-1 | Ar-4 | Ar-3 | Ar-5 |
| Ar-1 | Ar-3 | Ar-4 | Ar-2 | Ar-1 | Ar-4 | Ar-3 | Ar-6 |
| Ar-1 | Ar-3 | Ar-4 | Ar-3 | | | | |

TABLE 1-3

| R1 | R3 | R4 | R6 | R1 | R3 | R4 | R6 |
|---|---|---|---|---|---|---|---|
| Ar-1 | Ar-4 | Ar-4 | Ar-1 | Ar-1 | Ar-5 | Ar-3 | Ar-4 |
| Ar-1 | Ar-4 | Ar-4 | Ar-2 | Ar-1 | Ar-5 | Ar-3 | Ar-5 |
| Ar-1 | Ar-4 | Ar-4 | Ar-3 | Ar-1 | Ar-5 | Ar-3 | Ar-6 |
| Ar-1 | Ar-4 | Ar-4 | Ar-4 | Ar-1 | Ar-5 | Ar-4 | Ar-2 |
| Ar-1 | Ar-4 | Ar-4 | Ar-5 | Ar-1 | Ar-5 | Ar-4 | Ar-3 |
| Ar-1 | Ar-4 | Ar-4 | Ar-6 | Ar-1 | Ar-5 | Ar-4 | Ar-4 |
| Ar-1 | Ar-4 | Ar-5 | Ar-1 | Ar-1 | Ar-5 | Ar-4 | Ar-5 |
| Ar-1 | Ar-4 | Ar-5 | Ar-2 | Ar-1 | Ar-5 | Ar-4 | Ar-6 |
| Ar-1 | Ar-4 | Ar-5 | Ar-3 | Ar-1 | Ar-5 | Ar-5 | Ar-1 |
| Ar-1 | Ar-4 | Ar-5 | Ar-4 | Ar-1 | Ar-5 | Ar-5 | Ar-2 |
| Ar-1 | Ar-4 | Ar-5 | Ar-5 | Ar-1 | Ar-5 | Ar-5 | Ar-3 |
| Ar-1 | Ar-4 | Ar-5 | Ar-6 | Ar-1 | Ar-5 | Ar-5 | Ar-4 |
| Ar-1 | Ar-4 | Ar-6 | Ar-1 | Ar-1 | Ar-5 | Ar-5 | Ar-5 |
| Ar-1 | Ar-4 | Ar-6 | Ar-2 | Ar-1 | Ar-5 | Ar-5 | Ar-6 |
| Ar-1 | Ar-4 | Ar-6 | Ar-3 | Ar-1 | Ar-5 | Ar-6 | Ar-1 |
| Ar-1 | Ar-4 | Ar-6 | Ar-4 | Ar-1 | Ar-5 | Ar-6 | Ar-2 |
| Ar-1 | Ar-4 | Ar-6 | Ar-5 | Ar-1 | Ar-5 | Ar-6 | Ar-3 |
| Ar-1 | Ar-4 | Ar-6 | Ar-6 | Ar-1 | Ar-5 | Ar-6 | Ar-4 |
| Ar-1 | Ar-5 | Ar-1 | Ar-2 | Ar-1 | Ar-5 | Ar-6 | Ar-5 |
| Ar-1 | Ar-5 | Ar-1 | Ar-3 | Ar-1 | Ar-5 | Ar-6 | Ar-6 |
| Ar-1 | Ar-5 | Ar-1 | Ar-4 | Ar-1 | Ar-6 | Ar-1 | Ar-2 |
| Ar-1 | Ar-5 | Ar-1 | Ar-5 | Ar-1 | Ar-6 | Ar-1 | Ar-3 |
| Ar-1 | Ar-5 | Ar-1 | Ar-6 | Ar-1 | Ar-6 | Ar-1 | Ar-4 |
| Ar-1 | Ar-5 | Ar-2 | Ar-2 | Ar-1 | Ar-6 | Ar-1 | Ar-5 |
| Ar-1 | Ar-5 | Ar-2 | Ar-3 | Ar-1 | Ar-6 | Ar-1 | Ar-6 |
| Ar-1 | Ar-5 | Ar-2 | Ar-4 | Ar-1 | Ar-6 | Ar-2 | Ar-2 |
| Ar-1 | Ar-5 | Ar-2 | Ar-5 | Ar-1 | Ar-6 | Ar-2 | Ar-3 |
| Ar-1 | Ar-5 | Ar-2 | Ar-6 | Ar-1 | Ar-6 | Ar-2 | Ar-4 |
| Ar-1 | Ar-5 | Ar-3 | Ar-2 | Ar-1 | Ar-6 | Ar-2 | Ar-5 |
| Ar-1 | Ar-5 | Ar-3 | Ar-3 | Ar-1 | Ar-6 | Ar-2 | Ar-6 |

TABLE 1-4

| R1 | R3 | R4 | R6 | R1 | R3 | R4 | R6 |
|---|---|---|---|---|---|---|---|
| Ar-1 | Ar-6 | Ar-3 | Ar-2 | Ar-2 | Ar-1 | Ar-2 | Ar-6 |
| Ar-1 | Ar-6 | Ar-3 | Ar-3 | Ar-2 | Ar-1 | Ar-3 | Ar-2 |
| Ar-1 | Ar-6 | Ar-3 | Ar-4 | Ar-2 | Ar-1 | Ar-3 | Ar-3 |
| Ar-1 | Ar-6 | Ar-3 | Ar-5 | Ar-2 | Ar-1 | Ar-3 | Ar-4 |
| Ar-1 | Ar-6 | Ar-3 | Ar-6 | Ar-2 | Ar-1 | Ar-3 | Ar-5 |
| Ar-1 | Ar-6 | Ar-4 | Ar-2 | Ar-2 | Ar-1 | Ar-3 | Ar-6 |
| Ar-1 | Ar-6 | Ar-4 | Ar-3 | Ar-2 | Ar-1 | Ar-4 | Ar-2 |
| Ar-1 | Ar-6 | Ar-4 | Ar-4 | Ar-2 | Ar-1 | Ar-4 | Ar-3 |
| Ar-1 | Ar-6 | Ar-4 | Ar-5 | Ar-2 | Ar-1 | Ar-4 | Ar-4 |
| Ar-1 | Ar-6 | Ar-4 | Ar-6 | Ar-2 | Ar-1 | Ar-4 | Ar-5 |
| Ar-1 | Ar-6 | Ar-5 | Ar-2 | Ar-2 | Ar-1 | Ar-4 | Ar-6 |
| Ar-1 | Ar-6 | Ar-5 | Ar-3 | Ar-2 | Ar-1 | Ar-5 | Ar-2 |
| Ar-1 | Ar-6 | Ar-5 | Ar-4 | Ar-2 | Ar-1 | Ar-5 | Ar-3 |
| Ar-1 | Ar-6 | Ar-5 | Ar-5 | Ar-2 | Ar-1 | Ar-5 | Ar-4 |
| Ar-1 | Ar-6 | Ar-5 | Ar-6 | Ar-2 | Ar-1 | Ar-5 | Ar-5 |
| Ar-1 | Ar-6 | Ar-6 | Ar-1 | Ar-2 | Ar-1 | Ar-5 | Ar-6 |
| Ar-1 | Ar-6 | Ar-6 | Ar-2 | Ar-2 | Ar-1 | Ar-6 | Ar-2 |
| Ar-1 | Ar-6 | Ar-6 | Ar-3 | Ar-2 | Ar-1 | Ar-6 | Ar-3 |
| Ar-1 | Ar-6 | Ar-6 | Ar-4 | Ar-2 | Ar-1 | Ar-6 | Ar-4 |
| Ar-1 | Ar-6 | Ar-6 | Ar-5 | Ar-2 | Ar-1 | Ar-6 | Ar-5 |
| Ar-1 | Ar-6 | Ar-6 | Ar-6 | Ar-2 | Ar-1 | Ar-6 | Ar-6 |
| Ar-2 | Ar-1 | Ar-1 | Ar-2 | Ar-2 | Ar-2 | Ar-1 | Ar-3 |
| Ar-2 | Ar-1 | Ar-1 | Ar-3 | Ar-2 | Ar-2 | Ar-1 | Ar-4 |
| Ar-2 | Ar-1 | Ar-1 | Ar-4 | Ar-2 | Ar-2 | Ar-1 | Ar-5 |
| Ar-2 | Ar-1 | Ar-1 | Ar-5 | Ar-2 | Ar-2 | Ar-1 | Ar-6 |
| Ar-2 | Ar-1 | Ar-1 | Ar-6 | Ar-2 | Ar-2 | Ar-2 | Ar-2 |
| Ar-2 | Ar-1 | Ar-2 | Ar-2 | Ar-2 | Ar-2 | Ar-2 | Ar-3 |
| Ar-2 | Ar-1 | Ar-2 | Ar-3 | Ar-2 | Ar-2 | Ar-2 | Ar-4 |
| Ar-2 | Ar-1 | Ar-2 | Ar-4 | Ar-2 | Ar-2 | Ar-2 | Ar-5 |
| Ar-2 | Ar-1 | Ar-2 | Ar-5 | Ar-2 | Ar-2 | Ar-2 | Ar-6 |

TABLE 1-5

| R1 | R3 | R4 | R6 | R1 | R3 | R4 | R6 |
|---|---|---|---|---|---|---|---|
| Ar-2 | Ar-2 | Ar-3 | Ar-2 | Ar-2 | Ar-3 | Ar-3 | Ar-4 |
| Ar-2 | Ar-2 | Ar-3 | Ar-3 | Ar-2 | Ar-3 | Ar-3 | Ar-5 |
| Ar-2 | Ar-2 | Ar-3 | Ar-4 | Ar-2 | Ar-3 | Ar-3 | Ar-6 |
| Ar-2 | Ar-2 | Ar-3 | Ar-5 | Ar-2 | Ar-3 | Ar-4 | Ar-2 |
| Ar-2 | Ar-2 | Ar-3 | Ar-6 | Ar-2 | Ar-3 | Ar-4 | Ar-3 |
| Ar-2 | Ar-2 | Ar-4 | Ar-2 | Ar-2 | Ar-3 | Ar-4 | Ar-4 |
| Ar-2 | Ar-2 | Ar-4 | Ar-3 | Ar-2 | Ar-3 | Ar-4 | Ar-5 |
| Ar-2 | Ar-2 | Ar-4 | Ar-4 | Ar-2 | Ar-3 | Ar-4 | Ar-6 |
| Ar-2 | Ar-2 | Ar-4 | Ar-5 | Ar-2 | Ar-3 | Ar-5 | Ar-2 |
| Ar-2 | Ar-2 | Ar-4 | Ar-6 | Ar-2 | Ar-3 | Ar-5 | Ar-3 |
| Ar-2 | Ar-2 | Ar-5 | Ar-2 | Ar-2 | Ar-3 | Ar-5 | Ar-4 |
| Ar-2 | Ar-2 | Ar-5 | Ar-3 | Ar-2 | Ar-3 | Ar-5 | Ar-5 |
| Ar-2 | Ar-2 | Ar-5 | Ar-4 | Ar-2 | Ar-3 | Ar-5 | Ar-6 |
| Ar-2 | Ar-2 | Ar-5 | Ar-5 | Ar-2 | Ar-3 | Ar-6 | Ar-2 |
| Ar-2 | Ar-2 | Ar-5 | Ar-6 | Ar-2 | Ar-3 | Ar-6 | Ar-3 |
| Ar-2 | Ar-2 | Ar-6 | Ar-2 | Ar-2 | Ar-3 | Ar-6 | Ar-4 |
| Ar-2 | Ar-2 | Ar-6 | Ar-3 | Ar-2 | Ar-3 | Ar-6 | Ar-5 |
| Ar-2 | Ar-2 | Ar-6 | Ar-4 | Ar-2 | Ar-3 | Ar-6 | Ar-6 |
| Ar-2 | Ar-2 | Ar-6 | Ar-5 | Ar-2 | Ar-4 | Ar-1 | Ar-3 |
| Ar-2 | Ar-2 | Ar-6 | Ar-6 | Ar-2 | Ar-4 | Ar-1 | Ar-4 |
| Ar-2 | Ar-3 | Ar-1 | Ar-3 | Ar-2 | Ar-4 | Ar-1 | Ar-5 |
| Ar-2 | Ar-3 | Ar-1 | Ar-4 | Ar-2 | Ar-4 | Ar-1 | Ar-6 |
| Ar-2 | Ar-3 | Ar-1 | Ar-5 | Ar-2 | Ar-4 | Ar-2 | Ar-3 |
| Ar-2 | Ar-3 | Ar-1 | Ar-6 | Ar-2 | Ar-4 | Ar-2 | Ar-4 |
| Ar-2 | Ar-3 | Ar-2 | Ar-3 | Ar-2 | Ar-4 | Ar-2 | Ar-5 |
| Ar-2 | Ar-3 | Ar-2 | Ar-4 | Ar-2 | Ar-4 | Ar-2 | Ar-6 |
| Ar-2 | Ar-3 | Ar-2 | Ar-5 | Ar-2 | Ar-4 | Ar-3 | Ar-3 |
| Ar-2 | Ar-3 | Ar-2 | Ar-6 | Ar-2 | Ar-4 | Ar-3 | Ar-4 |
| Ar-2 | Ar-3 | Ar-3 | Ar-2 | Ar-2 | Ar-4 | Ar-3 | Ar-5 |
| Ar-2 | Ar-3 | Ar-3 | Ar-3 | Ar-2 | Ar-4 | Ar-3 | Ar-6 |

TABLE 1-6

| R1 | R3 | R4 | R6 | R1 | R3 | R4 | R6 |
|---|---|---|---|---|---|---|---|
| Ar-2 | Ar-4 | Ar-4 | Ar-2 | Ar-2 | Ar-5 | Ar-5 | Ar-2 |
| Ar-2 | Ar-4 | Ar-4 | Ar-3 | Ar-2 | Ar-5 | Ar-5 | Ar-3 |
| Ar-2 | Ar-4 | Ar-4 | Ar-4 | Ar-2 | Ar-5 | Ar-5 | Ar-4 |
| Ar-2 | Ar-4 | Ar-4 | Ar-5 | Ar-2 | Ar-5 | Ar-5 | Ar-5 |
| Ar-2 | Ar-4 | Ar-4 | Ar-6 | Ar-2 | Ar-5 | Ar-5 | Ar-6 |
| Ar-2 | Ar-4 | Ar-5 | Ar-2 | Ar-2 | Ar-5 | Ar-6 | Ar-2 |
| Ar-2 | Ar-4 | Ar-5 | Ar-3 | Ar-2 | Ar-5 | Ar-6 | Ar-3 |
| Ar-2 | Ar-4 | Ar-5 | Ar-4 | Ar-2 | Ar-5 | Ar-6 | Ar-4 |
| Ar-2 | Ar-4 | Ar-5 | Ar-5 | Ar-2 | Ar-5 | Ar-6 | Ar-5 |
| Ar-2 | Ar-4 | Ar-5 | Ar-6 | Ar-2 | Ar-5 | Ar-6 | Ar-6 |
| Ar-2 | Ar-4 | Ar-6 | Ar-2 | Ar-2 | Ar-6 | Ar-1 | Ar-3 |
| Ar-2 | Ar-4 | Ar-6 | Ar-3 | Ar-2 | Ar-6 | Ar-1 | Ar-4 |
| Ar-2 | Ar-4 | Ar-6 | Ar-4 | Ar-2 | Ar-6 | Ar-1 | Ar-5 |
| Ar-2 | Ar-4 | Ar-6 | Ar-5 | Ar-2 | Ar-6 | Ar-1 | Ar-6 |
| Ar-2 | Ar-4 | Ar-6 | Ar-6 | Ar-2 | Ar-6 | Ar-2 | Ar-3 |
| Ar-2 | Ar-5 | Ar-1 | Ar-3 | Ar-2 | Ar-6 | Ar-2 | Ar-4 |
| Ar-2 | Ar-5 | Ar-1 | Ar-4 | Ar-2 | Ar-6 | Ar-2 | Ar-5 |
| Ar-2 | Ar-5 | Ar-1 | Ar-5 | Ar-2 | Ar-6 | Ar-2 | Ar-6 |
| Ar-2 | Ar-5 | Ar-1 | Ar-6 | Ar-2 | Ar-6 | Ar-3 | Ar-3 |
| Ar-2 | Ar-5 | Ar-2 | Ar-3 | Ar-2 | Ar-6 | Ar-3 | Ar-4 |
| Ar-2 | Ar-5 | Ar-2 | Ar-4 | Ar-2 | Ar-6 | Ar-3 | Ar-5 |
| Ar-2 | Ar-5 | Ar-2 | Ar-5 | Ar-2 | Ar-6 | Ar-3 | Ar-6 |
| Ar-2 | Ar-5 | Ar-2 | Ar-6 | Ar-2 | Ar-6 | Ar-4 | Ar-3 |
| Ar-2 | Ar-5 | Ar-3 | Ar-3 | Ar-2 | Ar-6 | Ar-4 | Ar-4 |
| Ar-2 | Ar-5 | Ar-3 | Ar-4 | Ar-2 | Ar-6 | Ar-4 | Ar-5 |
| Ar-2 | Ar-5 | Ar-3 | Ar-5 | Ar-2 | Ar-6 | Ar-4 | Ar-6 |
| Ar-2 | Ar-5 | Ar-3 | Ar-6 | Ar-2 | Ar-6 | Ar-5 | Ar-3 |
| Ar-2 | Ar-5 | Ar-4 | Ar-3 | Ar-2 | Ar-6 | Ar-5 | Ar-4 |
| Ar-2 | Ar-5 | Ar-4 | Ar-4 | Ar-2 | Ar-6 | Ar-5 | Ar-5 |
| Ar-2 | Ar-5 | Ar-4 | Ar-5 | Ar-2 | Ar-6 | Ar-5 | Ar-6 |
| Ar-2 | Ar-5 | Ar-4 | Ar-6 | | | | |

TABLE 1-7

| R1 | R3 | R4 | R6 | R1 | R3 | R4 | R6 |
|---|---|---|---|---|---|---|---|
| Ar-2 | Ar-6 | Ar-6 | Ar-2 | Ar-3 | Ar-2 | Ar-1 | Ar-6 |
| Ar-2 | Ar-6 | Ar-6 | Ar-3 | Ar-3 | Ar-2 | Ar-2 | Ar-3 |
| Ar-2 | Ar-6 | Ar-6 | Ar-4 | Ar-3 | Ar-2 | Ar-2 | Ar-4 |
| Ar-2 | Ar-6 | Ar-6 | Ar-5 | Ar-3 | Ar-2 | Ar-2 | Ar-5 |
| Ar-2 | Ar-6 | Ar-6 | Ar-6 | Ar-3 | Ar-2 | Ar-2 | Ar-6 |
| Ar-3 | Ar-1 | Ar-1 | Ar-3 | Ar-3 | Ar-2 | Ar-3 | Ar-3 |
| Ar-3 | Ar-1 | Ar-1 | Ar-4 | Ar-3 | Ar-2 | Ar-3 | Ar-4 |
| Ar-3 | Ar-1 | Ar-1 | Ar-5 | Ar-3 | Ar-2 | Ar-3 | Ar-5 |
| Ar-3 | Ar-1 | Ar-1 | Ar-6 | Ar-3 | Ar-2 | Ar-3 | Ar-6 |
| Ar-3 | Ar-1 | Ar-2 | Ar-3 | Ar-3 | Ar-2 | Ar-4 | Ar-3 |
| Ar-3 | Ar-1 | Ar-2 | Ar-4 | Ar-3 | Ar-2 | Ar-4 | Ar-4 |
| Ar-3 | Ar-1 | Ar-2 | Ar-5 | Ar-3 | Ar-2 | Ar-4 | Ar-5 |
| Ar-3 | Ar-1 | Ar-2 | Ar-6 | Ar-3 | Ar-2 | Ar-4 | Ar-6 |
| Ar-3 | Ar-1 | Ar-3 | Ar-3 | Ar-3 | Ar-2 | Ar-5 | Ar-3 |
| Ar-3 | Ar-1 | Ar-3 | Ar-4 | Ar-3 | Ar-2 | Ar-5 | Ar-4 |
| Ar-3 | Ar-1 | Ar-3 | Ar-5 | Ar-3 | Ar-2 | Ar-5 | Ar-5 |
| Ar-3 | Ar-1 | Ar-3 | Ar-6 | Ar-3 | Ar-2 | Ar-5 | Ar-6 |
| Ar-3 | Ar-1 | Ar-4 | Ar-3 | Ar-3 | Ar-2 | Ar-6 | Ar-3 |
| Ar-3 | Ar-1 | Ar-4 | Ar-4 | Ar-3 | Ar-2 | Ar-6 | Ar-4 |
| Ar-3 | Ar-1 | Ar-4 | Ar-5 | Ar-3 | Ar-2 | Ar-6 | Ar-5 |
| Ar-3 | Ar-1 | Ar-4 | Ar-6 | Ar-3 | Ar-2 | Ar-6 | Ar-6 |
| Ar-3 | Ar-1 | Ar-5 | Ar-3 | Ar-3 | Ar-3 | Ar-1 | Ar-4 |
| Ar-3 | Ar-1 | Ar-5 | Ar-4 | Ar-3 | Ar-3 | Ar-1 | Ar-5 |
| Ar-3 | Ar-1 | Ar-5 | Ar-5 | Ar-3 | Ar-3 | Ar-1 | Ar-6 |
| Ar-3 | Ar-1 | Ar-5 | Ar-6 | Ar-3 | Ar-3 | Ar-2 | Ar-4 |
| Ar-3 | Ar-1 | Ar-6 | Ar-3 | Ar-3 | Ar-3 | Ar-2 | Ar-5 |
| Ar-3 | Ar-1 | Ar-6 | Ar-4 | Ar-3 | Ar-3 | Ar-2 | Ar-6 |
| Ar-3 | Ar-1 | Ar-6 | Ar-5 | Ar-3 | Ar-3 | Ar-3 | Ar-3 |
| Ar-3 | Ar-1 | Ar-6 | Ar-6 | Ar-3 | Ar-3 | Ar-3 | Ar-4 |
| Ar-3 | Ar-2 | Ar-1 | Ar-4 | Ar-3 | Ar-3 | Ar-3 | Ar-5 |
| Ar-3 | Ar-2 | Ar-1 | Ar-5 | | | | |

TABLE 1-8

| R1 | R3 | R4 | R6 | R1 | R3 | R4 | R6 |
|---|---|---|---|---|---|---|---|
| Ar-3 | Ar-3 | Ar-3 | Ar-6 | Ar-3 | Ar-4 | Ar-6 | Ar-3 |
| Ar-3 | Ar-3 | Ar-4 | Ar-3 | Ar-3 | Ar-4 | Ar-6 | Ar-4 |
| Ar-3 | Ar-3 | Ar-4 | Ar-4 | Ar-3 | Ar-4 | Ar-6 | Ar-5 |
| Ar-3 | Ar-3 | Ar-4 | Ar-5 | Ar-3 | Ar-4 | Ar-6 | Ar-6 |
| Ar-3 | Ar-3 | Ar-4 | Ar-6 | Ar-3 | Ar-5 | Ar-1 | Ar-4 |
| Ar-3 | Ar-3 | Ar-5 | Ar-3 | Ar-3 | Ar-5 | Ar-1 | Ar-5 |
| Ar-3 | Ar-3 | Ar-5 | Ar-4 | Ar-3 | Ar-5 | Ar-1 | Ar-6 |
| Ar-3 | Ar-3 | Ar-5 | Ar-5 | Ar-3 | Ar-5 | Ar-2 | Ar-4 |
| Ar-3 | Ar-3 | Ar-5 | Ar-6 | Ar-3 | Ar-5 | Ar-2 | Ar-5 |
| Ar-3 | Ar-3 | Ar-6 | Ar-3 | Ar-3 | Ar-5 | Ar-2 | Ar-6 |
| Ar-3 | Ar-3 | Ar-6 | Ar-4 | Ar-3 | Ar-5 | Ar-3 | Ar-4 |
| Ar-3 | Ar-3 | Ar-6 | Ar-5 | Ar-3 | Ar-5 | Ar-3 | Ar-5 |
| Ar-3 | Ar-3 | Ar-6 | Ar-6 | Ar-3 | Ar-5 | Ar-3 | Ar-6 |
| Ar-3 | Ar-4 | Ar-1 | Ar-4 | Ar-3 | Ar-5 | Ar-4 | Ar-4 |
| Ar-3 | Ar-4 | Ar-1 | Ar-5 | Ar-3 | Ar-5 | Ar-4 | Ar-5 |
| Ar-3 | Ar-4 | Ar-1 | Ar-6 | Ar-3 | Ar-5 | Ar-4 | Ar-6 |
| Ar-3 | Ar-4 | Ar-2 | Ar-4 | Ar-3 | Ar-5 | Ar-5 | Ar-3 |
| Ar-3 | Ar-4 | Ar-2 | Ar-5 | Ar-3 | Ar-5 | Ar-5 | Ar-4 |
| Ar-3 | Ar-4 | Ar-2 | Ar-6 | Ar-3 | Ar-5 | Ar-5 | Ar-5 |
| Ar-3 | Ar-4 | Ar-3 | Ar-4 | Ar-3 | Ar-5 | Ar-5 | Ar-6 |
| Ar-3 | Ar-4 | Ar-3 | Ar-5 | Ar-3 | Ar-5 | Ar-6 | Ar-3 |
| Ar-3 | Ar-4 | Ar-3 | Ar-6 | Ar-3 | Ar-5 | Ar-6 | Ar-4 |
| Ar-3 | Ar-4 | Ar-4 | Ar-3 | Ar-3 | Ar-5 | Ar-6 | Ar-5 |
| Ar-3 | Ar-4 | Ar-4 | Ar-4 | Ar-3 | Ar-5 | Ar-6 | Ar-6 |
| Ar-3 | Ar-4 | Ar-4 | Ar-5 | Ar-3 | Ar-6 | Ar-1 | Ar-4 |
| Ar-3 | Ar-4 | Ar-4 | Ar-6 | Ar-3 | Ar-6 | Ar-1 | Ar-5 |
| Ar-3 | Ar-4 | Ar-5 | Ar-3 | Ar-3 | Ar-6 | Ar-1 | Ar-6 |
| Ar-3 | Ar-4 | Ar-5 | Ar-4 | Ar-3 | Ar-6 | Ar-2 | Ar-4 |
| Ar-3 | Ar-4 | Ar-5 | Ar-5 | Ar-3 | Ar-6 | Ar-2 | Ar-5 |
| Ar-3 | Ar-4 | Ar-5 | Ar-6 | Ar-3 | Ar-6 | Ar-2 | Ar-6 |

TABLE 1-9

| R1 | R3 | R4 | R6 | R1 | R3 | R4 | R6 |
|---|---|---|---|---|---|---|---|
| Ar-3 | Ar-6 | Ar-3 | Ar-4 | Ar-4 | Ar-2 | Ar-1 | Ar-5 |
| Ar-3 | Ar-6 | Ar-3 | Ar-5 | Ar-4 | Ar-2 | Ar-1 | Ar-6 |
| Ar-3 | Ar-6 | Ar-3 | Ar-6 | Ar-4 | Ar-2 | Ar-2 | Ar-4 |
| Ar-3 | Ar-6 | Ar-4 | Ar-4 | Ar-4 | Ar-2 | Ar-2 | Ar-5 |
| Ar-3 | Ar-6 | Ar-4 | Ar-5 | Ar-4 | Ar-2 | Ar-2 | Ar-6 |
| Ar-3 | Ar-6 | Ar-4 | Ar-6 | Ar-4 | Ar-2 | Ar-3 | Ar-4 |
| Ar-3 | Ar-6 | Ar-5 | Ar-4 | Ar-4 | Ar-2 | Ar-3 | Ar-5 |
| Ar-3 | Ar-6 | Ar-5 | Ar-5 | Ar-4 | Ar-2 | Ar-3 | Ar-6 |
| Ar-3 | Ar-6 | Ar-5 | Ar-6 | Ar-4 | Ar-2 | Ar-4 | Ar-4 |
| Ar-3 | Ar-6 | Ar-6 | Ar-3 | Ar-4 | Ar-2 | Ar-4 | Ar-5 |
| Ar-3 | Ar-6 | Ar-6 | Ar-4 | Ar-4 | Ar-2 | Ar-4 | Ar-6 |
| Ar-3 | Ar-6 | Ar-6 | Ar-5 | Ar-4 | Ar-2 | Ar-5 | Ar-4 |
| Ar-3 | Ar-6 | Ar-6 | Ar-6 | Ar-4 | Ar-2 | Ar-5 | Ar-5 |
| Ar-4 | Ar-1 | Ar-1 | Ar-4 | Ar-4 | Ar-2 | Ar-5 | Ar-6 |
| Ar-4 | Ar-1 | Ar-1 | Ar-5 | Ar-4 | Ar-2 | Ar-6 | Ar-4 |
| Ar-4 | Ar-1 | Ar-1 | Ar-6 | Ar-4 | Ar-2 | Ar-6 | Ar-5 |
| Ar-4 | Ar-1 | Ar-2 | Ar-4 | Ar-4 | Ar-2 | Ar-6 | Ar-6 |
| Ar-4 | Ar-1 | Ar-2 | Ar-5 | Ar-4 | Ar-3 | Ar-1 | Ar-5 |
| Ar-4 | Ar-1 | Ar-2 | Ar-6 | Ar-4 | Ar-3 | Ar-1 | Ar-6 |
| Ar-4 | Ar-1 | Ar-3 | Ar-4 | Ar-4 | Ar-3 | Ar-2 | Ar-5 |
| Ar-4 | Ar-1 | Ar-3 | Ar-5 | Ar-4 | Ar-3 | Ar-2 | Ar-6 |
| Ar-4 | Ar-1 | Ar-3 | Ar-6 | Ar-4 | Ar-3 | Ar-3 | Ar-4 |
| Ar-4 | Ar-1 | Ar-4 | Ar-4 | Ar-4 | Ar-3 | Ar-3 | Ar-5 |
| Ar-4 | Ar-1 | Ar-4 | Ar-5 | Ar-4 | Ar-3 | Ar-3 | Ar-6 |
| Ar-4 | Ar-1 | Ar-4 | Ar-6 | Ar-4 | Ar-3 | Ar-4 | Ar-4 |
| Ar-4 | Ar-1 | Ar-5 | Ar-4 | Ar-4 | Ar-3 | Ar-4 | Ar-5 |
| Ar-4 | Ar-1 | Ar-5 | Ar-5 | Ar-4 | Ar-3 | Ar-4 | Ar-6 |
| Ar-4 | Ar-1 | Ar-5 | Ar-6 | Ar-4 | Ar-3 | Ar-5 | Ar-4 |
| Ar-4 | Ar-1 | Ar-6 | Ar-4 | Ar-4 | Ar-3 | Ar-5 | Ar-5 |
| Ar-4 | Ar-1 | Ar-6 | Ar-5 | Ar-4 | Ar-3 | Ar-5 | Ar-6 |
| Ar-4 | Ar-1 | Ar-6 | Ar-6 | | | | |

TABLE 1-10

| R1 | R3 | R4 | R6 | R1 | R3 | R4 | R6 |
|---|---|---|---|---|---|---|---|
| Ar-4 | Ar-3 | Ar-6 | Ar-4 | Ar-4 | Ar-5 | Ar-6 | Ar-6 |
| Ar-4 | Ar-3 | Ar-6 | Ar-5 | Ar-4 | Ar-6 | Ar-1 | Ar-5 |
| Ar-4 | Ar-3 | Ar-6 | Ar-6 | Ar-4 | Ar-6 | Ar-1 | Ar-6 |
| Ar-4 | Ar-4 | Ar-1 | Ar-5 | Ar-4 | Ar-6 | Ar-2 | Ar-5 |
| Ar-4 | Ar-4 | Ar-1 | Ar-6 | Ar-4 | Ar-6 | Ar-2 | Ar-6 |
| Ar-4 | Ar-4 | Ar-2 | Ar-5 | Ar-4 | Ar-6 | Ar-3 | Ar-5 |
| Ar-4 | Ar-4 | Ar-2 | Ar-6 | Ar-4 | Ar-6 | Ar-3 | Ar-6 |
| Ar-4 | Ar-4 | Ar-3 | Ar-5 | Ar-4 | Ar-6 | Ar-4 | Ar-5 |
| Ar-4 | Ar-4 | Ar-3 | Ar-6 | Ar-4 | Ar-6 | Ar-4 | Ar-6 |
| Ar-4 | Ar-4 | Ar-4 | Ar-4 | Ar-4 | Ar-6 | Ar-5 | Ar-5 |
| Ar-4 | Ar-4 | Ar-4 | Ar-5 | Ar-4 | Ar-6 | Ar-5 | Ar-6 |
| Ar-4 | Ar-4 | Ar-4 | Ar-6 | Ar-4 | Ar-6 | Ar-6 | Ar-4 |
| Ar-4 | Ar-4 | Ar-5 | Ar-4 | Ar-4 | Ar-6 | Ar-6 | Ar-5 |
| Ar-4 | Ar-4 | Ar-5 | Ar-5 | Ar-4 | Ar-6 | Ar-6 | Ar-6 |
| Ar-4 | Ar-4 | Ar-5 | Ar-6 | Ar-5 | Ar-1 | Ar-1 | Ar-5 |
| Ar-4 | Ar-4 | Ar-6 | Ar-4 | Ar-5 | Ar-1 | Ar-1 | Ar-6 |
| Ar-4 | Ar-4 | Ar-6 | Ar-5 | Ar-5 | Ar-1 | Ar-2 | Ar-5 |
| Ar-4 | Ar-4 | Ar-6 | Ar-6 | Ar-5 | Ar-1 | Ar-2 | Ar-6 |
| Ar-4 | Ar-5 | Ar-1 | Ar-5 | Ar-5 | Ar-1 | Ar-3 | Ar-5 |
| Ar-4 | Ar-5 | Ar-1 | Ar-6 | Ar-5 | Ar-1 | Ar-3 | Ar-6 |
| Ar-4 | Ar-5 | Ar-2 | Ar-5 | Ar-5 | Ar-1 | Ar-4 | Ar-5 |
| Ar-4 | Ar-5 | Ar-2 | Ar-6 | Ar-5 | Ar-1 | Ar-4 | Ar-6 |
| Ar-4 | Ar-5 | Ar-3 | Ar-5 | Ar-5 | Ar-1 | Ar-5 | Ar-5 |
| Ar-4 | Ar-5 | Ar-3 | Ar-6 | Ar-5 | Ar-1 | Ar-5 | Ar-6 |
| Ar-4 | Ar-5 | Ar-4 | Ar-5 | Ar-5 | Ar-1 | Ar-6 | Ar-5 |
| Ar-4 | Ar-5 | Ar-4 | Ar-6 | Ar-5 | Ar-1 | Ar-6 | Ar-6 |
| Ar-4 | Ar-5 | Ar-5 | Ar-4 | Ar-5 | Ar-2 | Ar-1 | Ar-6 |
| Ar-4 | Ar-5 | Ar-5 | Ar-5 | Ar-5 | Ar-2 | Ar-2 | Ar-5 |
| Ar-4 | Ar-5 | Ar-5 | Ar-6 | Ar-5 | Ar-2 | Ar-2 | Ar-6 |
| Ar-4 | Ar-5 | Ar-6 | Ar-4 | Ar-5 | Ar-2 | Ar-3 | Ar-5 |
| Ar-4 | Ar-5 | Ar-6 | Ar-5 | Ar-5 | Ar-2 | Ar-3 | Ar-6 |

TABLE 1-11

| R1 | R3 | R4 | R6 | R1 | R3 | R4 | R6 |
|---|---|---|---|---|---|---|---|
| Ar-5 | Ar-2 | Ar-4 | Ar-5 | Ar-5 | Ar-5 | Ar-6 | Ar-5 |
| Ar-5 | Ar-2 | Ar-4 | Ar-6 | Ar-5 | Ar-5 | Ar-6 | Ar-6 |
| Ar-5 | Ar-2 | Ar-5 | Ar-5 | Ar-5 | Ar-6 | Ar-1 | Ar-6 |
| Ar-5 | Ar-2 | Ar-5 | Ar-6 | Ar-5 | Ar-6 | Ar-2 | Ar-6 |
| Ar-5 | Ar-2 | Ar-6 | Ar-5 | Ar-5 | Ar-6 | Ar-3 | Ar-6 |
| Ar-5 | Ar-2 | Ar-6 | Ar-6 | Ar-5 | Ar-6 | Ar-4 | Ar-6 |
| Ar-5 | Ar-3 | Ar-1 | Ar-6 | Ar-5 | Ar-6 | Ar-5 | Ar-6 |
| Ar-5 | Ar-3 | Ar-2 | Ar-6 | Ar-5 | Ar-6 | Ar-6 | Ar-5 |
| Ar-5 | Ar-3 | Ar-3 | Ar-5 | Ar-5 | Ar-6 | Ar-6 | Ar-6 |
| Ar-5 | Ar-3 | Ar-3 | Ar-6 | Ar-6 | Ar-1 | Ar-1 | Ar-6 |
| Ar-5 | Ar-3 | Ar-4 | Ar-5 | Ar-6 | Ar-1 | Ar-2 | Ar-6 |
| Ar-5 | Ar-3 | Ar-4 | Ar-6 | Ar-6 | Ar-1 | Ar-3 | Ar-6 |
| Ar-5 | Ar-3 | Ar-5 | Ar-5 | Ar-6 | Ar-1 | Ar-4 | Ar-6 |
| Ar-5 | Ar-3 | Ar-5 | Ar-6 | Ar-6 | Ar-1 | Ar-5 | Ar-6 |
| Ar-5 | Ar-3 | Ar-6 | Ar-5 | Ar-6 | Ar-1 | Ar-6 | Ar-6 |
| Ar-5 | Ar-3 | Ar-6 | Ar-6 | Ar-6 | Ar-2 | Ar-2 | Ar-6 |
| Ar-5 | Ar-4 | Ar-1 | Ar-6 | Ar-6 | Ar-2 | Ar-3 | Ar-6 |
| Ar-5 | Ar-4 | Ar-2 | Ar-6 | Ar-6 | Ar-2 | Ar-4 | Ar-6 |
| Ar-5 | Ar-4 | Ar-3 | Ar-6 | Ar-6 | Ar-2 | Ar-5 | Ar-6 |
| Ar-5 | Ar-4 | Ar-4 | Ar-5 | Ar-6 | Ar-2 | Ar-6 | Ar-6 |
| Ar-5 | Ar-4 | Ar-4 | Ar-6 | Ar-6 | Ar-3 | Ar-3 | Ar-6 |
| Ar-5 | Ar-4 | Ar-5 | Ar-5 | Ar-6 | Ar-3 | Ar-4 | Ar-6 |
| Ar-5 | Ar-4 | Ar-5 | Ar-6 | Ar-6 | Ar-3 | Ar-5 | Ar-6 |
| Ar-5 | Ar-4 | Ar-6 | Ar-5 | Ar-6 | Ar-3 | Ar-6 | Ar-6 |
| Ar-5 | Ar-4 | Ar-6 | Ar-6 | Ar-6 | Ar-4 | Ar-4 | Ar-6 |
| Ar-5 | Ar-5 | Ar-1 | Ar-6 | Ar-6 | Ar-4 | Ar-5 | Ar-6 |
| Ar-5 | Ar-5 | Ar-2 | Ar-6 | Ar-6 | Ar-4 | Ar-6 | Ar-6 |
| Ar-5 | Ar-5 | Ar-3 | Ar-6 | Ar-6 | Ar-5 | Ar-5 | Ar-6 |
| Ar-5 | Ar-5 | Ar-4 | Ar-6 | Ar-6 | Ar-5 | Ar-6 | Ar-6 |
| Ar-5 | Ar-5 | Ar-5 | Ar-5 | Ar-6 | Ar-6 | Ar-6 | Ar-6 |
| Ar-5 | Ar-5 | Ar-5 | Ar-6 | | | | |

Furthermore, in the embodiment 1B, when X in the general formula (1) is C—R⁷, R⁷ is a group including no fused bicyclic or polycyclic heteroaryl group. A fused bicyclic or polycyclic heteroaryl group absorbs visible light. When a fused bicyclic or polycyclic heteroaryl group is excited by absorbing visible light, the conjugation in the excited state tends to have a local uneven distribution of electrons because of the fact that the skeleton thereof contains a heteroatom as a constituent. In particular, electron transfer occurs easily between non planar parts of the pyrromethene boron complex. If, however, a fused bicyclic or polycyclic heteroaryl group is present at the position of R⁷ that is a non planar part of the pyrromethene boron complex, the fused bicyclic or polycyclic heteroaryl group absorbs visible light and is excited to give rise to an uneven distribution of electrons in the fused bicyclic or polycyclic heteroaryl group. As a result of this, electron transfer occurs between the heteroaryl group and the pyrromethene boron complex skeleton, and consequently the electron transition within the pyrromethene boron complex skeleton is inhibited. This causes a decrease in the emission quantum yield of the pyrromethene boron complex.

When, in contrast, X is C—R⁷ and R⁷ is a group including no fused bicyclic or polycyclic heteroaryl group, there is no electron transfer between the pyrromethene boron complex and R⁷, and excitation and inactivation by electron transition can occur in the pyrromethene boron complex skeleton. Thus, a high emission quantum yield that is a characteristic of pyrromethene boron complexes can be obtained. For example, R⁷ is preferably a substituted or unsubstituted aryl group.

Incidentally, the phenomenon described above in which the electron transition in the pyrromethene boron complex skeleton is inhibited is a phenomenon which occurs when the substituent contained in R⁷ absorbs visible light and electron transfer occurs between the substituent and the pyrromethene boron complex skeleton. When the substituent contained in R⁷ is a monocyclic heteroaryl group, the heteroaryl group does not absorb visible light and is not excited. Thus, no electron transfer occurs between the heteroaryl group and the pyrromethene boron complex skeleton.

### Embodiment 1C

Next, pyrromethene boron complexes according to an embodiment 1C of the present invention will be described. The pyrromethene boron complex according to the embodiment 1C is a color conversion material which is suited for emission diodes (OLED) and organic EL using organic substances as light-emitting materials, and satisfies at least one of the condition (A) and the condition (B) described hereinabove.

For example, in the embodiment 1C, at least one of R² and R⁵ in the general formula (1) is preferably a hydrogen atom, an alkyl group, a cycloalkyl group or a halogen. When at least one of R² and R⁵ is a hydrogen atom, an alkyl group, a cycloalkyl group or a halogen, the compound represented by the general formula (1) concurrently exhibits electrochemical stability, good sublimability and good deposition stability. Thus, when the compound represented by the general formula (1) according to the embodiment 1C is used in an organic thin film light-emitting device, it is possible to obtain an organic thin film light-emitting device which concurrently satisfies high efficiency emission, low driving voltage and durability. Furthermore, R² and R⁵ are preferably both any of a hydrogen atom, an alkyl group, a cycloalkyl group and a halogen because the compound represented by the general formula (1) attains enhanced electrochemical stability.

Furthermore, in the embodiment 1C, it is preferable that at least one of R² and R⁵ in the general formula (1) be a hydrogen atom or an alkyl group. When at least one of R² and R⁵ is a hydrogen atom or an alkyl group, the compound represented by the general formula (1) attains enhancements in sublimability and deposition stability. Thus, when the compound represented by the general formula (1) according to the embodiment 1C is used in an organic thin film light-emitting device, the emission efficiency is enhanced. Furthermore, R² and R⁵ are preferably each a hydrogen atom or an alkyl group because the compound represented by the general formula (1) attains further enhancements in sublimability.

Furthermore, in the embodiment 1C, it is preferable that at least one of R² and R⁵ in the general formula (1) be a hydrogen atom. When at least one of R² and R⁵ is a hydrogen atom, the compound represented by the general formula (1) attains further enhancements in sublimability. Thus, when the compound represented by the general formula (1) according to the embodiment 1C is used in an organic thin film light-emitting device, the emission efficiency is further enhanced. Furthermore, R² and R⁵ are particularly preferably each a hydrogen atom because the compound represented by the general formula (1) attains still further enhancements in sublimability.

Hereinbelow, characteristics which are common to the compounds represented by the general formula (1) according to all the embodiments in the present invention will be described.

When X in the general formula (1) is C—R⁷, R⁷ is, from the points of view of thermal stability and photo stability, preferably selected from groups other than hydroxy group, thiol group, alkoxy groups, alkylthio groups, aryl ether groups and aryl thioether groups. These substituents contain an oxygen atom or a sulfur atom. Substituents containing an oxygen atom or a sulfur atom have a high acidity and are easily detached from molecules to which they substitute. If the compound represented by the general formula (1) is substituted with such a high acidity substituent at the position of R⁷, the substituent is detached from the pyrromethene boron complex.

Consequently, the compound represented by the general formula (1) exhibits low thermal stability and photo stability. When, on the other hand, R⁷ is other than those groups containing the above substituents, the substituent substituted at R⁷ is not detached from the pyrromethene boron complex skeleton. In this case, the compound represented by the general formula (1) advantageously exhibits high thermal stability and photo stability.

Furthermore, when X in the general formula (1) is C—R⁷, R⁷ is, from the point of view of durability, preferably any of a substituted or unsubstituted alkyl group, a substituted or unsubstituted cycloalkyl group, a substituted or unsubstituted aryl group, or a substituted or unsubstituted heteroaryl group.

From the point of view of photo stability, R⁷ is preferably a substituted or unsubstituted aryl group. Specifically, R⁷ is preferably a substituted or unsubstituted phenyl group, a substituted or unsubstituted biphenyl group, a substituted or unsubstituted terphenyl group, or a substituted or unsubstituted naphthyl group, and more preferably a substituted or unsubstituted phenyl group, a substituted or unsubstituted biphenyl group, or a substituted or unsubstituted terphenyl group.

Furthermore, from the points of view of enhancing the compatibility with solvents and enhancing the emission efficiency, the substituent in the case where R⁷ is substituted is preferably a substituted or unsubstituted alkyl group, or a substituted or unsubstituted alkoxy group, and more preferably a methyl group, an ethyl group, an isopropyl group, a tert-butyl group or a methoxy group. From the point of view of dispersibility, tert-butyl group and methoxy group are particularly preferable. A reason for this is because quenching due to the aggregation of molecules can be prevented.

Particularly preferred examples of R⁷ include substituted or unsubstituted phenyl groups. Specific examples include phenyl group, 2-tolyl group, 3-tolyl group, 4-tolyl group, 2-methoxyphenyl group, 3-methoxyphenyl group, 4-methoxyphenyl group, 4-ethylphenyl group, 4-n-propylphenyl group, 4-isopropylphenyl group, 4-n-butylphenyl group, 4-t-butylphenyl group, 2,4-xylyl group, 3,5-xylyl group, 2,6-xylyl group, 2,4-dimethoxyphenyl group, 3,5-dimethoxyphenyl group, 2,6-dimethoxyphenyl group, 2,4,6-trimethylphenyl group (mesityl group), 2,4,6-trimethoxyphenyl group and fluorenyl group.

Furthermore, from the point of view of enhancing the stability against oxygen of the compound represented by the general formula (1) and thereby enhancing the durability, the substituent in the case where R⁷ is substituted is preferably an electron withdrawing group. Preferred examples of the electron withdrawing groups include fluorine, fluorine-containing alkyl groups, substituted or unsubstituted acyl groups, substituted or unsubstituted ester groups, substituted or unsubstituted amide groups, substituted or unsubstituted sulfonyl groups, nitro group, silyl group, cyano group and aromatic heterocyclic groups.

Particularly preferred examples of R⁷ include fluorophenyl group, trifluoromethylphenyl group, carboxylatophenyl group, acylphenyl group, amidophenyl group, sulfonylphenyl group, nitrophenyl group, silylphenyl group and benzonitrile group. More specific examples include 2-fluorophenyl group, 3-fluorophenyl group, 4-fluorophenyl group, 2,3-difluorophenyl group, 2,4-difluorophenyl group, 2,5-difluorophenyl group, 2,6-difluorophenyl group, 3,5-difluorophenyl group, 2,3,4-trifluorophenyl group, 2,3,5-trifluorophenyl group, 2,4,5-trifluorophenyl group, 2,4,6-trifluorophenyl group, 2,3,4,5-tetrafluorophenyl group, 2,3,4,6-tetrafluorophenyl group, 2,3,5,6-tetrafluorophenyl group, 2,3,4,5,6-pentafluorophenyl group, 2-trifluoromethylphenyl group, 3-trifluoromethylphenyl group, 4-trifluoromethylphenyl group, 2,3-bis(trifluoromethyl)phenyl group, 2,4-bis(trifluoromethyl)phenyl group, 2,5-bis(trifluoromethyl)phenyl group, 2,6-dibis(trifluoromethyl)phenyl group, 3,5-bis(trifluoromethyl)phenyl group, 2,3,4-tris(trifluoromethyl)phenyl group, 2,3,5-tris(trifluoromethyl)phenyl group, 2,4,5-tris(trifluoromethyl)phenyl group, 2,4,6-tris(trifluoromethyl)phenyl group, 2,3,4,5-tetrakis(trifluoromethyl)phenyl group, 2,3,4,6-tetrakis(trifluoromethyl)phenyl group, 2,3,5,6-tetrakis(trifluoromethyl)phenyl group, 2,3,4,5,6-penta(trifluoromethyl)phenyl group, 2-methoxycarbonylphenyl group, 3-methoxycarbonylphenyl group, 4-methoxycarbonylphenyl group, 2,3,4-tris(trifluoromethyl)phenyl group, 2,3,5-tris(trifluoromethyl)phenyl group, 2,4,5-tris(trifluoromethyl)phenyl group, 2,4,6-tris(trifluoromethyl)phenyl group, 2,3,4,5-tetrakis(trifluoromethyl)phenyl group, 2,3,4,6-tetrakis(trifluoromethyl)phenyl group, 2,3,5,6-tetrakis(trifluoromethyl)phenyl group, 2,3,4,5,6-penta(trifluoromethyl)phenyl group, 3,5-bis(methoxycarbonyl)phenyl group, 3,5-bis(methoxycarbonyl)phenyl group, 4-nitrophenyl group, 4-trimethylsilylphenyl group, 3,5-bis(trimethylsilyl)phenyl group and 4-benzonitrile group. Of these, 3-methoxycarbonylphenyl group, 4-methoxycarbonylphenyl group, 3,5-bis(methoxycarbonyl)phenyl group, 3-trifluoromethylphenyl group, 4-trifluoromethylphenyl group and 3,5-bis(trifluoromethyl)phenyl group are more preferable.

R⁸ and R⁹ in the general formula (1) are preferably cyano groups as described hereinabove, and, if not cyano groups, are preferably each an alkyl group, an aryl group, a heteroaryl group, an alkoxy group, an aryloxy group, a fluorine atom, a fluorine-containing alkyl group, a fluorine-containing heteroaryl group, a fluorine-containing aryl group, a fluorine-containing alkoxy group or a fluorine-containing aryloxy group. From the point of view of the fact that stability against excitation light and higher emission quantum yield can be obtained, R⁸ and R⁹ are more preferably each a fluorine atom, a fluorine-containing alkyl group, a fluorine-containing alkoxy group or a fluorine-containing aryl group. Of these, from the point of view of easy synthesis, R⁸ and R⁹ are still more preferably each a fluorine atom.

Here, the fluorine-containing aryl group is an aryl group containing a fluorine atom. Examples of the fluorine-containing aryl groups include, for example, fluorophenyl group, trifluoromethylphenyl group and pentafluorophenyl group. The fluorine-containing heteroaryl group is a heteroaryl group containing fluorine. Examples of the fluorine-containing heteroaryl groups include, for example, fluoropyridyl group, trifluoromethylpyridyl group and trifluoropyridyl group.

The fluorine-containing alkyl group is an alkyl group containing fluorine. Examples of the fluorine-containing alkyl groups include, for example, trifluoromethyl group and pentafluoroethyl group.

Still more preferred examples of the compounds represented by the general formula (1) include compounds with a structure represented by the general formula (2) below.

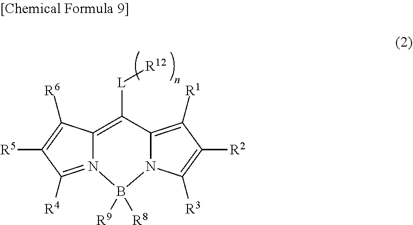

In the general formula (2), R¹ to R⁶, R⁸, and R⁹ are the same as described in the general formula (1). R¹² is a substituted or unsubstituted aryl group, or a substituted or unsubstituted heteroaryl group. L is a substituted or unsubstituted arylene group, or a substituted or unsubstituted heteroarylene group. The letter n is an integer of 1 to 5. When n is 2 to 5, as many R¹² as indicated by n may be the same as or different from one another.

In the compound represented by the general formula (2), the substituted or unsubstituted arylene group, or the substituted or unsubstituted heteroarylene group represented by L has appropriate bulkiness and thus makes it possible to prevent the aggregation of the molecules. Consequently, the emission efficiency and durability of the compound represented by the general formula (2) are still more enhanced.

From the point of view of photo stability, it is preferable that L in the general formula (2) be a substituted or unsubstituted arylene group. When L is a substituted or unsubstituted arylene group, the aggregation of the molecules can be prevented without deteriorations in emission wavelength. Consequently, the durability of the compound represented by the general formula (2) can be enhanced. Specifically, preferred arylene groups are phenylene group, biphenylene group and naphthylene group.

From the point of view of photo stability, it is preferable that R¹² in the general formula (2) be a substituted or unsubstituted aryl group. When R¹² is a substituted or unsubstituted aryl group, the aggregation of the molecules can be prevented without deteriorations in emission wavelength and thereby the durability of the compound represented by the general formula (2) can be enhanced. Specifically, the aryl group is preferably a substituted or unsubstituted phenyl group, a substituted or unsubstituted biphenyl group, a substituted or unsubstituted terphenyl group, or a substituted or unsubstituted naphthyl group, and more preferably a substituted or unsubstituted phenyl group, a substituted or unsubstituted biphenyl group, or a substituted or unsubstituted terphenyl group.

Furthermore, from the points of view of enhancing the compatibility with solvents and enhancing the emission efficiency, the substituents in the case where L and R¹² are substituted are preferably each a substituted or unsubstituted alkyl group, or a substituted or unsubstituted alkoxy group, and more preferably each a methyl group, an ethyl group, an isopropyl group, a tert-butyl group or a methoxy group. From the point of view of dispersibility, tert-butyl group and methoxy group are particularly preferable. A reason for this is because quenching due to the aggregation of the molecules can be prevented.

From the point of view of the substitution with such groups, a particularly preferred example of R¹² is a substituted or unsubstituted phenyl group. Specific examples include phenyl group, 2-tolyl group, 3-tolyl group, 4-tolyl group, 2-methoxyphenyl group, 3-methoxyphenyl group, 4-methoxyphenyl group, 4-ethylphenyl group, 4-n-propylphenyl group, 4-isopropylphenyl group, 4-n-butylphenyl group, 4-t-butylphenyl group, 2,4-xylyl group, 3,5-xylyl group, 2,6-xylyl group, 2,4-dimethoxyphenyl group, 3,5-dimethoxyphenyl group, 2,6-dimethoxyphenyl group, 2,4,6-trimethylphenyl group (mesityl group), 2,4,6-trimethoxyphenyl group and fluorenyl group.

Furthermore, from the point of view of enhancing the stability against oxygen of the compound represented by the general formula (2) and thereby enhancing the durability, the substituents in the case where L and R¹² are substituted are preferably each an electron withdrawing group. Preferred examples of the electron withdrawing groups include fluorine atom, fluorine-containing alkyl groups, substituted or unsubstituted acyl groups, substituted or unsubstituted alkoxycarbonyl groups, substituted or unsubstituted aryloxycarbonyl groups, substituted or unsubstituted ester groups, substituted or unsubstituted amide groups, substituted or unsubstituted sulfonyl groups, nitro group, silyl group, cyano group and aromatic heterocyclic groups.

From the point of view of the substitution with the electron withdrawing groups, particularly preferred examples of R¹² include fluorophenyl group, trifluoromethylphenyl group, alkoxycarbonylphenyl group, aryloxycarbonylphenyl group, acylphenyl group, amidophenyl group, sulfonylphenyl group, nitrophenyl group, silylphenyl group and benzonitrile group. More specific examples include fluorine atom, trifluoromethyl group, cyano group, methoxycarbonyl group, amide group, acyl group, nitro group, 2-fluorophenyl group, 3-fluorophenyl group, 4-fluorophenyl group, 2,3-difluorophenyl group, 2,4-difluorophenyl group, 2,5-difluorophenyl group, 2,6-difluorophenyl group, 3,5-difluorophenyl group, 2,3,4-trifluorophenyl group, 2,3,5-trifluorophenyl group, 2,4,5-trifluorophenyl group, 2,4,6-trifluorophenyl group, 2,3,4,5-tetrafluorophenyl group, 2,3,4,6-tetrafluorophenyl group, 2,3,5,6-tetrafluorophenyl group, 2,3,4,5,6-pentafluorophenyl group, 2-trifluoromethylphenyl group, 3-trifluoromethylphenyl group, 4-trifluoromethylphenyl group, 2,3-bis(trifluoromethyl)phenyl group, 2,4-bis(trifluoromethyl)phenyl group, 2,5-bis(trifluoromethyl)phenyl group, 2,6-dibis(trifluoromethyl)phenyl group, 3,5-bis(trifluoromethyl)phenyl group, 2,3,4-tris(trifluoromethyl)phenyl group, 2,3,5-tris(trifluoromethyl)phenyl group, 2,4,5-tris(trifluoromethyl)phenyl group, 2,4,6-tris(trifluoromethyl)phenyl group, 2,3,4,5-tetrakis(trifluoromethyl)phenyl group, 2,3,4,6-tetrakis(trifluoromethyl)phenyl group, 2,3,5,6-tetrakis(trifluoromethyl)phenyl group, 2,3,4,5,6-penta(trifluoromethyl)phenyl group, 2-methoxycarbonylphenyl group, 3-methoxycarbonylphenyl group, 4-methoxycarbonylphenyl group, 3,5-bis(methoxycarbonyl)phenyl group, 4-nitrophenyl group, 4-trimethylsilylphenyl group, 3,5-bis(trimethylsilyl)phenyl group and 4-benzonitrile group. Of these, 4-methoxycarbonylphenyl group and 3,5-bis(trifluoromethyl)phenyl group are more preferable.

From the point of view of the fact that the compound gives a higher emission quantum yield, is more resistant to thermal decomposition, and exhibits photo stability, L in the general formula (2) is preferably a substituted or unsubstituted phenylene group.

In the general formula (2), the integer n is preferably 1 or 2, and more preferably 2. That is, the compound represented by the general formula (2) preferably includes one or two groups R¹², and more preferably includes two groups R¹². When the compound includes one or two, more preferably two, groups R¹² having a bulky substituent or an electron withdrawing group, the compound represented by the general formula (2) can attain enhanced durability while maintaining a high emission quantum yield. When n is 2, the two groups R¹² may be the same as or different from one another.

Furthermore, the molecular weight of the compound represented by the general formula (1) is preferably not less than 450. When the compound represented by the general formula (1) is used as a resin composition, a high molecular weight leads to the suppression of the migration of molecules within the resin, and thus durability is enhanced. Furthermore, when the compound represented by the general formula (1) is used in an organic thin film light-emitting device, the sublimation temperature is sufficiently high to make it possible to prevent a contamination in a chamber. Thus, the organic thin film light-emitting device exhibits stable high luminance emission, and therefore highly efficient emission can be obtained easily.

Furthermore, the molecular weight of the compound represented by the general formula (1) is preferably not more than 2000. When the compound represented by the general formula (1) is used as a resin composition, 2000 or less molecular weight leads to the suppression of the aggregation of the molecules and, as a result of this, the quantum yield is enhanced. Furthermore, when the compound represented by the general formula (1) is used in an organic thin film light-emitting device, the compound can be stably deposited without being thermally decomposed.

Some examples of the compounds represented by the general formula (1) will be illustrated hereinbelow, but the compounds are not limited thereto.

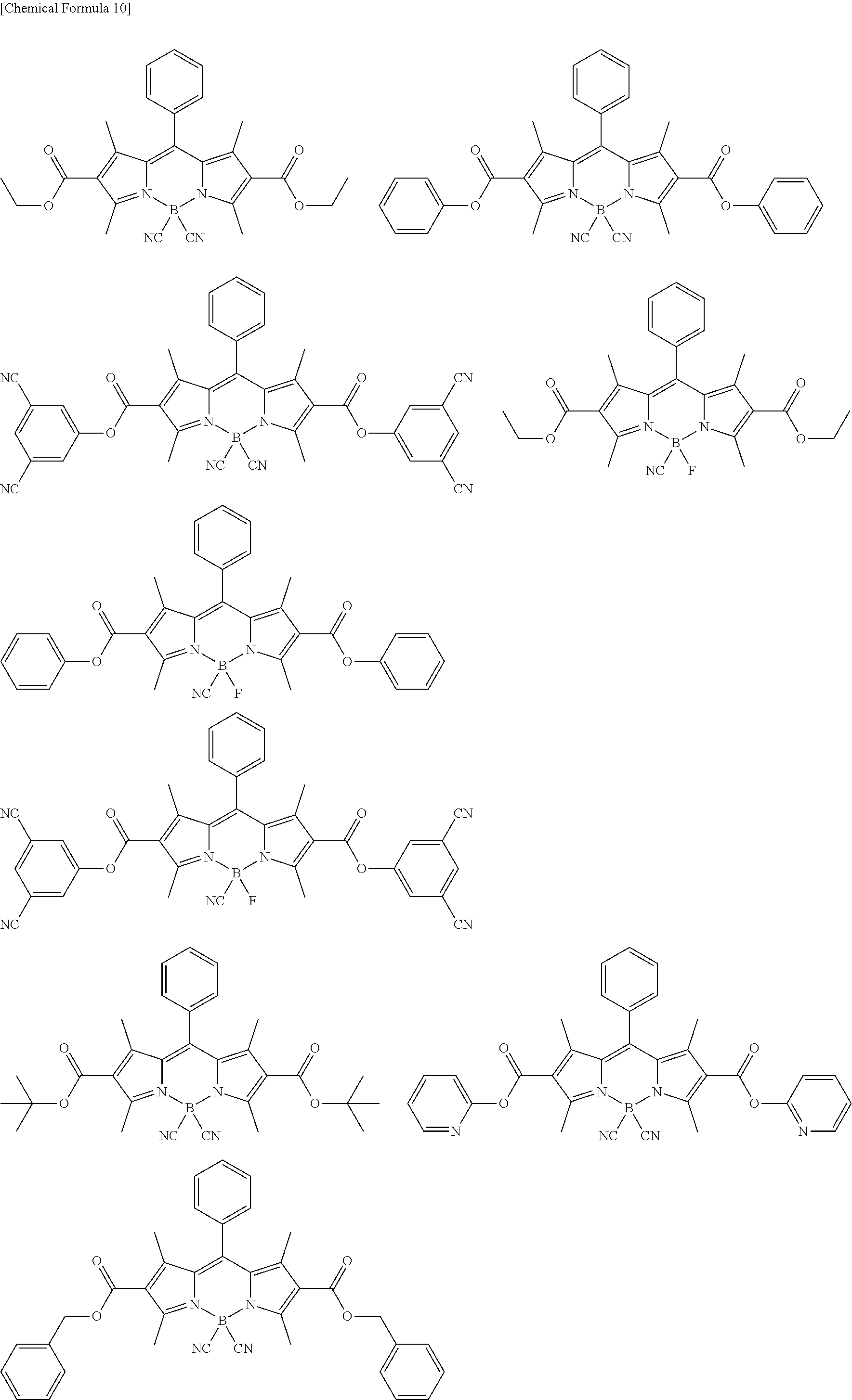

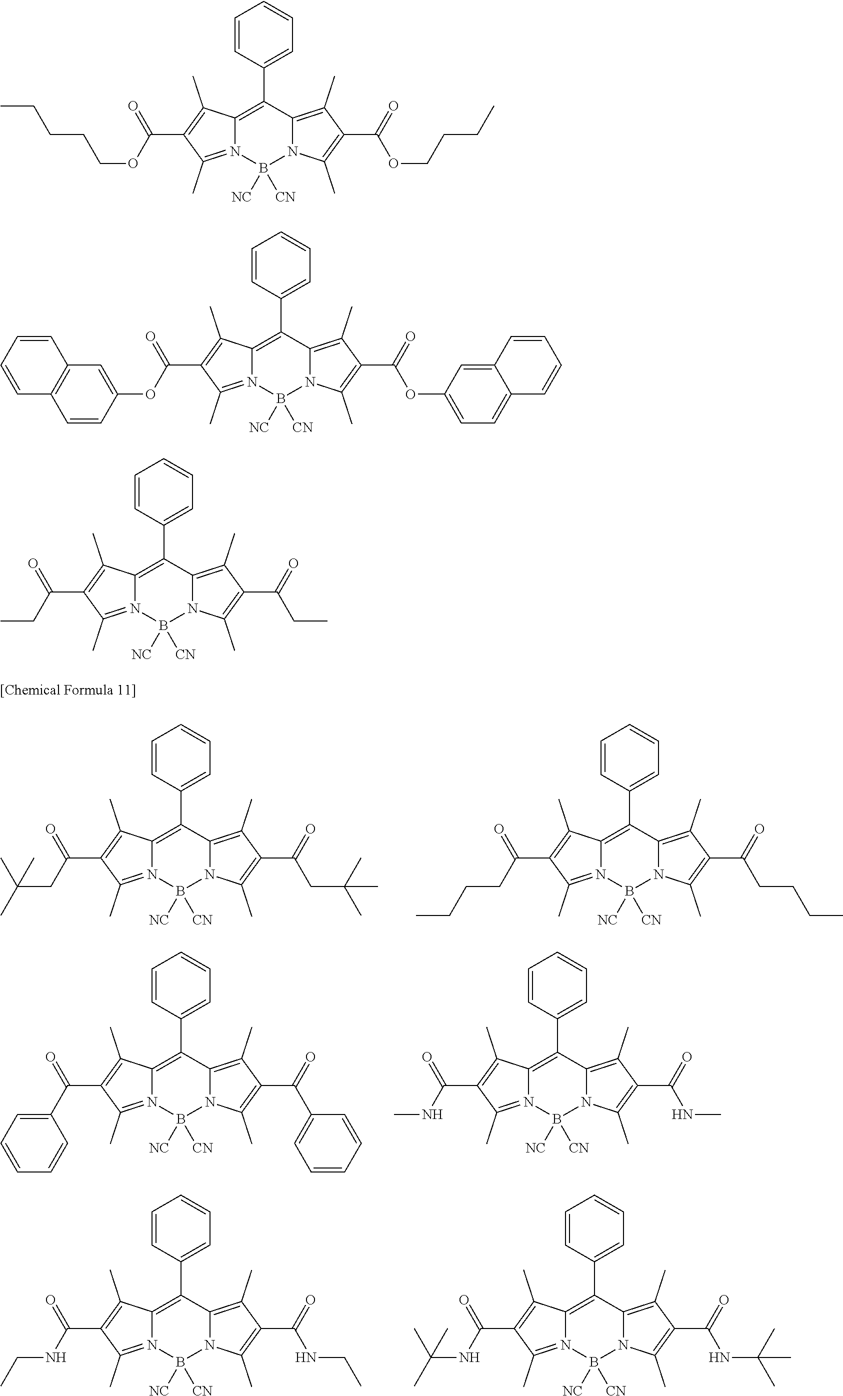

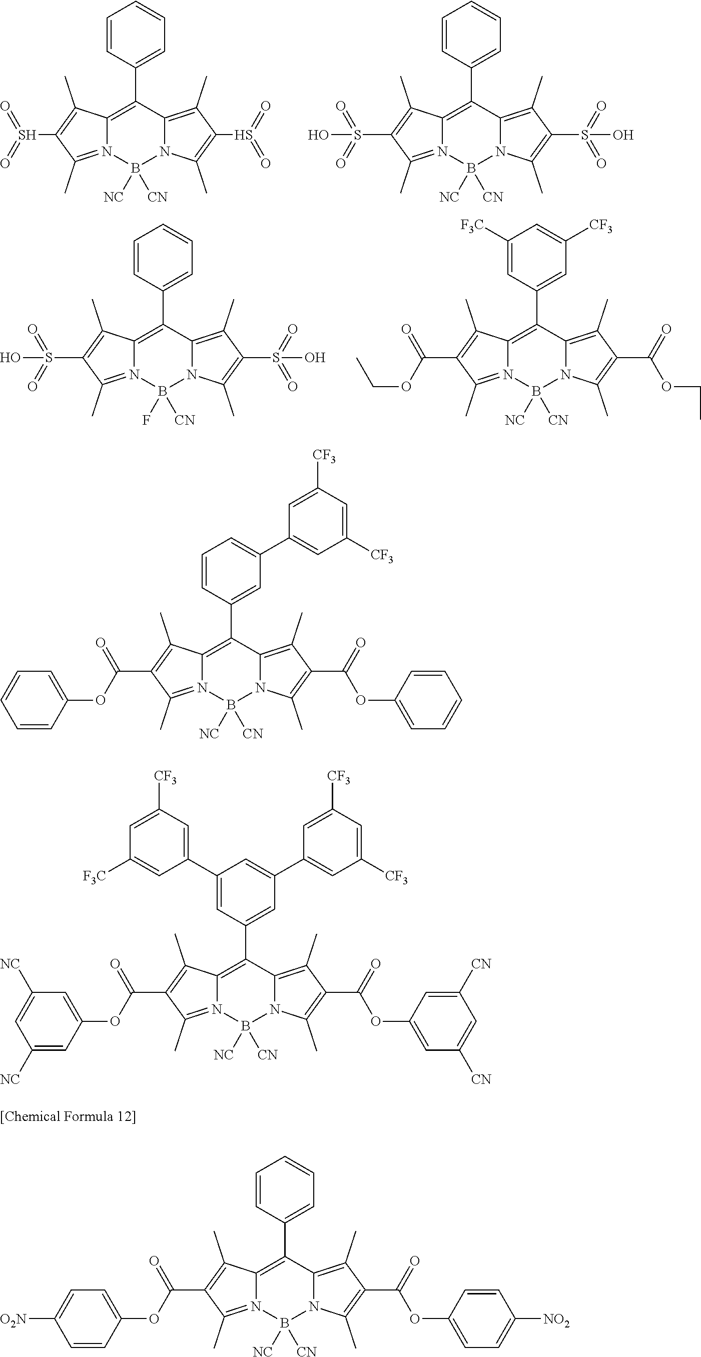

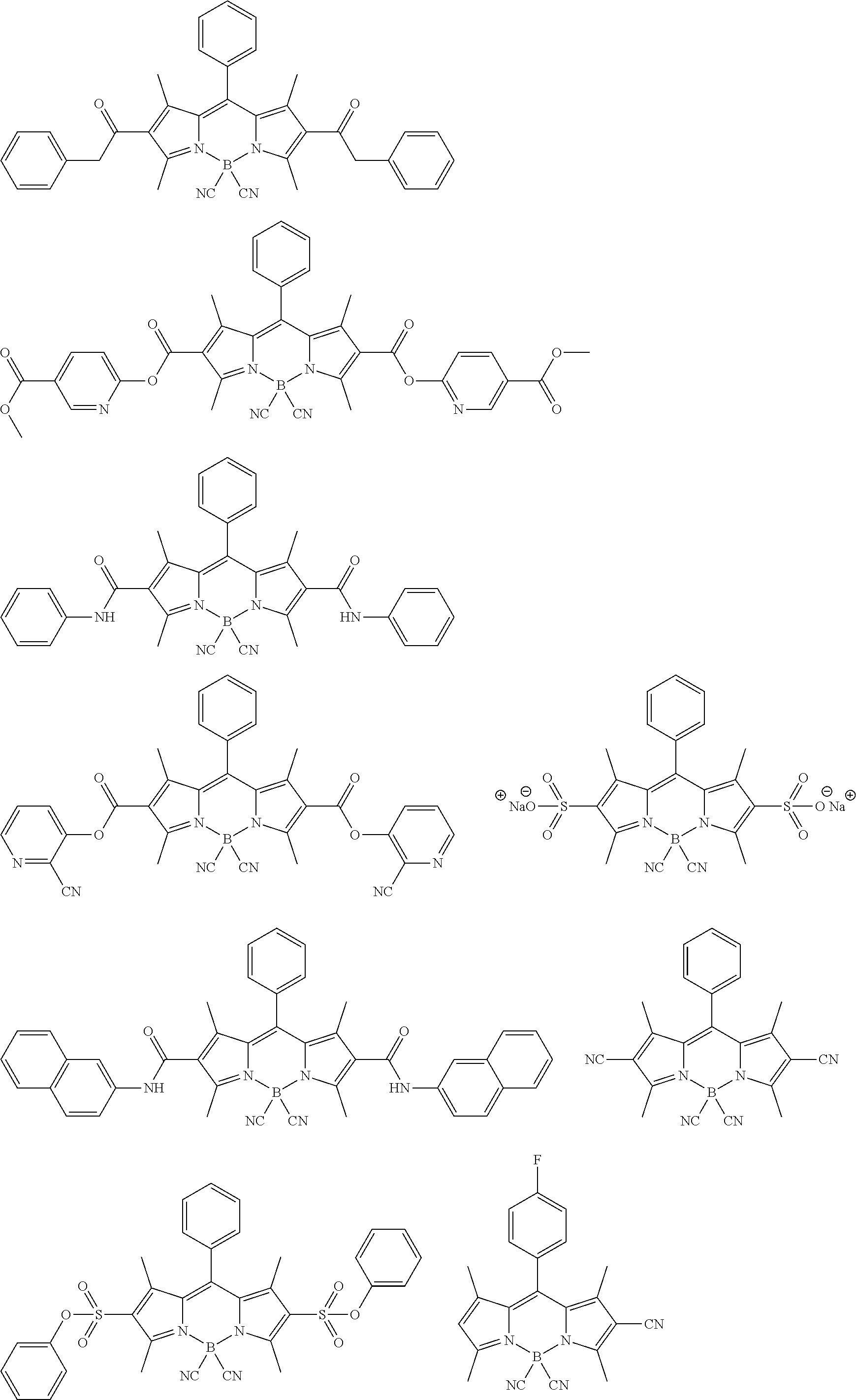

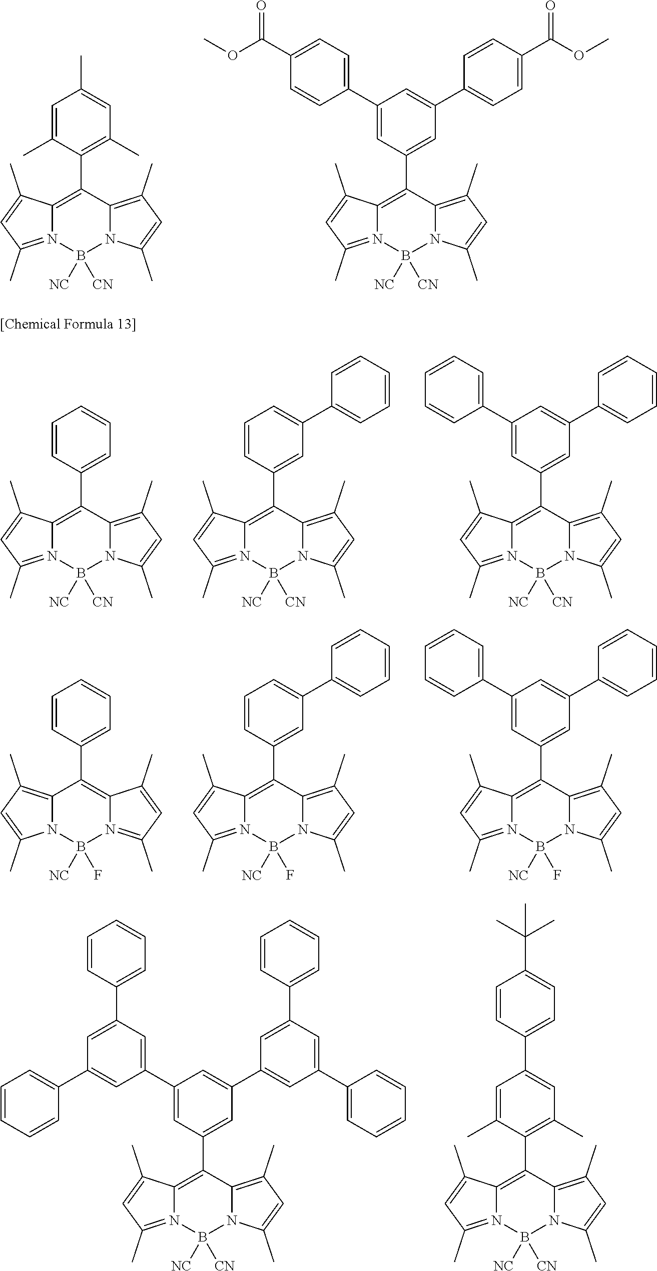

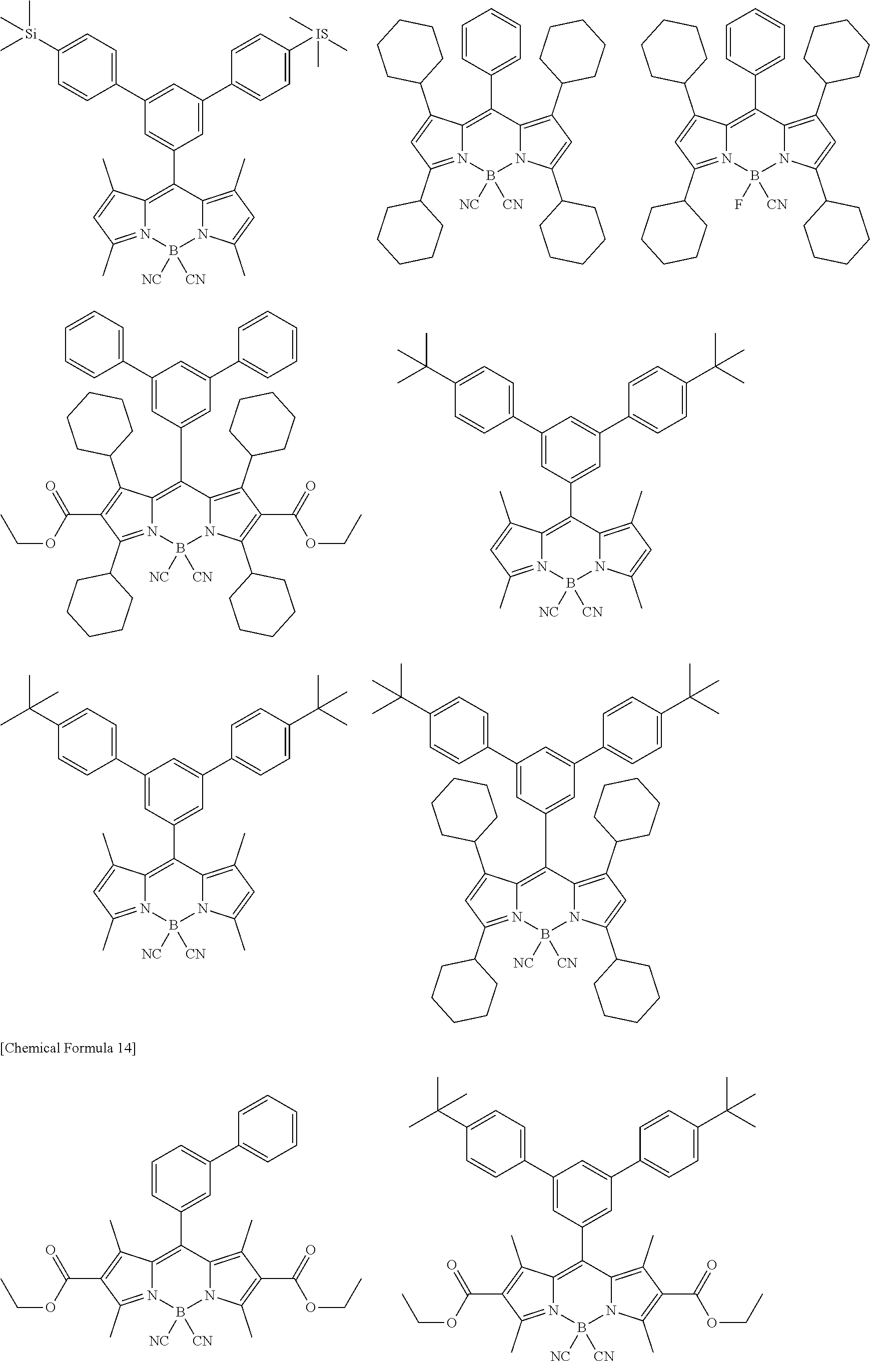

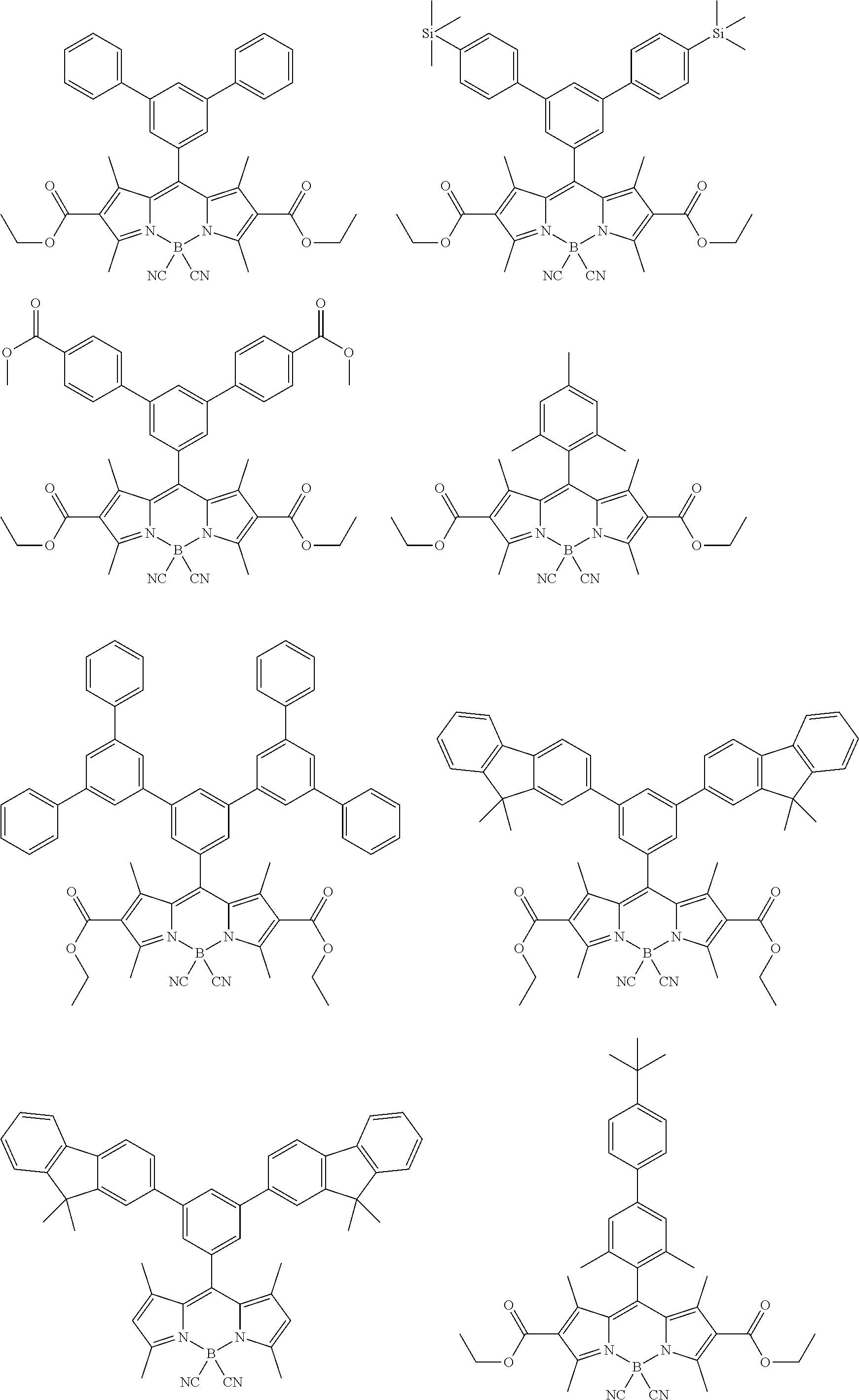

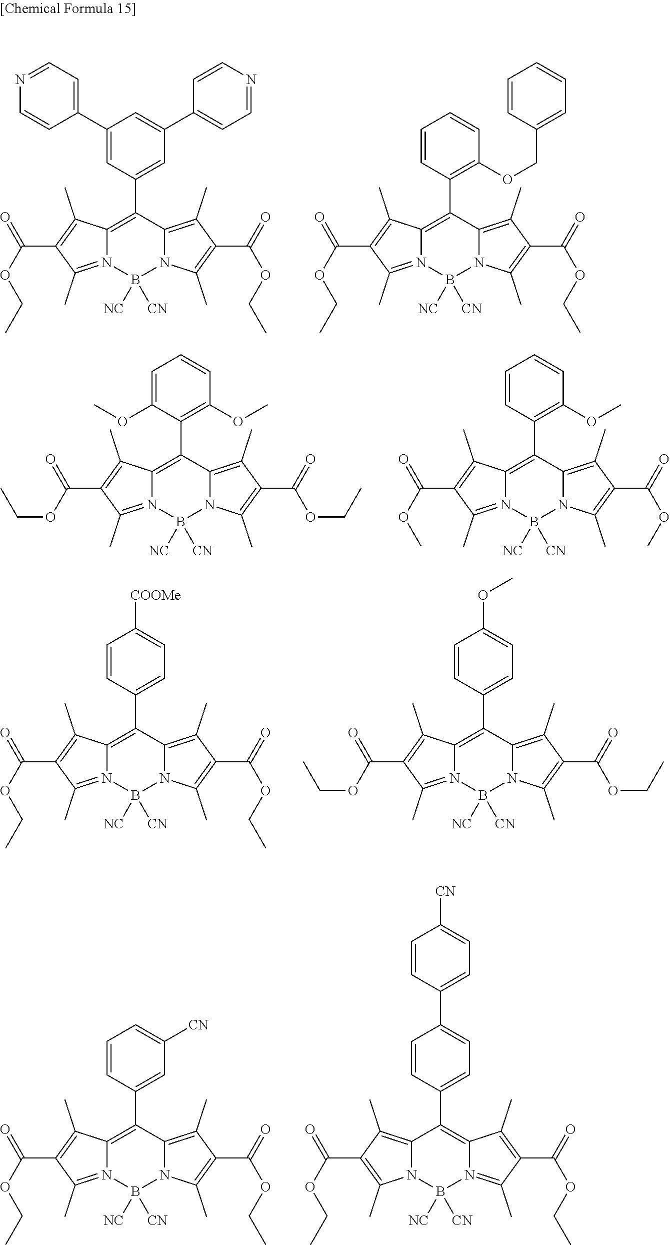

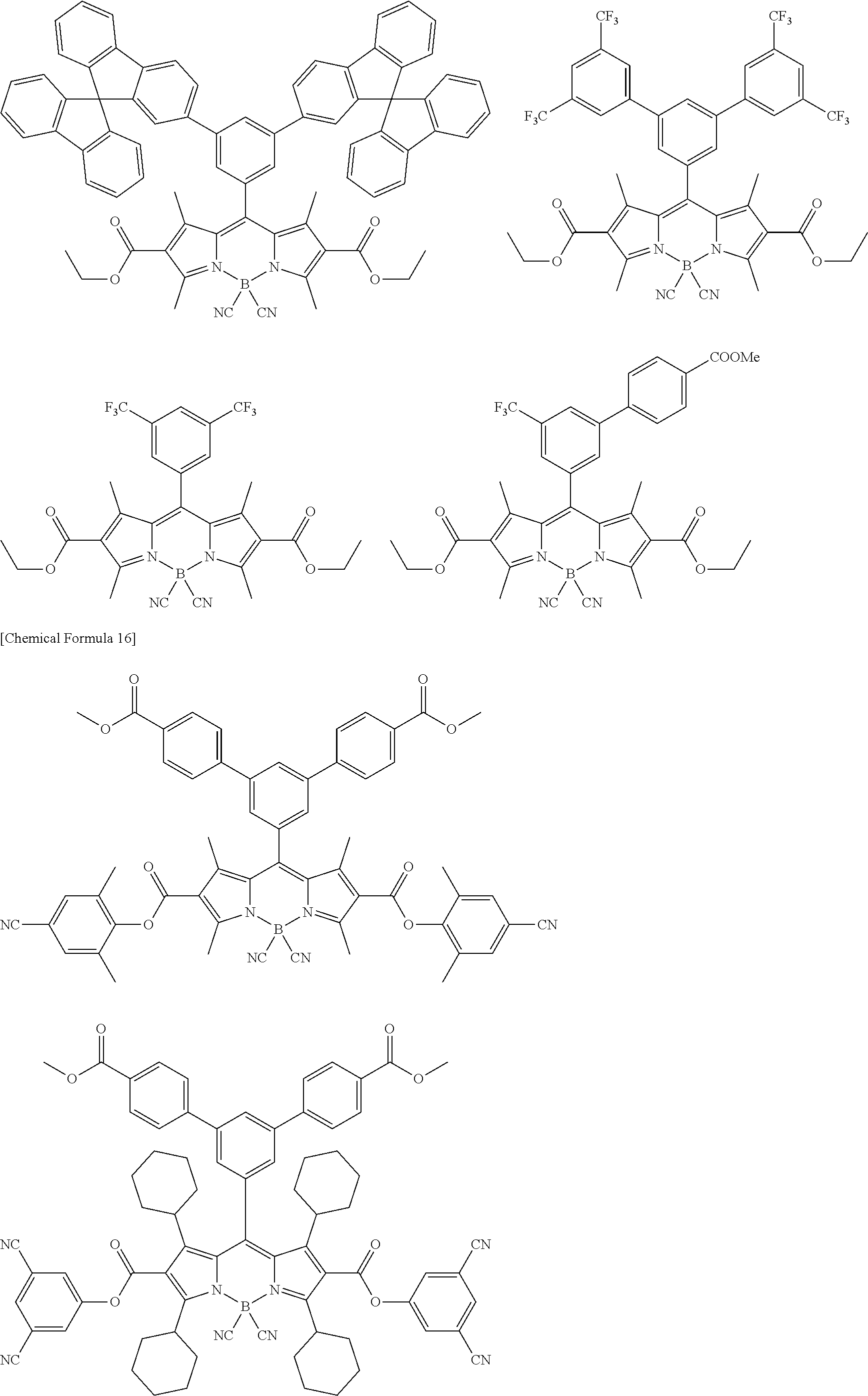

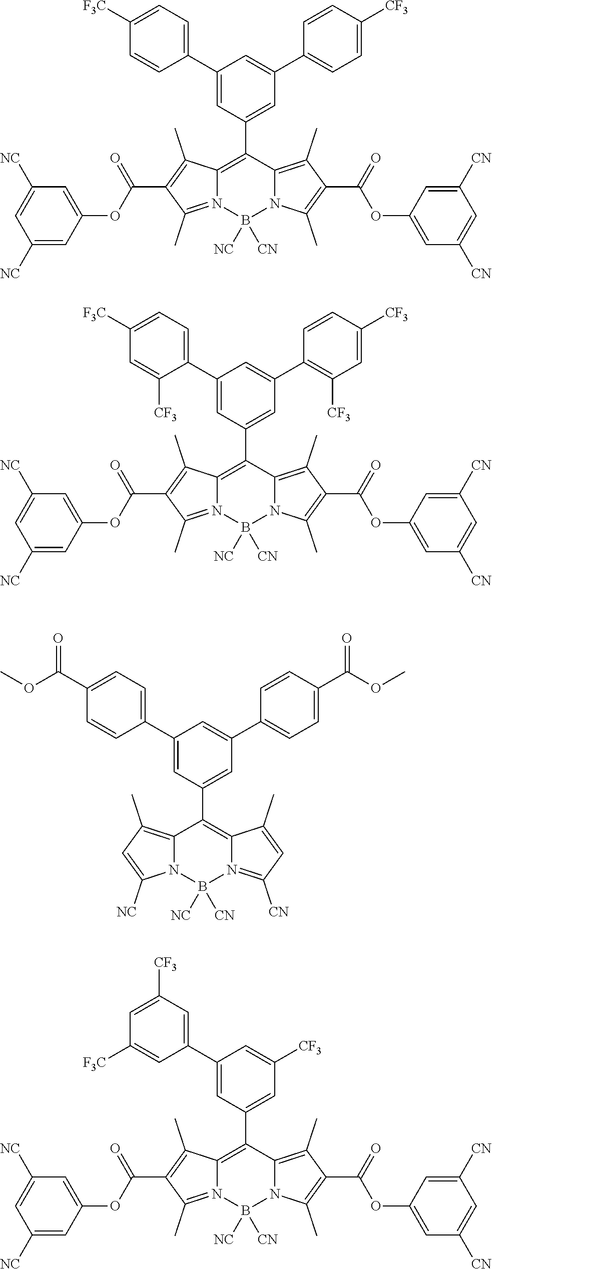

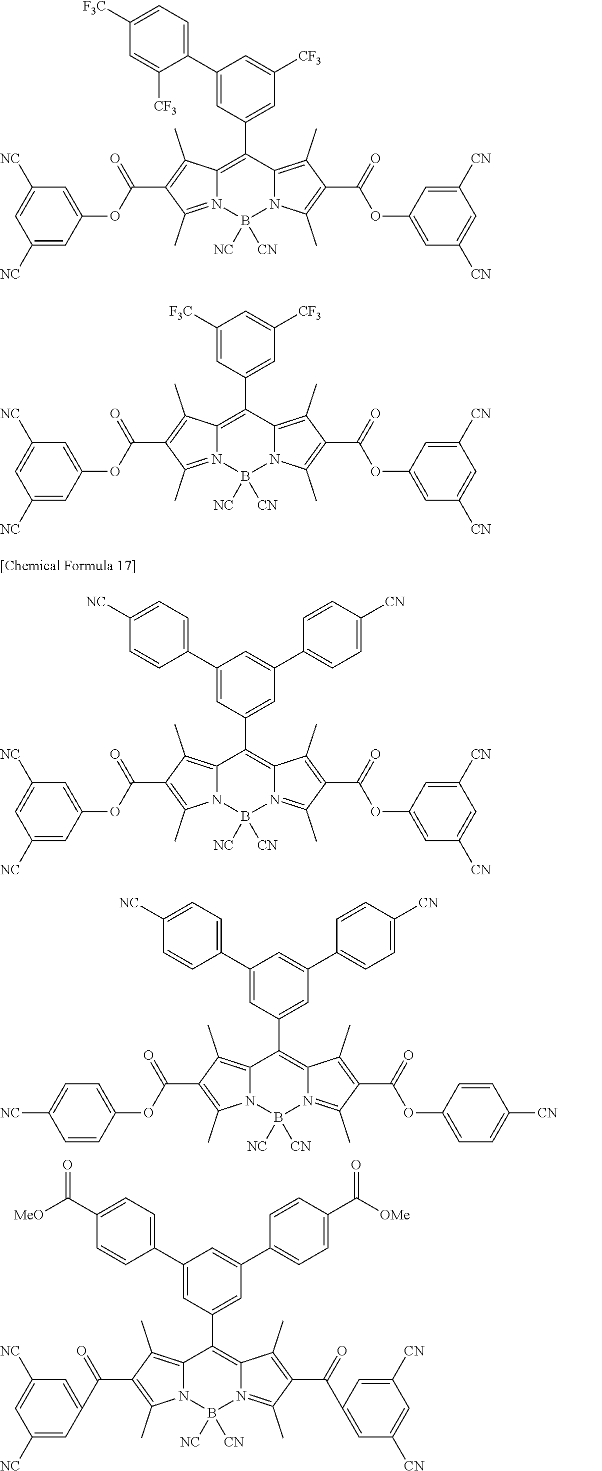

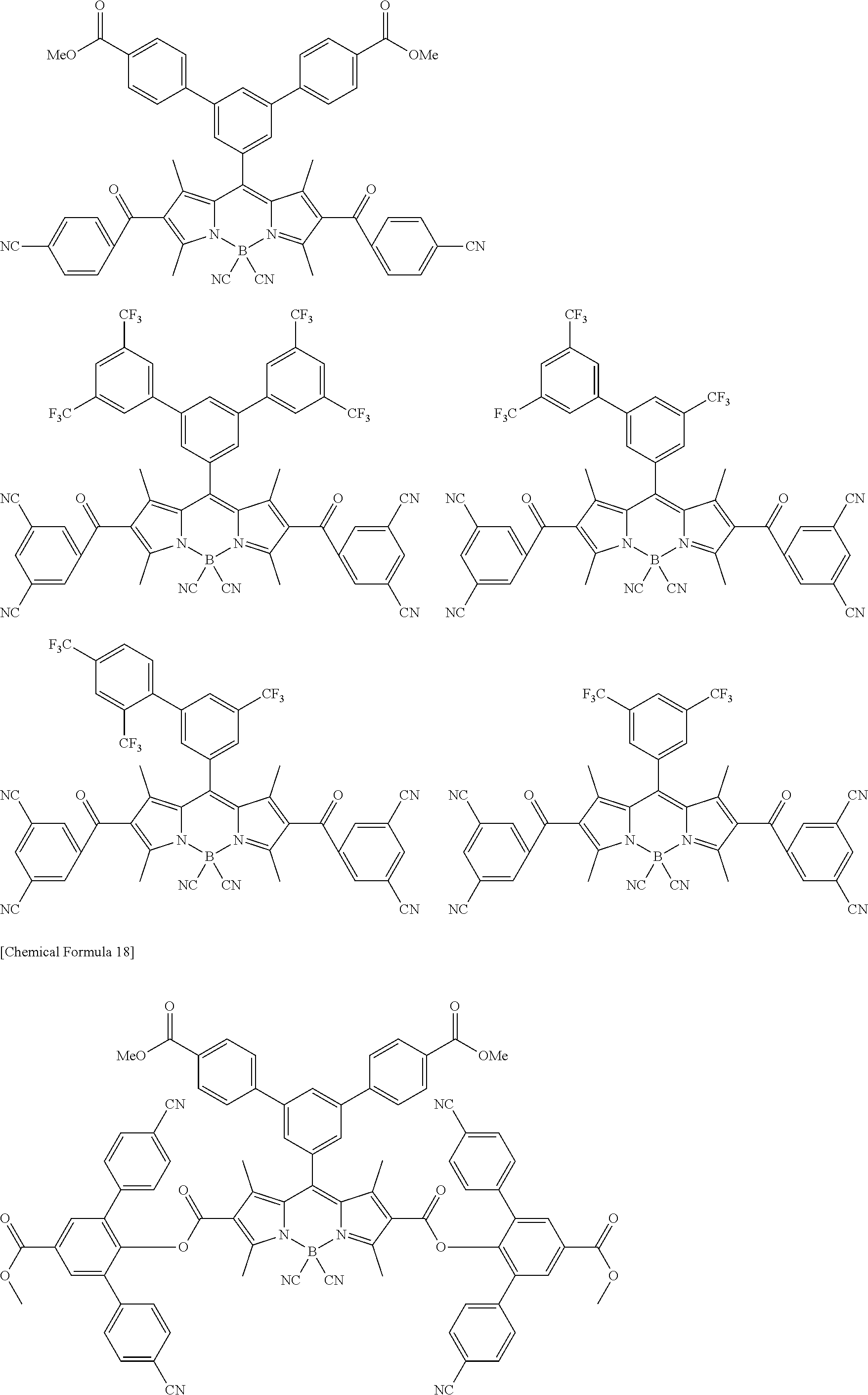

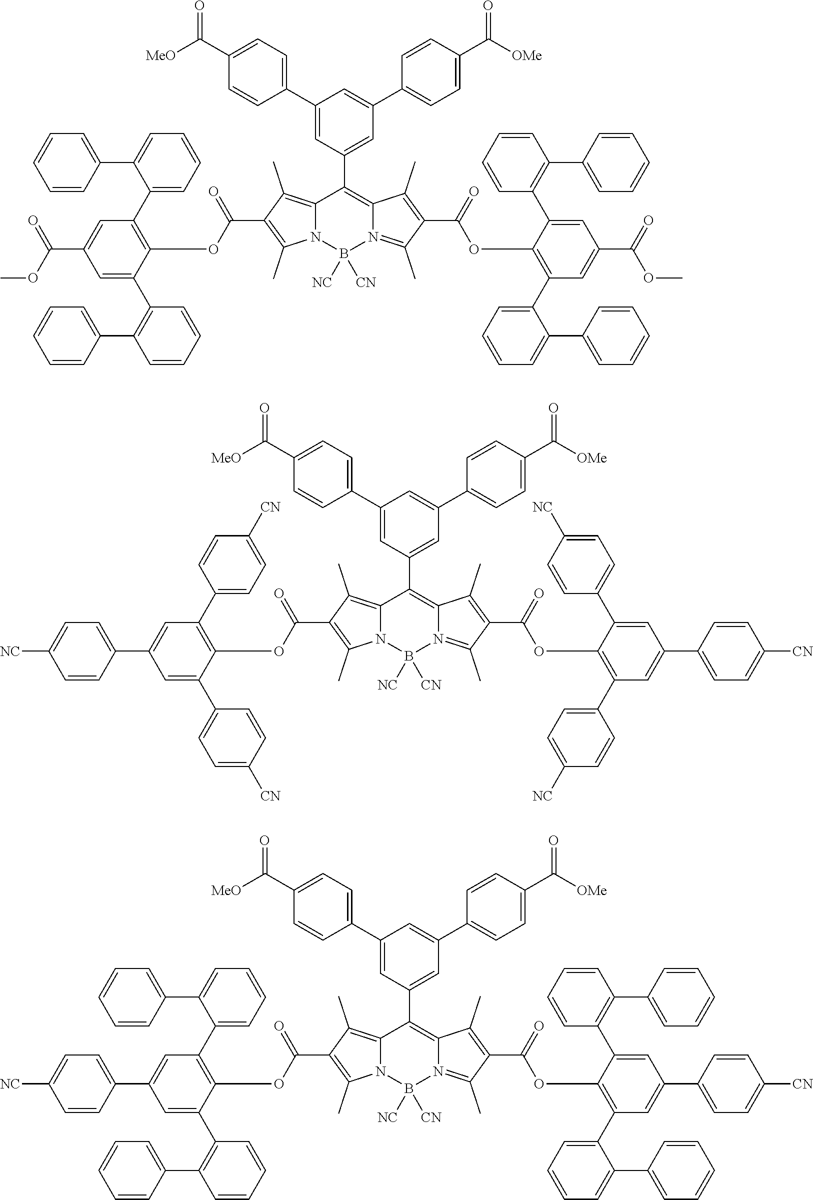

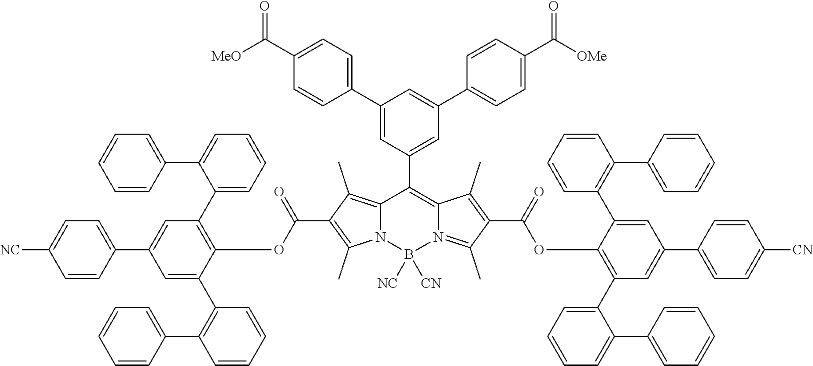

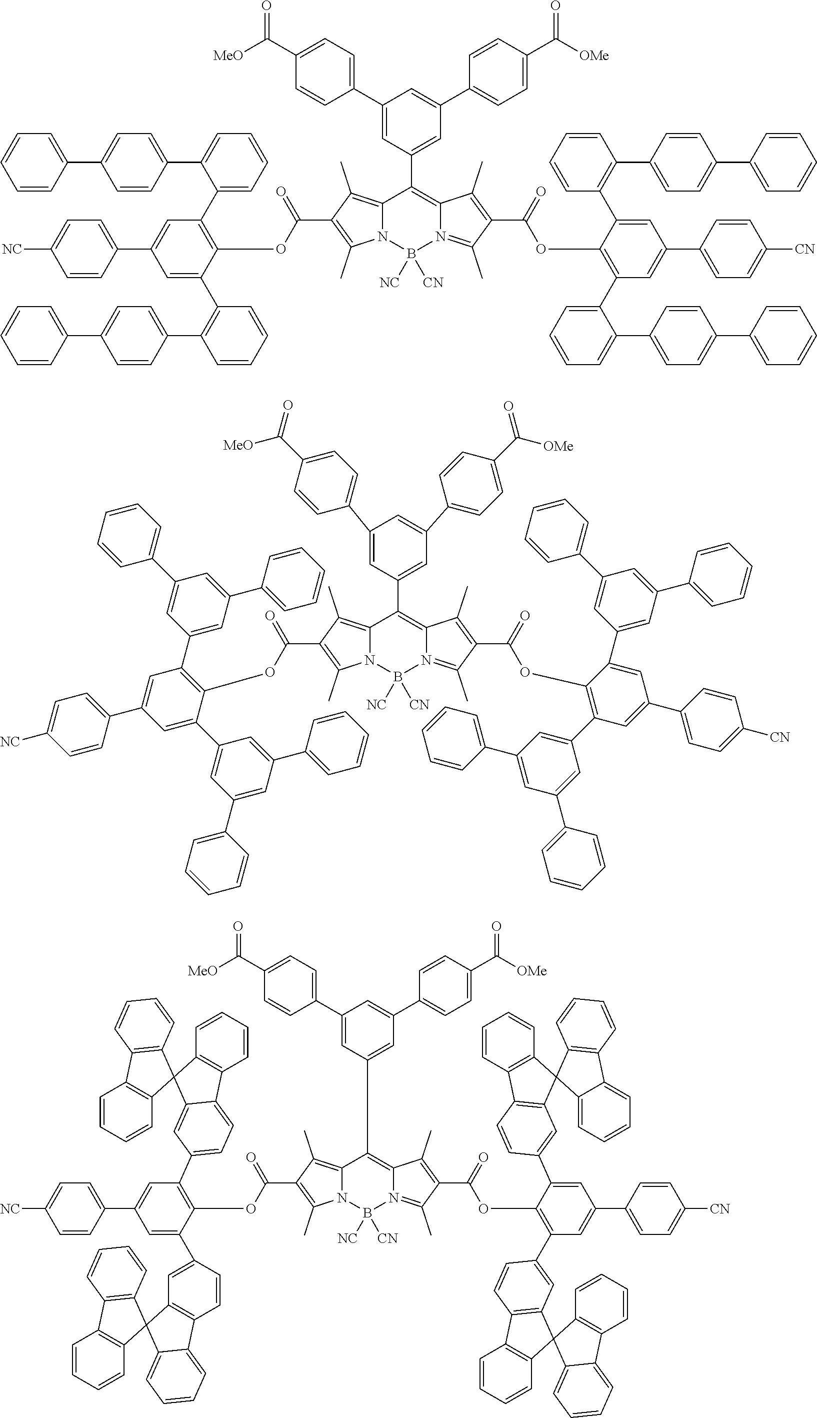

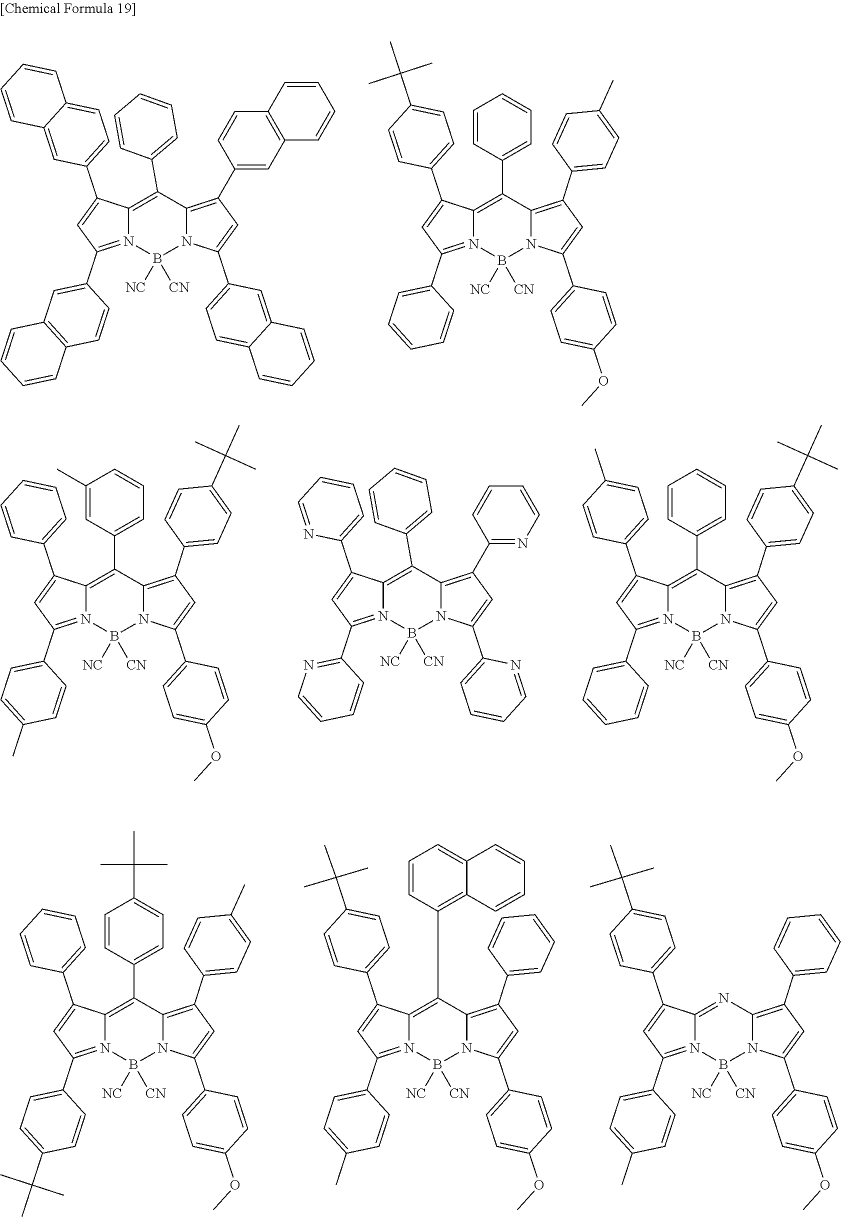

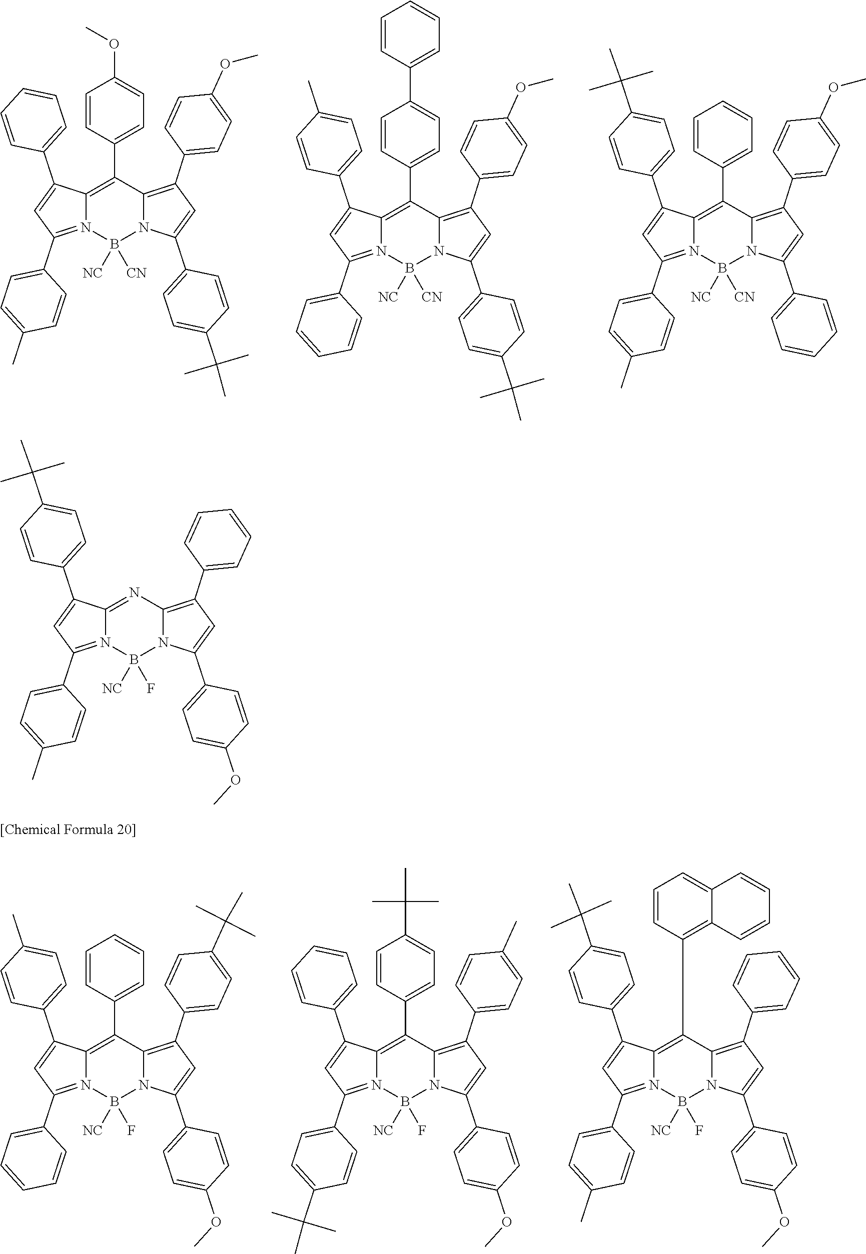

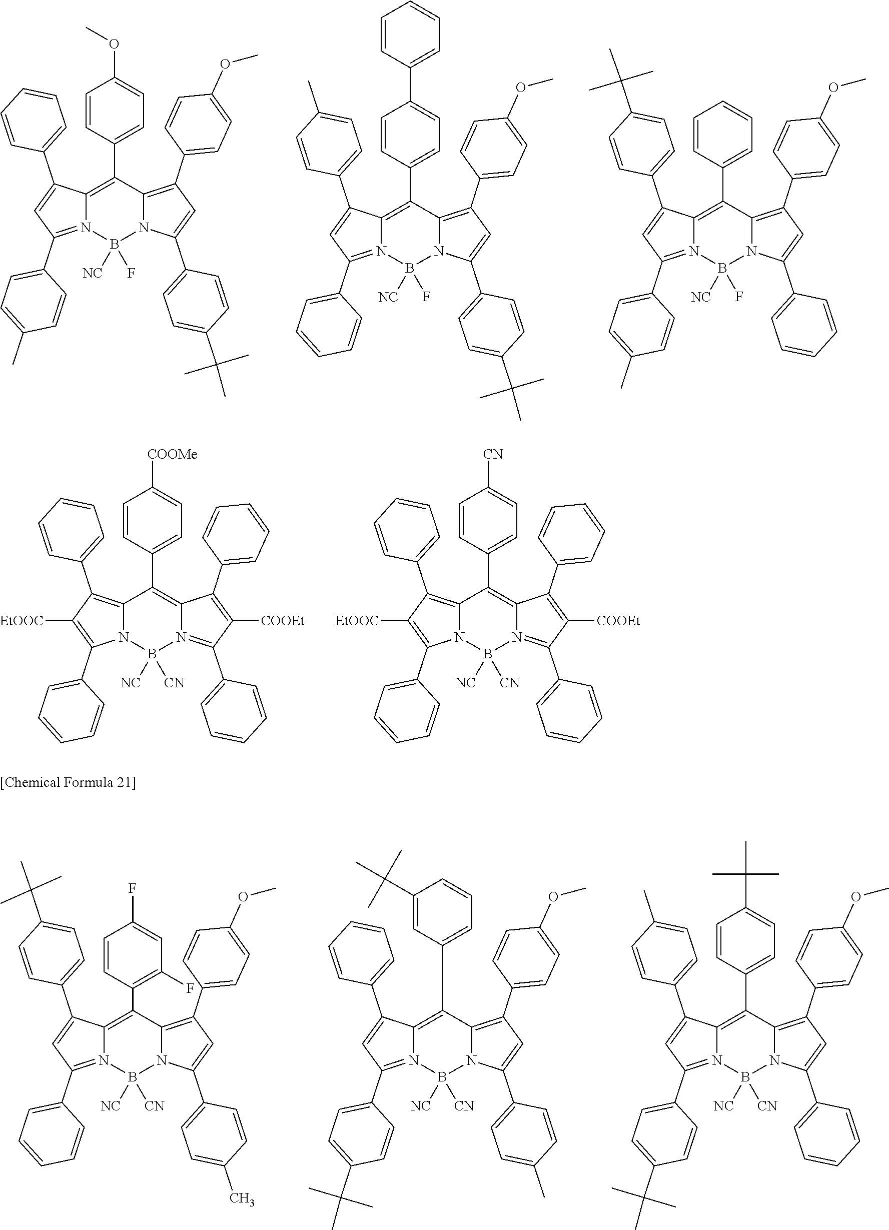

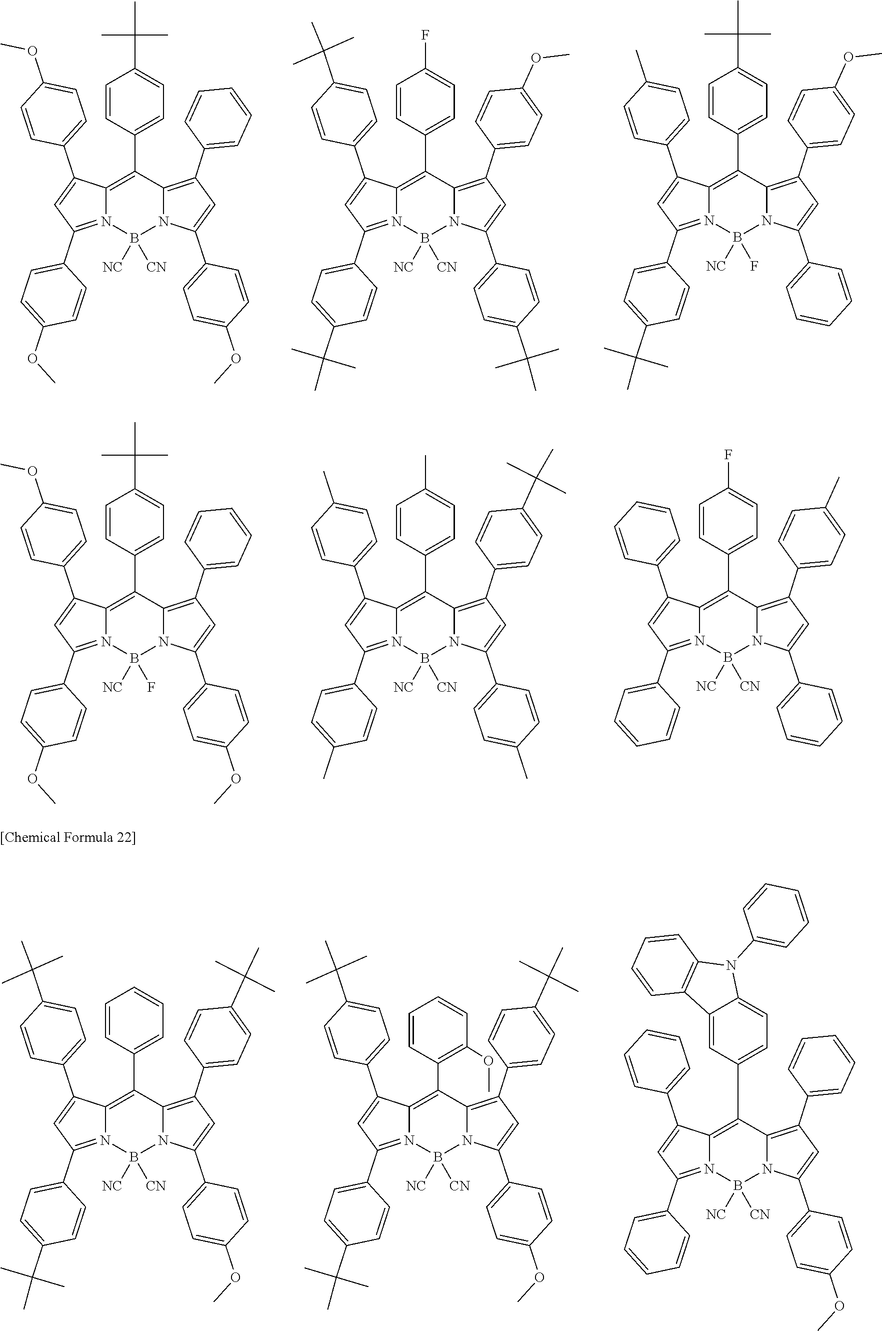

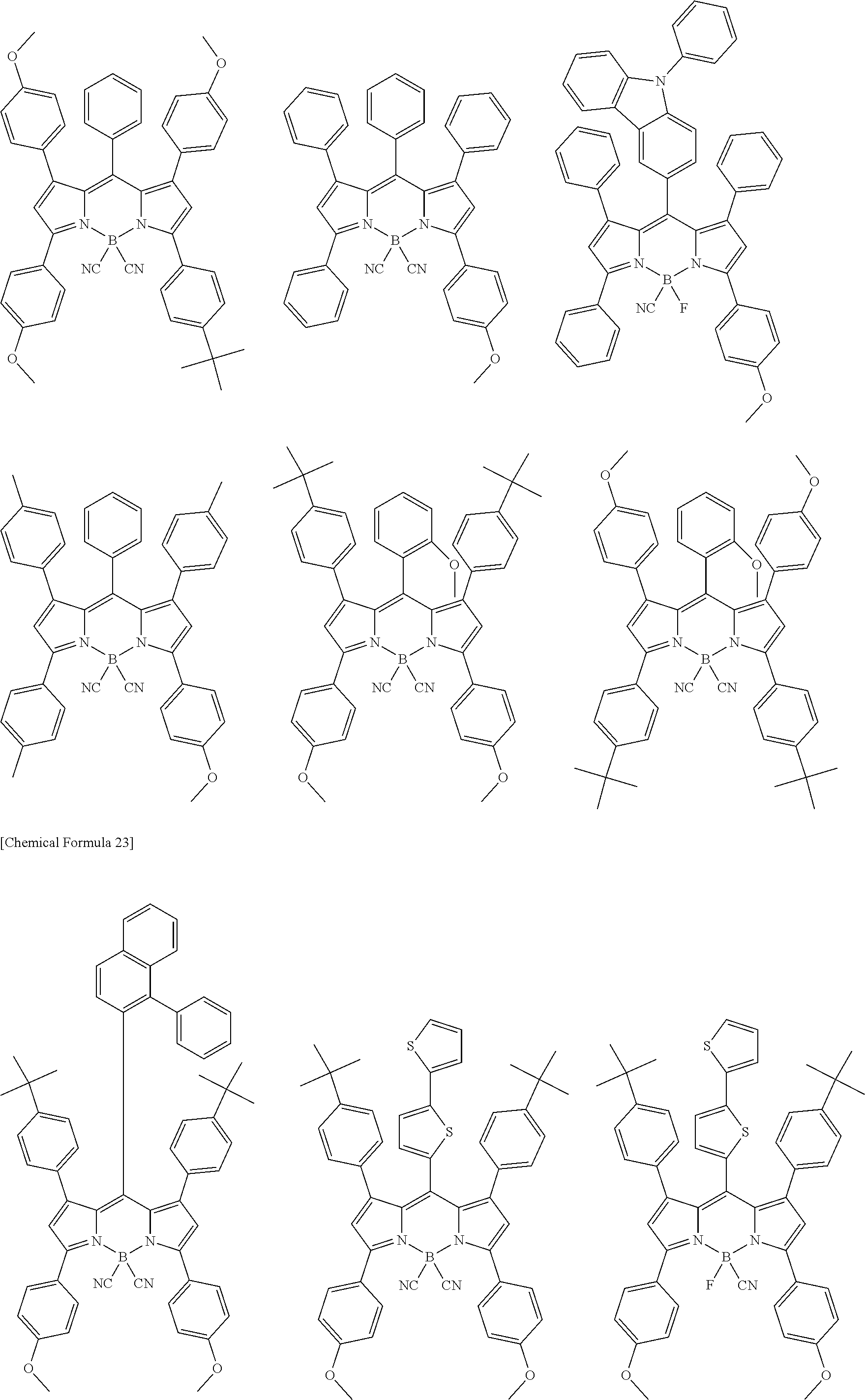

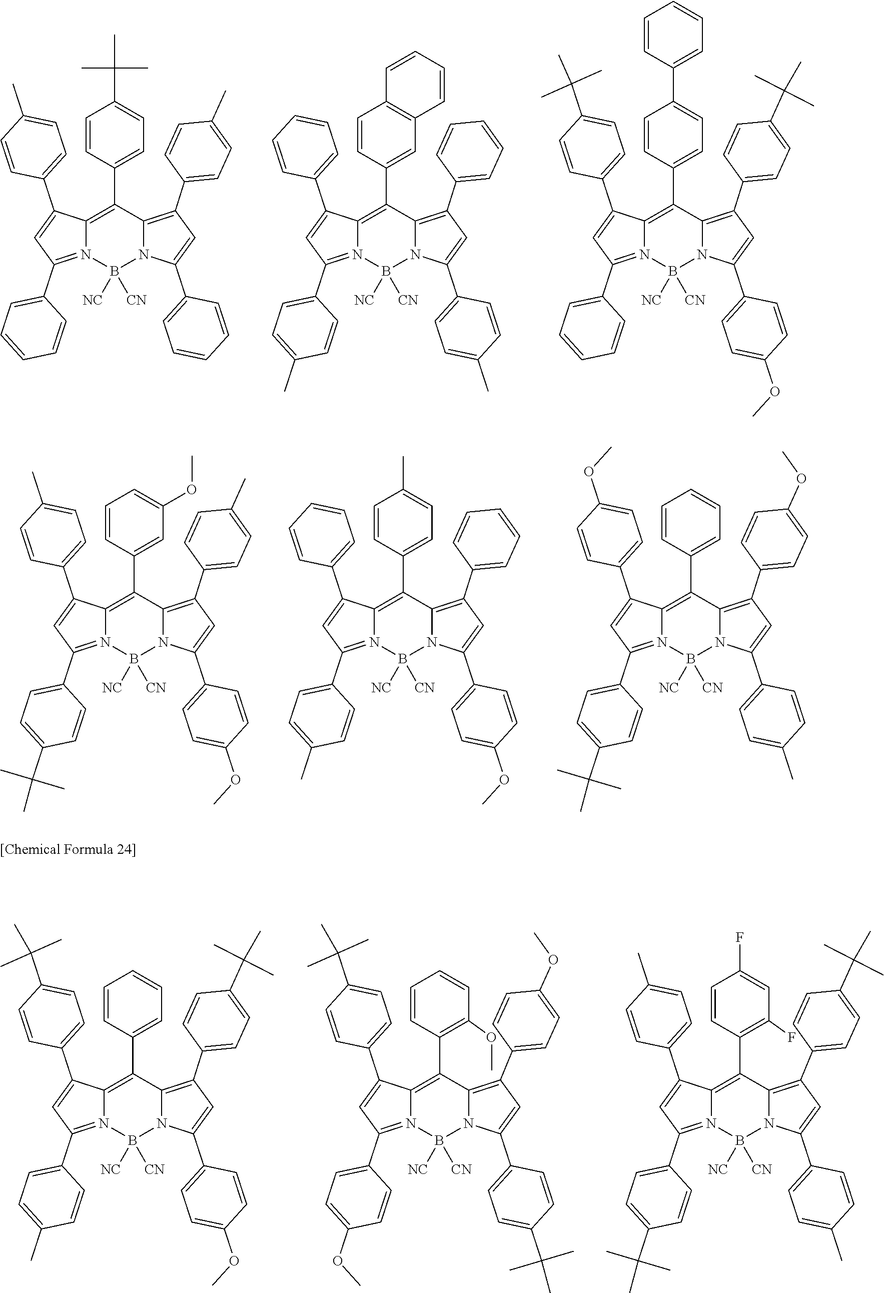

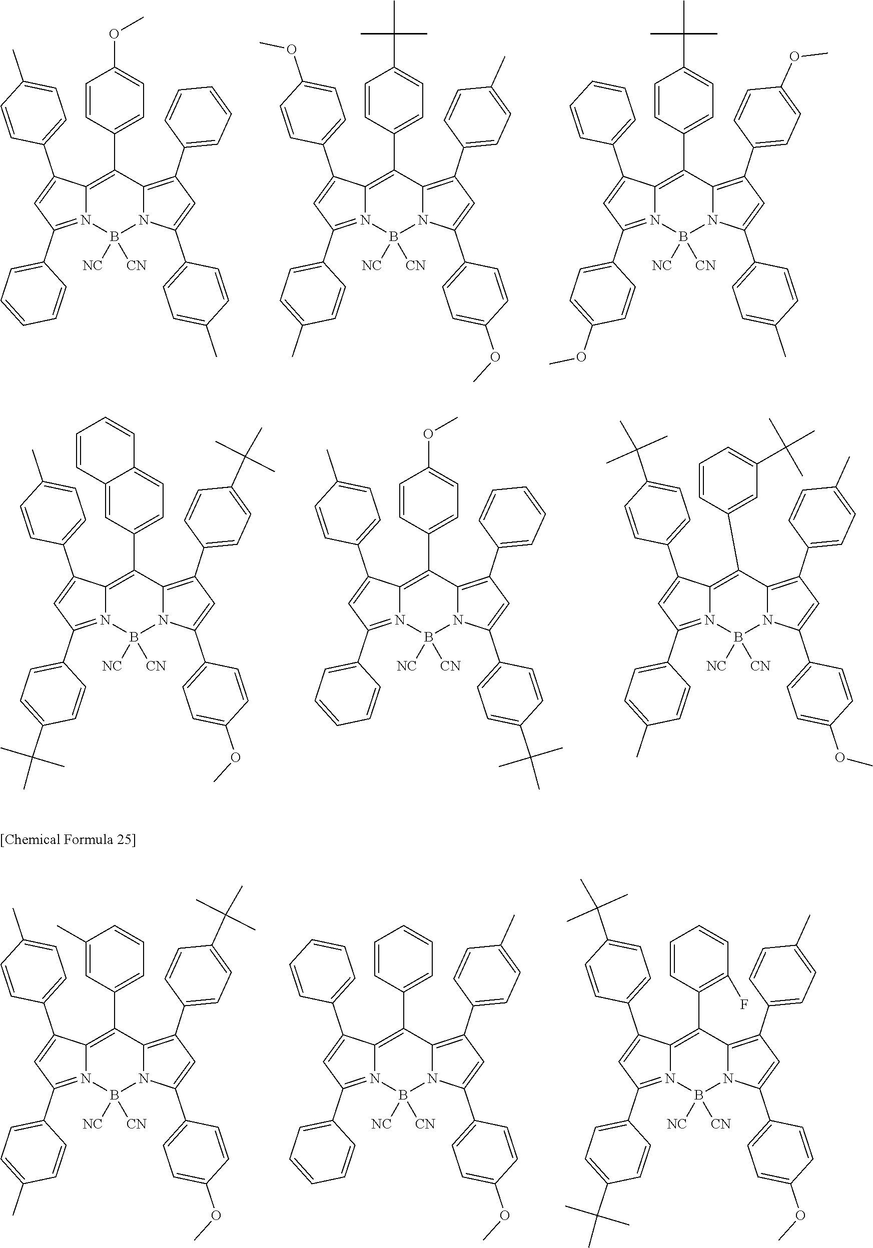

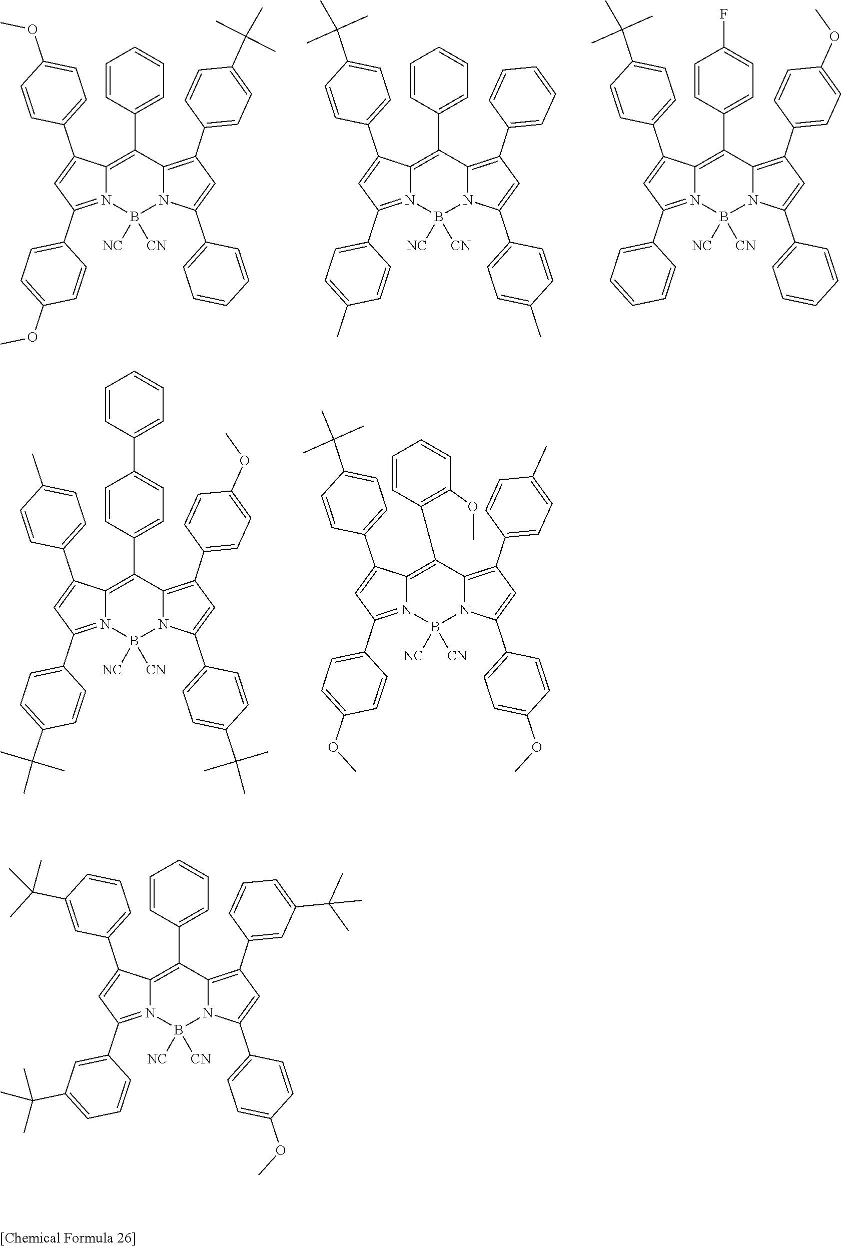

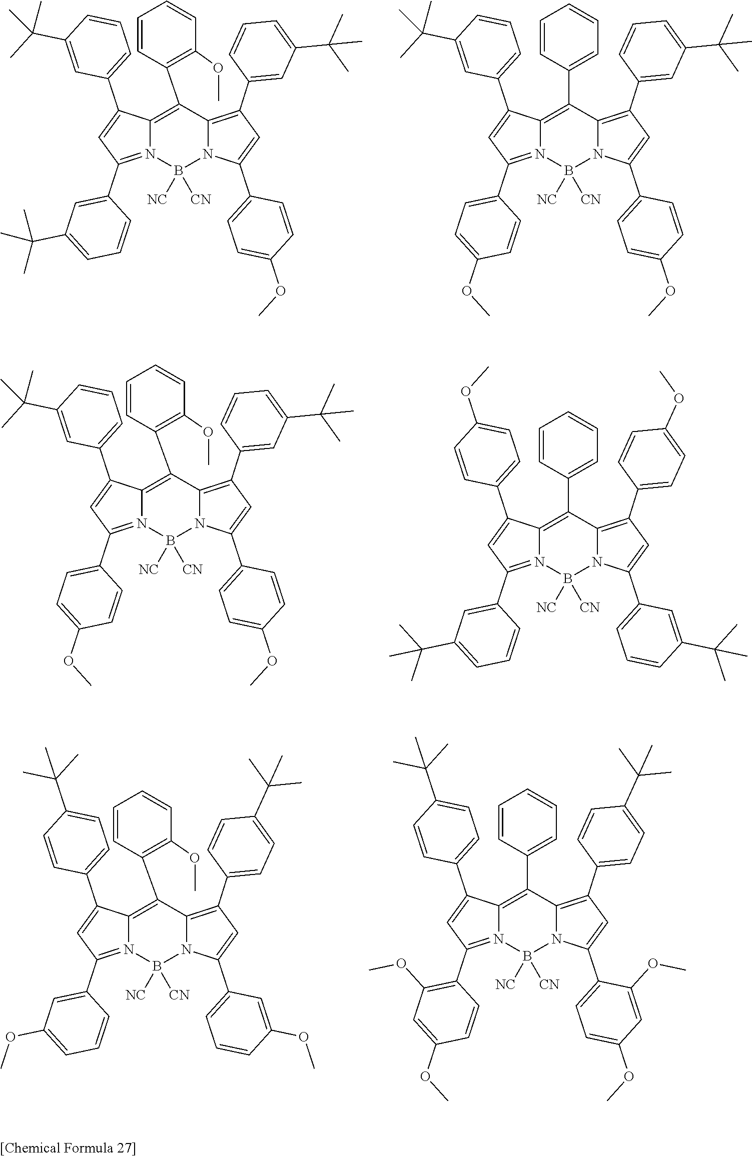

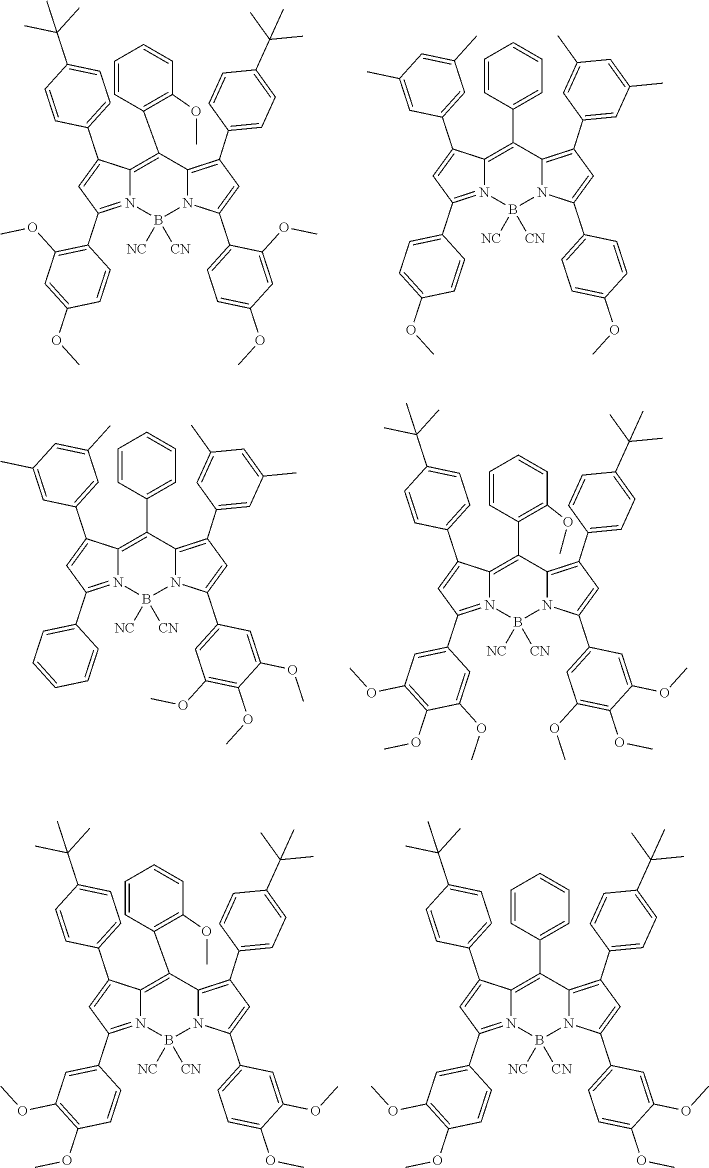

The compounds represented by the general formula (1) may be produced by, for example, the methods described in Japanese Patent Application Laid-open (Translation of PCT Application) No. H8-509471 and Japanese Patent Application Laid-open No. 2000-208262. Specifically, the target pyrromethene metal complex may be obtained by reacting a pyrromethene compound and a metal salt in the presence of a base.

Furthermore, regarding the synthesis of pyrromethene-boron fluoride complexes, the compounds represented by the general formula (1) may be synthesized with reference to the methods described in J. Org. Chem., Vol. 64, No. 21, pp. 7813-7819 (1999), Angew. Chem., Int. Ed. Engl., Vol. 36, pp. 1333-1335 (1997), etc. In an exemplary method, a compound represented by the general formula (10) below and a compound represented by the general formula (11) are heated in 1,2-dichloroethane in the presence of phosphorus oxychloride, and thereafter reacted with a compound represented by the general formula (12) below in 1,2-dichloroethane in the presence of triethylamine to give a compound represented by the general formula (1). However, the present invention is not limited thereto. Here, R¹ to R⁹ are the same as described hereinabove. J denotes a halogen.

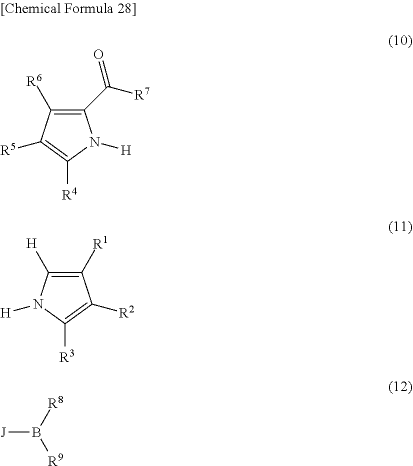

Furthermore, an aryl group or a heteroaryl group may be introduced by a method in which a carbon-carbon bond is formed using a coupling reaction of a halogenated derivative with a boronic acid or a boronate ester derivative. However, the present invention is not limited thereto. Similarly, an amino group or a carbazolyl group may be introduced by, for example, a method in which a carbon-nitrogen bond is formed using a coupling reaction of a halogenated derivative with an amine or a carbazole derivative in the presence of a metal catalyst such as palladium. However, the present invention is not limited thereto.

The compound represented by the general formula (1), when excited by excitation light, preferably shows emission having a peak wavelength observed in the region of not less than 500 nm and not more than 580 nm. Hereinbelow, the emission having a peak wavelength observed in the region of not less than 500 nm and not more than 580 nm is referred to as “green emission”.

The compound represented by the general formula (1) preferably shows green emission when excited by excitation light with a wavelength in the range of not less than 430 nm and not more than 500 nm. In general, the larger the energy of excitation light, the more likely the decomposition of a light-emitting material. However, excitation light with a wavelength in the range of not less than 430 nm and not more than 500 nm is of relatively small excitation energy. Thus, green emission with good color purity can be obtained without causing the decomposition of the light-emitting material in a color conversion composition.

The compound represented by the general formula (1), when excited by excitation light, preferably shows emission having a peak wavelength observed in the region of not less than 580 nm and not more than 750 nm. Hereinbelow, the emission having a peak wavelength observed in the region of not less than 580 nm and not more than 750 nm is referred to as “red emission”.

The compound represented by the general formula (1) preferably shows red emission when excited by excitation light with a wavelength in the range of not less than 430 nm and not more than 500 nm. In general, the larger the energy of excitation light, the more likely the decomposition of a light-emitting material. However, excitation light with a wavelength in the range of not less than 430 nm and not more than 500 nm is of relatively small excitation energy. Thus, red emission with good color purity can be obtained without causing the decomposition of the light-emitting material in a color conversion composition.

[symbol] Color Conversion Compositions

[symbol]

A color conversion composition according to an embodiment of the present invention will be described in detail. The color conversion composition according to an embodiment of the present invention converts incident light from an emitter such as a light source to light having a longer wavelength than the incident light, and preferably includes the compound (the pyrromethene boron complex) represented by the general formula (1) described hereinabove and a binder resin.

Where necessary, the color conversion composition according to an embodiment of the present invention may appropriately contain an additional compound other than the compound represented by the general formula (1). For example, the composition may contain an assist dopant such as rubrene in order to further enhance the energy transfer efficiency from the excitation light to the compound represented by the general formula (1). Furthermore, when it is desired to add an emission color other than the emission color of the compound represented by the general formula (1), a desired organic light-emitting material, for example, such an organic light-emitting material as a coumarin derivative or a rhodamine derivative, may be added. Furthermore, besides organic light-emitting materials, known light-emitting materials such as inorganic phosphors, fluorescent pigments, fluorescent dyes and quantum dots may be added in combination.

Some examples of the organic light-emitting materials other than the compounds represented by the general formula (1) are illustrated below, but the present invention is not particularly limited thereto.

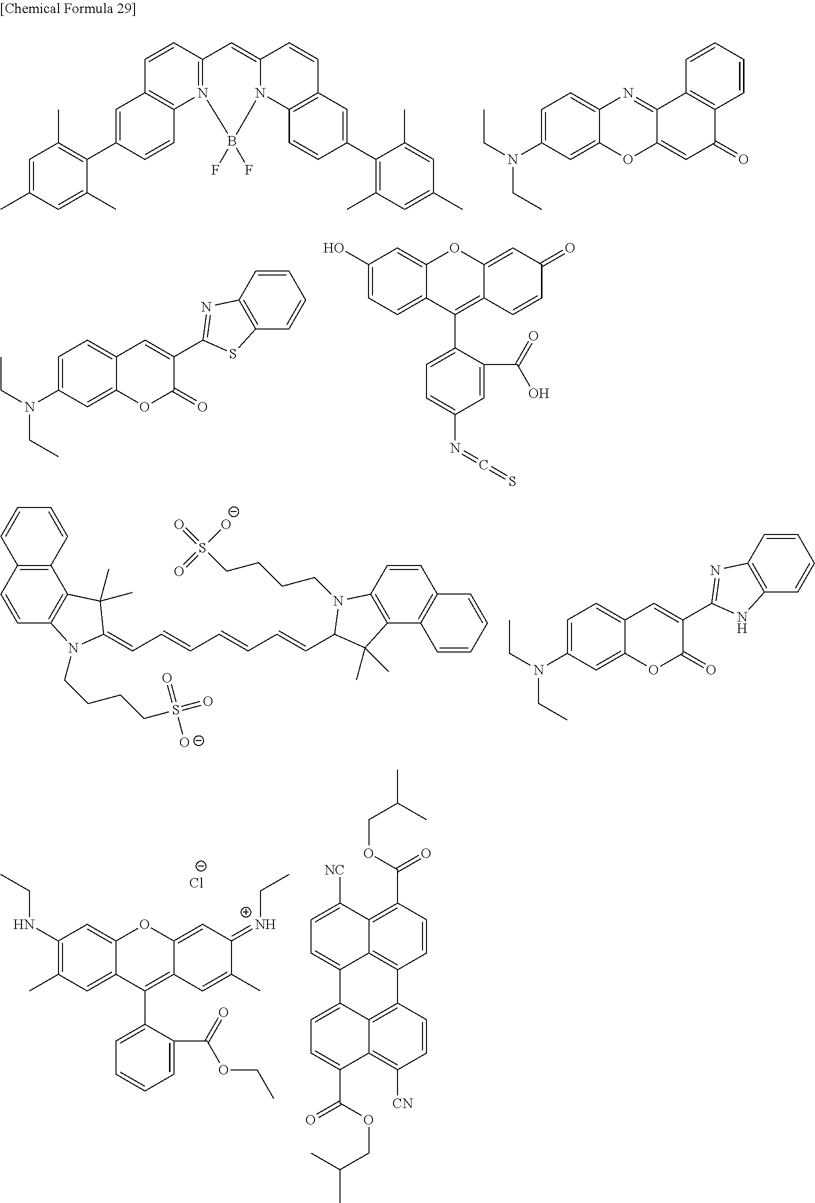

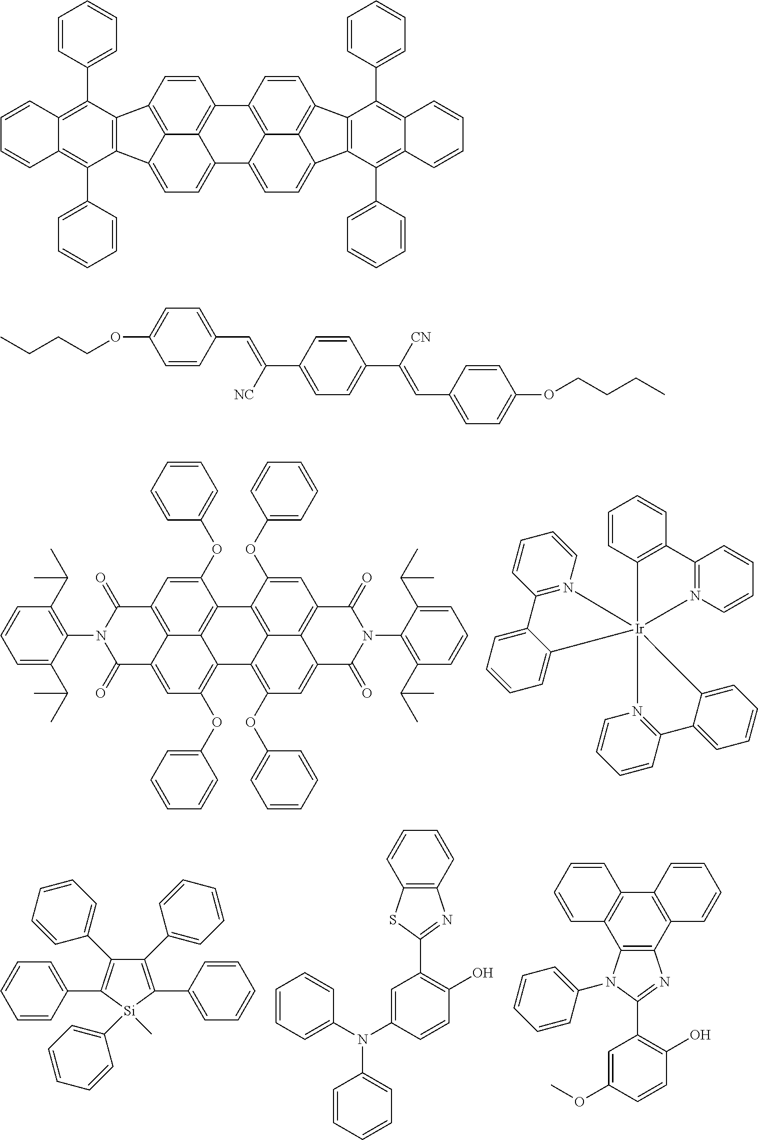

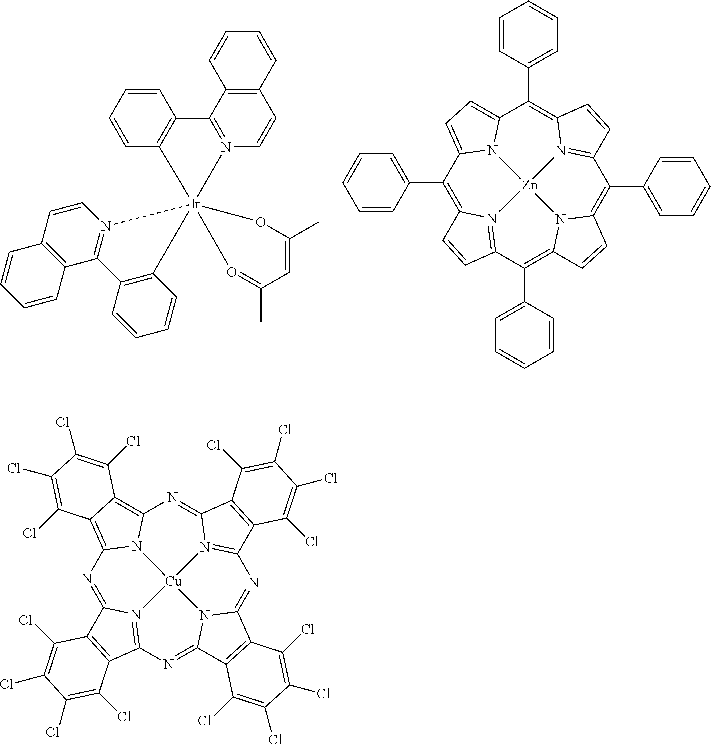

In the present invention, the color conversion composition, when excited by excitation light, preferably shows emission having a peak wavelength observed in the region of not less than 500 nm and not more than 580 nm. Furthermore, the color conversion composition, when excited by excitation light, preferably shows emission having a peak wavelength observed in the region of not less than 580 nm and not more than 750 nm.

That is, the color conversion composition according to an embodiment of the present invention preferably contains a light-emitting material (a) and a light-emitting material (b) described below. The light-emitting material (a) is a light-emitting material which, when excited by excitation light, shows emission having a peak wavelength observed in the region of not less than 500 nm and not more than 580 nm. The light-emitting material (b) is a light-emitting material which is excited by at least one of excitation light and the emission from the light-emitting material (a) to show emission having a peak wavelength observed in the region of not less than 580 nm and not more than 750 nm. At least one of the light-emitting material (a) and the light-emitting material (b) is preferably a compound (a pyrromethene boron complex) represented by the general formula (1). Furthermore, the excitation light used above is more preferably excitation light having a wavelength in the range of not less than 430 nm and not more than 500 nm.

Part of the excitation light having a wavelength in the range of not less than 430 nm and not more than 500 nm partially transmits through a color conversion film according to an embodiment of the present invention. Thus, when a blue LED having a sharp emission peak is used, blue, green, and red colors each have a sharp profile of emission spectrum to make it possible to obtain white light with good color purity. As a result, particularly in a display, more vivid colors and a larger color gamut can be efficiently produced. Furthermore, in illumination applications, emission characteristics particularly in the green region and the red region are improved compared with the currently prevailing white LED combining a blue LED and a yellow phosphor, and thus it is possible to obtain a favorable white light source with enhanced color-rendering property.

Preferred examples of the light-emitting materials (a) include coumarin derivatives such as coumarin 6, coumarin 7 and coumarin 153, cyanine derivatives such as indocyanine green, fluorescein derivatives such as fluorescein, fluorescein isothiocyanate and carboxyfluorescein diacetate, phthalocyanine derivatives such as phthalocyanine green, perylene derivatives such as diisobutyl-4,10-dicyanoperylene-3,9-dicarboxylate, pyrromethene derivatives, stilbene derivatives, oxazine derivatives, naphthalimide derivatives, pyrazine derivatives, benzimidazole derivatives, benzoxazole derivatives, benzothiazole derivatives, imidazopyridine derivatives, azole derivatives, compounds having a fused aryl ring such as anthracene and derivatives thereof, aromatic amine derivatives and organometal complex compounds. However, the light-emitting materials (a) are not particularly limited thereto. Of the above compounds, pyrromethene derivatives are particularly suitable because these compounds give a high emission quantum yield and exhibit emission with high color purity. Of the pyrromethene derivatives, those compounds represented by the general formula (1) are preferable because the durability is markedly enhanced.

Preferred examples of the light-emitting materials (b) include cyanine derivatives such as 4-dicyanomethylene-2-methyl-6-(p-dimethylaminostyryl)-4H-pyrane, rhodamine derivatives such as rhodamine B, rhodamine 6G, rhodamine 101 and sulforhodamine 101, pyridine derivatives such as 1-ethyl-2-(4-(p-dimethylaminophenyl)-1,3-butadienyl)-pyridinium-perchlorate, perylene derivatives such as N,N′-bis(2,6-diisopropylphenyl)-1,6,7,12-tetraphenoxyperylene-3,4:9,10-bisdicarboimide, porphyrin derivatives, pyrromethene derivatives, oxazine derivatives, pyrazine derivatives, compounds having a fused aryl ring such as naphthacene and dibenzodiindenoperylene and derivatives thereof, and organometal complex compounds. However, the light-emitting materials (b) are not particularly limited thereto. Of the above compounds, pyrromethene derivatives are particularly suitable because these compounds give a high emission quantum yield and exhibit emission with high color purity. Of the pyrromethene derivatives, those compounds represented by the general formula (1) are preferable because the durability is significantly enhanced.

Furthermore, the light-emitting material (a) and the light-emitting material (b) are preferably both compounds represented by the general formula (1) because highly efficient emission, high color purity and high durability can be concurrently satisfied.

The content of the compound represented by the general formula (1) in the color conversion composition according to an embodiment of the present invention is variable depending on the molar absorption coefficient, emission quantum yield and absorption intensity at the excitation wavelength of the compound and also depending on the thickness and transmittance of a film that is formed, but is usually 1.0×10⁻⁴ parts by weight to 30 parts by weight with respect to 100 parts by weight of the binder resin. The content of the compound is more preferably 1.0×10⁻³ parts by weight to 10 parts by weight, and particularly preferably 1.0×10⁻² parts by weight to 5 parts by weight with respect to 100 parts by weight of the binder resin.

Furthermore, when the color conversion composition contains both a light-emitting material (a) showing green emission and a light-emitting material (b) showing red emission, part of the green emission is converted to red emission. In view of this, the content wₐ of the light-emitting material (a) and the content w_{b} of the light-emitting material (b) preferably satisfy the relation wₐ w_{b}. Furthermore, the ratio of the content of the light-emitting material (a) to the content of the light-emitting material (b) is wₐ: wb=1000:1 to 1:1, more preferably 500:1 to 2:1, and particularly preferably 200:1 to 3:1. Here, the content wₐ and the content w_{b} are weight percentages relative to the weight of the binder resin.

[symbol] Binder Resins

[symbol]

The binder resin may be any material which forms a continuous phase and is excellent in properties such as formability, transparency and heat resistance. Examples of the binder resins include known resins, for example, photocurable resist materials having a reactive vinyl group such as acrylic acid-based resins, methacrylic acid-based resins, polyvinyl cinnamate-based resins and cyclic rubber-based resins, epoxy resins, silicone resins (including cured (crosslinked) organopolysiloxanes such as silicone rubbers and silicone gels), urea resins, fluororesins, polycarbonate resins, acrylic resins, urethane resins, melamine resins, polyvinyl resins, polyamide resins, phenol resins, polyvinyl alcohol resins, cellulose resins, aliphatic ester resins, aromatic ester resins, aliphatic polyolefin resins and aromatic polyolefin resins. Furthermore, copolymer resins of the above resins are also usable as the binder resins. By appropriately designing the resins described above, a binder resin useful in the color conversion composition and the color conversion film according to an embodiment of the present invention may be obtained. Of the above resins, thermoplastic resins are more preferable because the film-forming process is facilitated. Of the thermosetting resins, epoxy resins, silicone resins, acrylic resins, ester resins, olefin resins, or mixtures thereof may be suitably used from the points of view of transparency, heat resistance, etc.

Furthermore, from the point of view of durability, particularly preferred thermoplastic resins are acrylic resins, ester resins and cycloolefin resins.

Furthermore, additives may be added to the binder resin. For example, there may be added a dispersant, a leveling agent, etc. to stabilize coatings, or a film surface modifier, for example, an adhesion aid such as a silane coupling agent. Furthermore, inorganic particles such as silica particles or silicone microparticles may also be added as a color conversion material precipitation inhibitor to the binder resin.

Furthermore, from the point of view of heat resistance, the binder resin is particularly preferably a silicone resin. Of the silicone resins, addition reaction-curable silicone compositions are preferable. An addition reaction-curable silicone composition is cured at room temperature or by being heated at a temperature of 50° C. to 200° C., and is excellent in transparency, heat resistance and adhesion. An example of the addition reaction-curable silicone compositions is formed by the hydrosilylation reaction of a compound which contains an alkenyl group bonded to a silicon atom, with a compound which has a hydrogen atom bonded to a silicon atom. Of these materials, examples of the “compound which contains an alkenyl group bonded to a silicon atom” include, for example, vinyltrimethoxysilane, vinyltriethoxysilane, allyltrimethoxysilane, propenyltrimethoxysilane, norbornenyltrimethoxysilane and octenyltrimethoxysilane. Examples of the “compound which has a hydrogen atom bonded to a silicon atom” include, for example, methyl hydrogen polysiloxane, dimethyl polysiloxane-CO-methyl hydrogen polysiloxane, ethyl hydrogen polysiloxane, and methyl hydrogen polysiloxane-CO-methyl phenyl polysiloxane.

Furthermore, other known materials such as those described in, for example, Japanese Patent Application Laid-open No. 2010-159411 may also be used as the addition reaction-curable silicone compositions.

Furthermore, commercially available addition reaction-curable silicone compositions, for example, general LED silicone sealants may also be used. Specific examples thereof include OE-6630A/B and OE-6336A/B each manufactured by Dow Corning Toray Co., Ltd., and SCR-1012A/B and SCR-1016A/B each manufactured by Shin-Etsu Chemical Co., Ltd.

In the color conversion composition for forming a color conversion film according to an embodiment of the present invention, the binder resin preferably includes an additional component which is a hydrosilylation reaction retarder such as acetylene alcohol for the purpose of inhibiting curing at room temperature to extend the pot life. Furthermore, where necessary, the binder resin may include, for example, microparticles such as fumed silica, glass powder or quartz powder, an inorganic filler or a pigment such as titanium oxide, zirconia oxide, barium titanate or zinc oxide, a flame retardant, a heat-resistant agent, an antioxidant, a dispersant, a solvent, or a tackifier such as a silane coupling agent or a titanium coupling agent, without impairing the advantageous effects of the present invention.

In particular, from the point of view of the surface smoothness of color conversion films, it is preferable to add a low-molecular polydimethylsiloxane component, a silicone oil, etc. to the composition for forming color conversion films. Such a component is preferably added at 100 ppm to 2000 ppm, and more preferably added at 500 ppm to 1000 ppm relative to the whole of the composition.

[symbol] Additional Components

[symbol]

The color conversion composition according to an embodiment of the present invention may include, in addition to the compound represented by the general formula (1) and the binder resin described hereinabove, additional components (additives) such as light stabilizers, antioxidants, processing heat stabilizers, lightfastness stabilizers including UV absorbers, silicone microparticles and silane coupling agents.

Examples of the light stabilizers include, for example, tertiary amines, catechol derivatives and nickel compounds, but are not particularly limited thereto. Furthermore, these light stabilizers may be used singly, or a plurality thereof may be used in combination.

Examples of the antioxidants include, for example, phenol-based antioxidants such as 2,6-di-tert-butyl-p-cresol and 2,6-di-tert-butyl-4-ethylphenol, but are not particularly limited thereto. Furthermore, these antioxidants may be used singly, or a plurality thereof may be used in combination.

Examples of the processing heat stabilizers include, for example, phosphorus-based stabilizers such as tributyl phosphite, tricyclohexyl phosphite, triethylphosphine and diphenylbutylphosphine, but are not particularly limited thereto. Furthermore, these stabilizers may be used singly, or a plurality thereof may be used in combination.

Examples of the lightfastness stabilizers include, for example, benzotriazoles such as 2-(5-methyl-2-hydroxyphenyl)benzotriazole and 2-[2-hydroxy-3,5-bis(α,α-dimethylbenzyl)phenyl]-2H-benzotriazole, but are not particularly limited thereto. Furthermore, these lightfastness stabilizers may be used singly, or a plurality thereof may be used in combination.

In the color conversion composition according to an embodiment of the present invention, the content of these additives may vary depending on the molar absorption coefficient, emission quantum yield and absorption intensity at the excitation wavelength of the compound and also depending on the thickness and transmittance of a color conversion film that is formed, but is usually preferably not less than 1.0×10⁻³ parts by weight and not more than 30 parts by weight with respect to 100 parts by weight of the binder resin. Furthermore, the content of the additives is more preferably not less than 1.0×10⁻² parts by weight and not more than 15 parts by weight, and particularly preferably not less than 1.0×10⁻¹ parts by weight and not more than 10 parts by weight with respect to 100 parts by weight of the binder resin.

[symbol] Solvents

[symbol]

The color conversion composition according to an embodiment of the present invention may contain a solvent. The solvent is not particularly limited as long as it can adjust the viscosity of the resin in the fluid state and does not excessively adversely affect the emission and durability of the light-emitting substance. Examples of the solvents include, for example, toluene, methyl ethyl ketone, methyl isobutyl ketone, hexane, acetone, terpineol, texanol, methyl cellosolve, butyl carbitol, butyl carbitol acetate and propylene glycol monomethyl ether acetate. A mixture of two or more kinds of these solvents may be used. Of these solvents, toluene is particularly suitably used because it does not affect the degradation of the compound represented by the general formula (1) and dries with little residual solvent.

[symbol] Methods for Producing Color Conversion Compositions

[symbol]

An example of the methods for producing the color conversion composition according to an embodiment of the present invention is described below. In this production method, predetermined amounts of the components such as the compound represented by the general formula (1), the binder resin and the solvent described above are mixed together. After these components are mixed together with the predetermined composition, the mixture is homogeneously mixed and dispersed by the use of a stirring kneading device such as a homogenizer, a rotation-revolution stirrer, a three-roll mill, a ball mill, a planetary ball mill or a bead mill, thereby giving a color conversion composition.

It is preferable to perform degassing under vacuum or reduced pressure conditions after the mixing and dispersing process or during the mixing and dispersing process. Furthermore, some specific components may be mixed together beforehand or may be subjected to treatment such as aging. The solvent may be removed with an evaporator to control the solid concentration to a desired level.

[symbol] Methods for Preparing Color Conversion Films

[symbol]

In the present invention, the configuration of a color conversion film is not limited as long as the film includes a layer including the color conversion composition described hereinabove, or a layer including a cured product obtained by curing the composition. A cured product of the color conversion composition, when contained in the color conversion film, is preferably a layer obtained by curing the color conversion composition (a layer including a cured product of the color conversion composition). For example, typical structural examples of the color conversion films include those four structures described below.

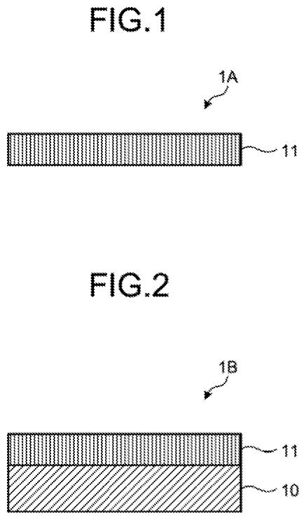

FIG. 1 is a schematic sectional view illustrating a first example of the color conversion films according to an embodiment of the present invention. As illustrated in FIG. 1, a color conversion film 1A of the first example is a monolayer film composed of a color conversion layer 11. The color conversion layer 11 is a layer including a cured product of the color conversion composition described hereinabove.

FIG. 2 is a schematic sectional view illustrating a second example of the color conversion films according to an embodiment of the present invention. As illustrated in FIG. 2, a color conversion film 1B of the second example is a stack including a substrate layer 10 and a color conversion layer 11. In the structural example of the color conversion film 1B, the color conversion layer 11 is stacked on the substrate layer 10.

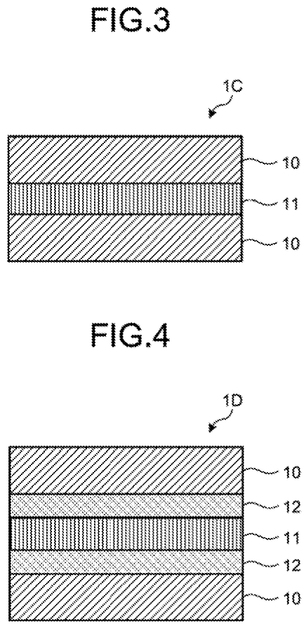

FIG. 3 is a schematic sectional view illustrating a third example of the color conversion films according to an embodiment of the present invention. As illustrated in FIG. 3, a color conversion film 1C of the third example is a stack including a plurality of substrate layers 10, and a color conversion layer 11. In the structural example of the color conversion film 1C, the color conversion layer 11 is sandwiched between the substrate layers 10.

FIG. 4 is a schematic sectional view illustrating a fourth example of the color conversion films according to an embodiment of the present invention. As illustrated in FIG. 4, a color conversion film 1D of the fourth example is a stack including a plurality of substrate layers 10, a color conversion layer 11, and a plurality of barrier films 12. In the structural example of the color conversion film 1D, the color conversion layer 11 is sandwiched between the barrier films 12, and the stack of the color conversion layer 11 and the barrier films 12 is further sandwiched between the substrate layers 10. That is, as illustrated in FIG. 4, the color conversion film 1D may have barrier films 12 to prevent degradation of the color conversion layer 11 by oxygen, water or heat.

[symbol] Substrate Layers

[symbol]

The substrate layers (for example, the substrate layers 10 illustrated in FIGS. 2 to 4) are not particularly limited and may be any known materials such as metals, films, glasses, ceramics and papers. Specific examples of the substrate layers include metal sheets or foils such as aluminum (including aluminum alloys), zinc, copper and iron, films of plastics such as cellulose acetates, polyethylene terephthalates (PET), polyethylenes, polyesters, polyamides, polyimides, polyphenylene sulfides, polystyrenes, polypropylenes, polycarbonates, polyvinylacetals, aramids, silicones, polyolefins, thermoplastic fluororesins and tetrafluoroethylene-ethylene copolymers (ETFE), films of plastics including α-polyolefin resins, polycaprolactone resins, acrylic resins, silicone resins, and copolymer resins of these resins with ethylene, papers laminated with the above plastics, papers coated with the above plastics, papers laminated or deposited with the above metals, and plastic films laminated or deposited with the above metals. Furthermore, when the substrate layer is a metal sheet, the surface thereof may be plated with chromium-based metal, nickel-based metal or the like, or may be coated with a ceramic.

Of these, in view of easy preparation of the color conversion films and easy forming of the color conversion films, glasses or resin films are preferably used. Furthermore, it is preferable that the films be of high strength so that the film-shaped substrate layers are handled without the risk of rupture or the like. In view of such characteristics that are required and economic efficiency, resin films are preferable, and, in particular, plastic films selected from the group consisting of PET, polyphenylene sulfides, polycarbonates and polypropylenes are preferable in view of economic efficiency and handleability. Furthermore, polyimide films are preferable in view of heat resistance when the color conversion films are dried or the color conversion films are contact bonded at a high temperature of 200° C. or above using an extruder. To facilitate the separation of the film, the surface of the substrate layer may be release treated beforehand.

The thickness of the substrate layer is not particularly limited, but the lower limit thereof is preferably not less than 25 μm, and more preferably not less than 38 μm. Furthermore, the upper limit thereof is preferably not more than 5000 μm, and more preferably not more than 3000 μm.

(Color Conversion Layers)

Next, an example of the methods for producing the color conversion layer in the color conversion film according to an embodiment of the present invention is described. In the method for producing the color conversion layer, a color conversion composition prepared by the method described hereinabove is applied onto a base such as a substrate layer or a barrier film, and is dried. In this manner, color conversion layers (for example, the color conversion layers 11 illustrated in FIGS. 1 to 4) are formed. The application may be performed with a reverse roll coater, a blade coater, a slit die coater, a direct gravure coater, an offset gravure coater, a kiss coater, a natural roll coater, an air knife coater, a roll blade coater, a reverse roll blade coater, a two-stream coater, a rod coater, a wire bar coater, an applicator, a dip coater, a curtain coater, a spin coater, a knife coater, etc. In order to obtain uniformity in the film thickness of the color conversion layer, the composition is preferably applied with a slit die coater.

The color conversion layer may be dried using a general heating device such as a hot air drier or an infrared drier. For the heating of the color conversion film, a general heating device such as a hot air drier or an infrared drier is used. In this case, the heating conditions are usually 40° C. to 250° C. and 1 minute to 5 hours, and preferably 60° C. to 200° C. and 2 minutes to 4 hours. Furthermore, it is also possible to perform stepwise heating and curing such as step-curing.

After the color conversion layer is prepared, the substrate layer may be changed as necessary. In this case, for example, the exchange may be performed simply using a hot plate or using a vacuum laminator or a dry film laminator, although not limited thereto.

The thickness of the color conversion layer is not particularly limited, but is preferably 10 μm to 1000 μm. If the thickness of the color conversion layer is less than 10 μm, a problem arises that the toughness of the color conversion film is lowered. If the thickness of the color conversion layer is more than 1000 μm, the color conversion film is cracked easily and is difficult to form into a shape. The thickness of the color conversion layer is more preferably 30 μm to 100 μm.

On the other hand, from the point of view of increasing the heat resistance of the color conversion film, the film thickness of the color conversion film is preferably not more than 200 μm, more preferably not more than 100 μm, and still more preferably not more than 50 μm.

The film thickness of the color conversion film in the present invention indicates the film thickness (the average film thickness) measured based on JIS K7130 (1999), Plastics-Film and sheeting-Determination of thickness, Measurement Method A for measuring thickness by mechanical scanning.

(Barrier Films)

Barrier films (for example, the barrier films 12 illustrated in FIG. 4) are used appropriately in order to, for example, impart enhanced gas barrier properties to the color conversion layer. Examples of the barrier films include, for example, films including inorganic oxides such as silicon oxide, aluminum oxide, titanium oxide, tantalum oxide, zinc oxide, tin oxide, indium oxide, yttrium oxide and magnesium oxide, inorganic nitrides such as silicon nitride, aluminum nitride, titanium nitride and silicon carbonitride, mixtures thereof, metal oxide thin films and metal nitride thin films obtained by adding additional elements to the above materials, and various resins such as polyvinylidene chlorides, acrylic resins, silicon-based resins, melamine-based resins, urethane-based resins, fluororesins and polyvinyl alcohol-based resins including saponified vinyl acetate. Furthermore, examples of the barrier films having a barrier function against water include, for example, films including various resins such as polyethylenes, polypropylenes, nylons, polyvinylidene chlorides, vinylidene chloride-vinyl chloride copolymers, vinylidene chloride-acrylonitrile copolymers, fluororesins and polyvinyl alcohol-based resins including saponified vinyl acetate.

The barrier films may be provided on both sides of the color conversion layer 11 as is the case for the barrier films 12 illustrated in FIG. 4, or may be disposed only on one side of the color conversion layer 11. Furthermore, an auxiliary layer having an antireflection function, an antiglare function, an antireflection-antiglare function, a hardcoat function (an anti-friction function), an antistatic function, an antifouling function, an electromagnetic wave shielding function, an infrared cutting function, an ultraviolet cutting function, a polarizing function or a toning function may be further provided in accordance with the function required of the color conversion film.

[symbol] Excitation Light

[symbol]

The excitation light may be any type of excitation light as long as the light has a wavelength in a region where a mixture of light-emitting substances including the compound represented by the general formula (1) can exhibit absorption to emit light. In principle, any excitation light may be used, for example, light from fluorescent light sources such as hot cathode tubes, cold cathode tubes and inorganic electroluminescence (EL), organic EL device light sources, LED light sources and incandescent light sources, sunlight, etc. In particular, light from an LED light source is suitable excitation light. In displays and illumination applications, light from a blue LED light source having excitation light in the wavelength range of 430 nm to 500 nm is more suitable excitation light for the reason that the color purity of blue light can be enhanced.

The excitation light may be light having a single kind of emission peak or light having two or more kinds of emission peaks. In order to increase the color purity, light having a single kind of emission peak is preferable. Furthermore, it is possible to use an appropriate combination of a plurality of excitation light sources having different kinds of emission peaks.

[symbol] Light Source Units

[symbol]

A light source unit according to an embodiment of the present invention includes at least a light source and the color conversion film described above. The light source and the color conversion film may be arranged in any manner without limitation. The configuration may be such that the light source and the color conversion film are in close contact with each other, or may be a remote phosphor system in which the light source and the color conversion film are separated from each other. Furthermore, the light source unit may be configured to further include a color filter for the purpose of increasing the color purity.

As already mentioned, excitation light with a wavelength in the range of 430 nm to 500 nm is of relatively small excitation energy and thus the decomposition of light-emitting substances such as the compound represented by the general formula (1) can be prevented. Thus, the light source used in the light source unit is preferably a light-emitting diode having a maximum emission in the wavelength range of not less than 430 nm and not more than 500 nm. Furthermore, this light source preferably has a maximum emission in the wavelength range of not less than 440 nm and not more than 470 nm.

Furthermore, it is preferable that the light source be a light-emitting diode having an emission wavelength peak in the range of 430 nm to 470 nm and having an emission wavelength region in the range of 400 nm to 500 nm, and the emission spectrum of the light-emitting diode satisfy the mathematical expression (f2).

[MATHEMATICAL EXPRESSION 1]

1>β/α≥0.15 (f2)

In the mathematical expression (f2), α is the emission intensity at the emission wavelength peak in the emission spectrum, and β is the emission intensity at the emission wavelength peak plus 15 nm wavelength.

The light source units in the present invention may be used in applications such as displays, illumination, interiors, indicators and signboards, and are particularly suitably used in displays and illumination applications.

[symbol] Displays and Illumination Apparatuses

[symbol]

A display according to an embodiment of the present invention includes at least the color conversion film described above. When, for example, the display is a liquid crystal display or the like, the light source unit described above which includes the light source, the color conversion film, etc. is used as a backlight unit. Furthermore, an illumination apparatus according to an embodiment of the present invention includes at least the color conversion film described above. For example, this illumination apparatus is configured to emit white light by including a light source unit that is a combination of a blue LED light source and the color conversion film which converts the blue light from the blue LED light source into light with a longer wavelength.

[symbol] Light-Emitting Devices

[symbol]

A light-emitting device according to an embodiment of the present invention is a light-emitting device which emits light using electric energy, and is preferably, for example, an organic thin film light-emitting device. More specifically, the light-emitting device includes an anode, a cathode, and an organic layer disposed between the anode and the cathode. The organic layer contains the compound (the pyrromethene boron complex) represented by the general formula (1) described hereinabove. For example, it is preferable that the organic layer include at least an emission layer and an electron transport layer, and the emission layer include the pyrromethene boron complex described hereinabove. This light-emitting device is preferably a light-emitting device which emits light from the organic layer, in particular the emission layer, using electric energy.

In the light-emitting device according to an embodiment of the present invention, the organic layer is a stack including at least an emission layer and an electrical transport layer. An exemplary stack structure of the organic layer is a stack structure composed of an emission layer and an electron transport layer (emission layer/electron transport layer). Furthermore, in addition to the stack structure consisting solely of emission layer/electron transport layer, other exemplary stack structures of the organic layers include the following first to third stack structures. Examples of the first stack structures include, for example, structures in which a hole transport layer, an emission layer and an electron transport layer are stacked (hole transport layer/emission layer/electron transport layer). Examples of the second stack structures include, for example, structures in which a hole transport layer, an emission layer, an electron transport layer and an electron injection layer are stacked (hole transport layer/emission layer/electron transport layer/electron injection layer). Examples of the third stack structures include, for example, structures in which a hole injection layer, a hole transport layer, an emission layer, an electron transport layer and an electron injection layer are stacked (hole injection layer/hole transport layer/emission layer/electron transport layer/electron injection layer). Furthermore, each type of the layers may include a single layer or a plurality of layers. Furthermore, the light-emitting device according to the present embodiment may be a stack type including a plurality of phosphorescent emission layers or fluorescent emission layers in the organic layer, or may be a light-emitting device combining a fluorescent emission layer and a phosphorescent emission layer. Furthermore, in the organic layer in this light-emitting device, a plurality of emission layers differing in the color of emissions may be stacked together.

Furthermore, the light-emitting device according to the present embodiment may be of a tandem type in which a plurality of the stacks described above are stacked through an intermediate layer. In the stack structure of such a tandem-type light-emitting device, at least one layer is preferably a phosphorescent emission layer. The intermediate layer is generally also called an intermediate electrode, an intermediate conductive layer, a charge generating layer, an electron withdrawing layer, a connection layer or an intermediate insulating layer. The intermediate layer may be a layer of known material configuration. Specific examples of the stack structures of the tandem-type light-emitting devices include, for example, stack structures which include a charge generating layer as an intermediate layer between an anode and a cathode, as is the case in the following fourth and fifth stack structures. Examples of the fourth stack structures include, for example, stack structures including hole transport layer/emission layer/electron transport layer, a charge generating layer, and hole transport layer/emission layer/electron transport layer (hole transport layer/emission layer/electron transport layer/charge generating layer/hole transport layer/emission layer/electron transport layer). Examples of the fifth stack structures include, for example, stack structures including hole injection layer/hole transport layer/emission layer/electron transport layer/electron injection layer, a charge generating layer, and hole injection layer/hole transport layer/emission layer/electron transport layer/electron injection layer (hole injection layer/hole transport layer/emission layer/electron transport layer/electron injection layer/charge generating layer/hole injection layer/hole transport layer/emission layer/electron transport layer/electron injection layer). Specifically, pyridine derivatives and phenanthroline derivatives are preferably used as materials which constitute the intermediate layers.

The pyrromethene boron complex according to an embodiment of the present invention may be used in any organic layer in the stack structure of the light-emitting device described above, but is preferably used in an emission layer of the light-emitting device on account of the fact that it has a high emission quantum yield.

(Emission Layers)

The emission layer included in the light-emitting device according to the present embodiment may be a single layer or a plurality of layers and, in both cases, is formed of a light-emitting material (host material, dopant material). The light-emitting material forming the emission layer may be a mixture of a host material and a dopant material, or may be a host material alone.

Furthermore, the host material and the dopant material may be each a single material or a combination of materials. The dopant material may be included throughout the entirety of the host material, or may be included partially in the host material. The dopant material may be stacked on or dispersed in the host material. An emission layer including a mixture of a host material and a dopant material may be formed by a method in which the host material and the dopant material are co-deposited, or a method in which the host material and the dopant material are mixed together beforehand and then deposited.

Specifically, some light-emitting materials which may be used in the emission layers are those conventionally known as emitters, including fused ring derivatives such as anthracene and pyrene, metal chelated oxinoid compounds such as tris(8-quinolinolato)aluminum, bisstyryl derivatives such as bisstyrylanthracene derivatives and distyrylbenzene derivatives, dibenzofuran derivatives, carbazole derivatives and indolocarbazole derivatives. However, the light-emitting materials are not particularly limited thereto.

Examples of the host materials include, although not limited to, compounds having a fused aryl ring and derivatives thereof such as naphthalene, anthracene, phenanthrene, pyrene, chrysene, naphthacene, triphenylene, perylene, fluoranthene, fluorene and indene. Of these, anthracene derivatives and naphthacene derivatives are particularly preferable as the host materials.

Examples of the dopant materials include, although not limited to, compounds having a fused aryl ring such as naphthalene, anthracene, phenanthrene, pyrene, chrysene, triphenylene, perylene, fluoranthene, fluorene and indene, and derivatives thereof (for example, 2-(benzothiazol-2-yl)-9,10-diphenylanthracene and 5,6,11,12-tetraphenylnaphthacene), aminostyryl derivatives such as 4,4′-bis(2-(4-diphenylaminophenyl)ethenyl)biphenyl and 4,4′-bis(N-(stilben-4-yl)-N-phenylamino)stilbene, pyrromethene derivatives, and aromatic amine derivatives represented by N,N′-diphenyl-N,N′-di(3-methylphenyl)-4,4′-diphenyl-1,1′-diamine.

Furthermore, the emission layer according to the present embodiment may include a phosphorescent material. A phosphorescent material is a material that shows phosphorescent emission even at room temperature. When a phosphorescent material is used as a dopant material, phosphorescent emission needs to be basically obtained even at room temperature. As long as this phosphorescent emission is obtained, the phosphorescent material as a dopant material is not particularly limited. For example, the phosphorescent material is preferably an organometal complex compound containing at least one metal selected from the group consisting of iridium (Ir), ruthenium (Ru), rhodium (Rh), palladium (Pd), platinum (Pt), osmium (Os) and rhenium (Re). In particular, an organometal complex containing iridium or platinum is more preferable from the point of view of the fact that it has a high phosphorescent emission yield even at room temperature.

The pyrromethene boron complex according to an embodiment of the present invention has high emission performance and thus may be used as a light-emitting material in the light-emitting device described above. The pyrromethene boron complex according to an embodiment of the present invention shows strong emission in the green to red wavelength region (500 nm to 750 nm wavelength region), and thus may be suitably used as a green and red light-emitting material. The pyrromethene boron complex according to an embodiment of the present invention has high emission quantum yield, and thus may be suitably used as a dopant material in the emission layer described above.

The light-emitting device according to an embodiment of the present invention is also preferably used as a backlight in various apparatuses and the like. This backlight is used mainly for the purpose of enhancing the visibility of display devices which are not self-luminous, and is used in, for example, liquid crystal display devices, clocks and watches, audio devices, automobile panels, display panels, signs, etc. In particular, the light-emitting device of the present invention is preferably used as a backlight in such display applications as liquid crystal display devices, particularly personal computers heading for slimmer profile. Thus, the light-emitting device of the present invention can provide a backlight that is slimmer and more lightweight than the conventional backlights.

### EXAMPLES

The present invention will be described based on Examples hereinbelow, but the present invention is not limited by Examples presented below. In Examples and Comparative Examples below, Compounds G-1 to G-38, G-101 to G-108, R-1 to R-5, and R-101 to R-106 are the compounds illustrated below.

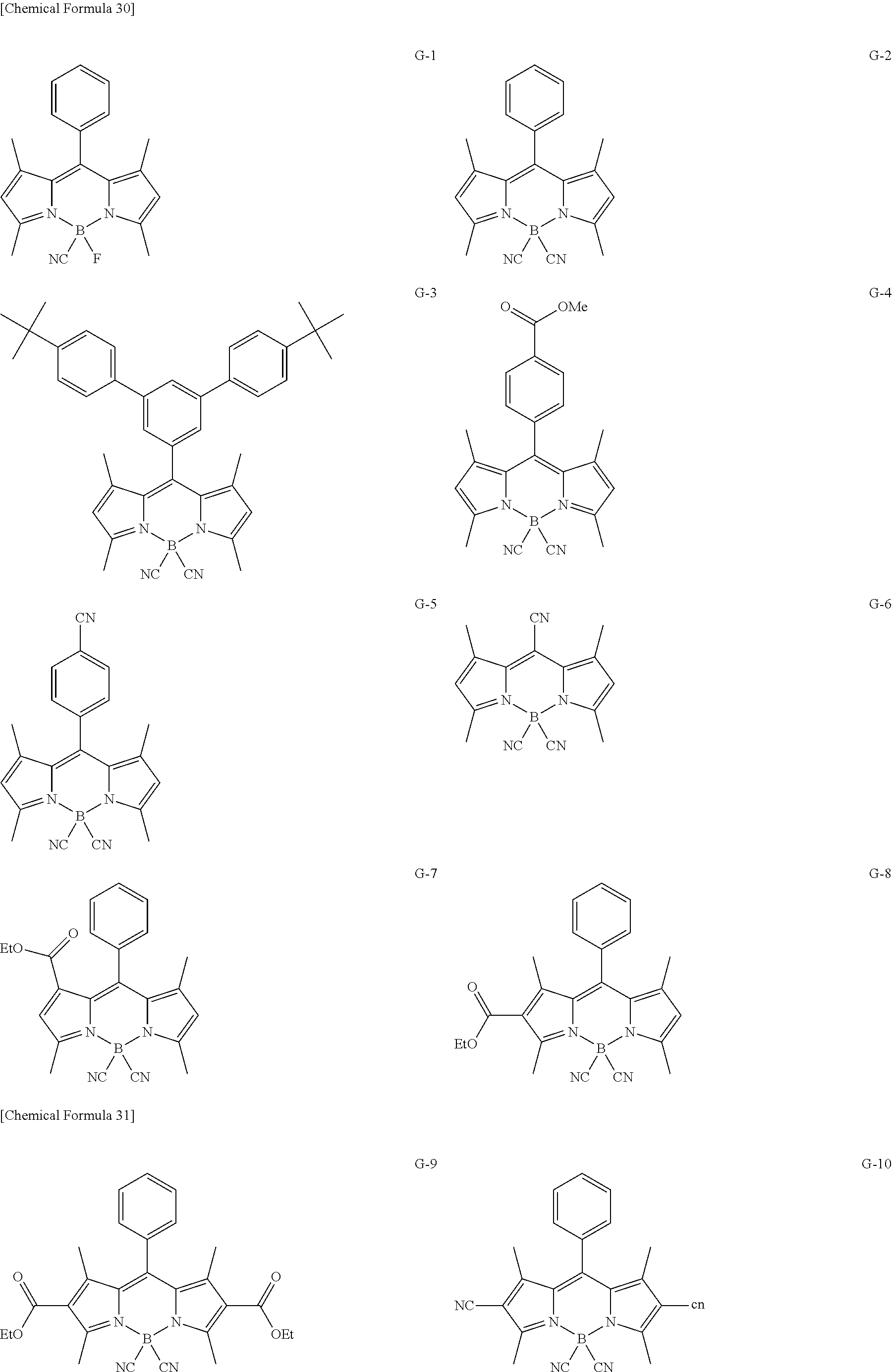

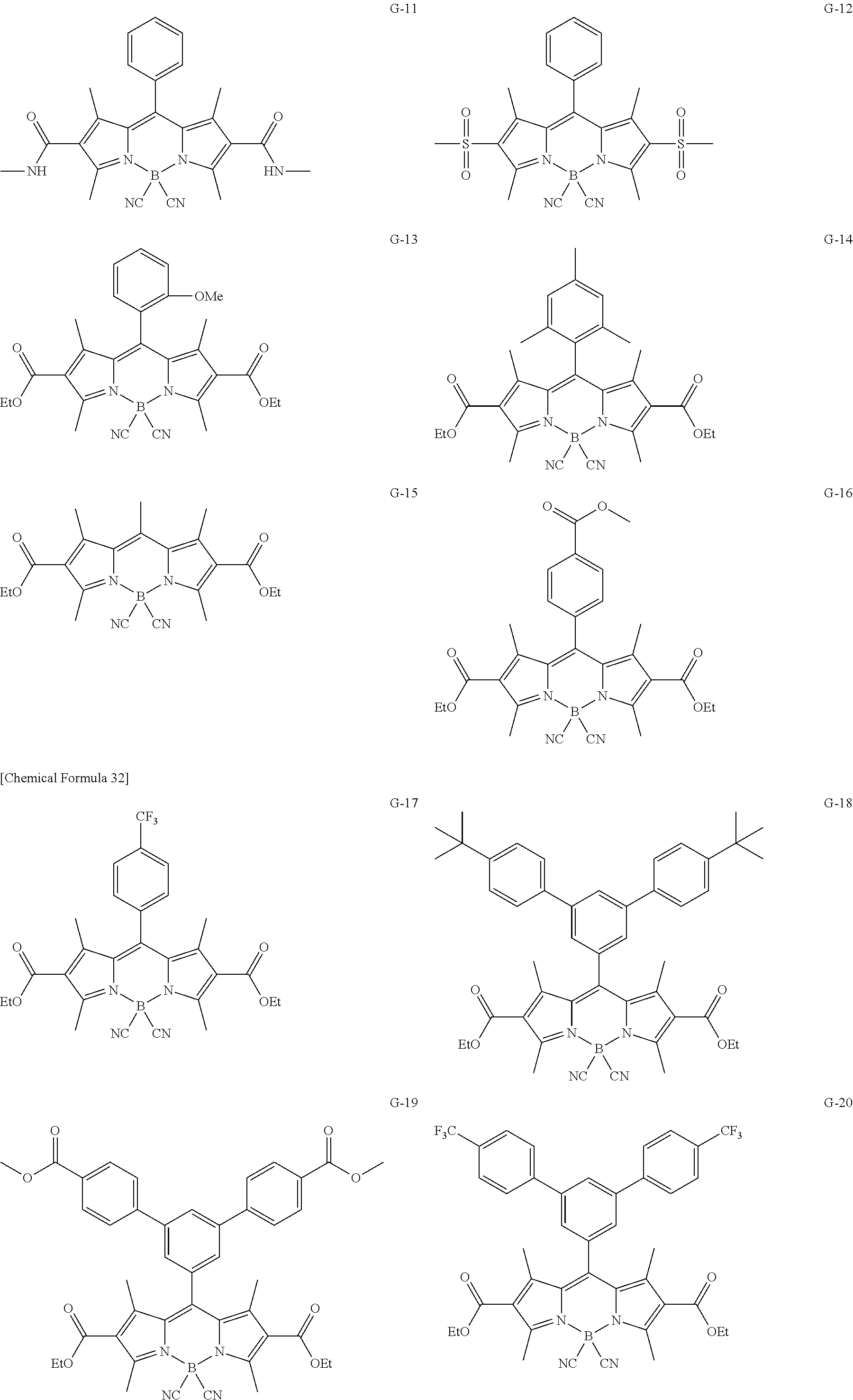

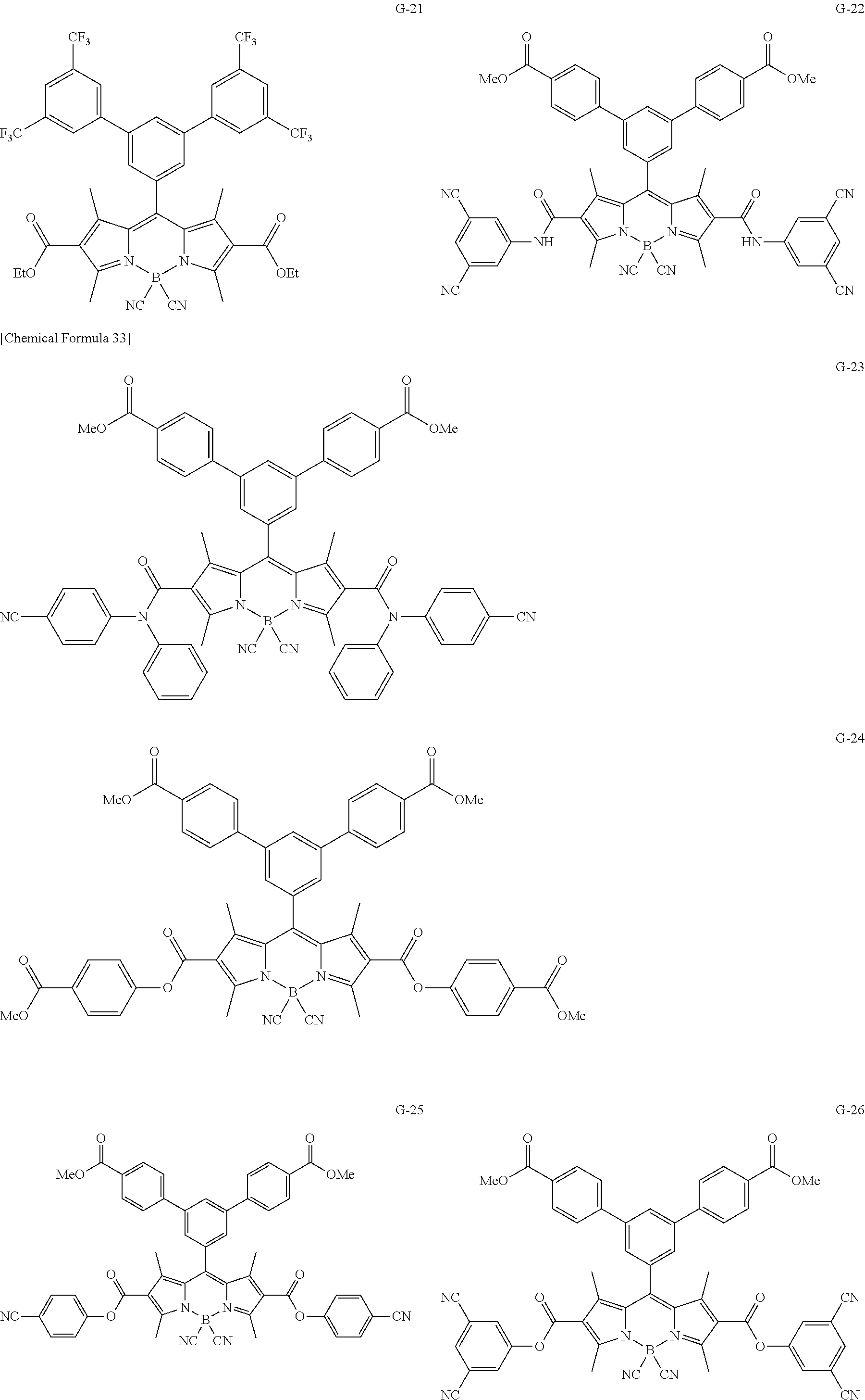

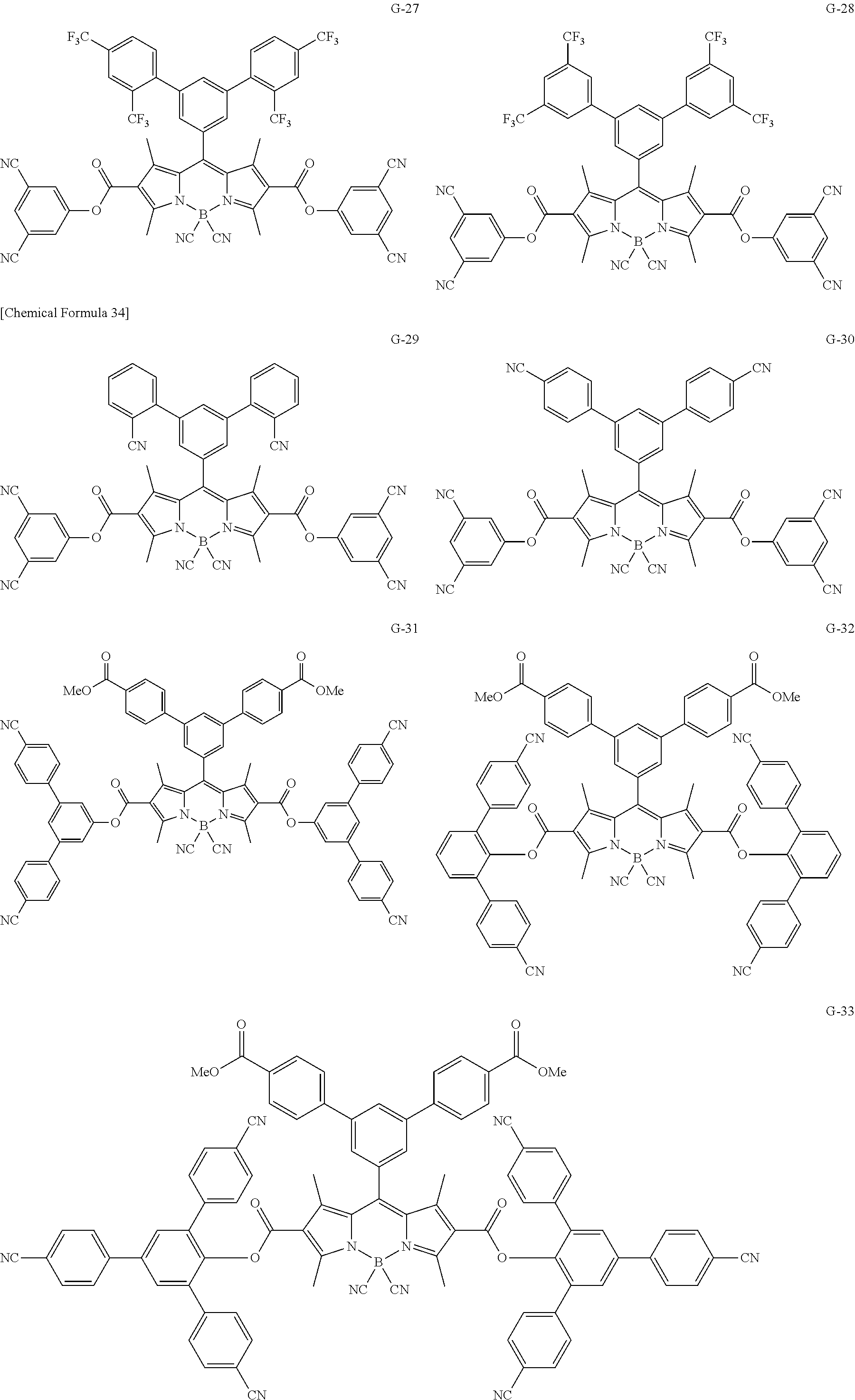

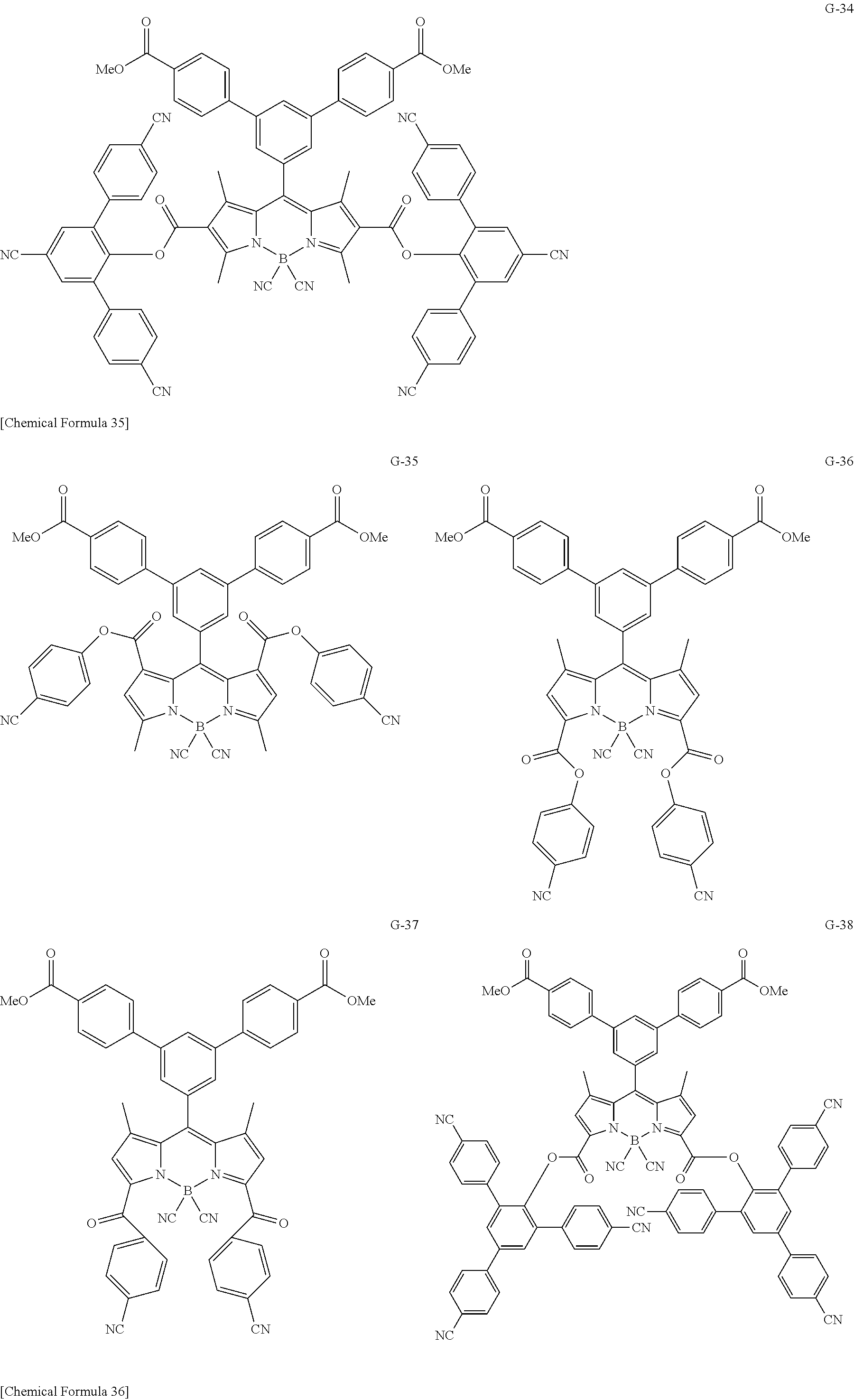

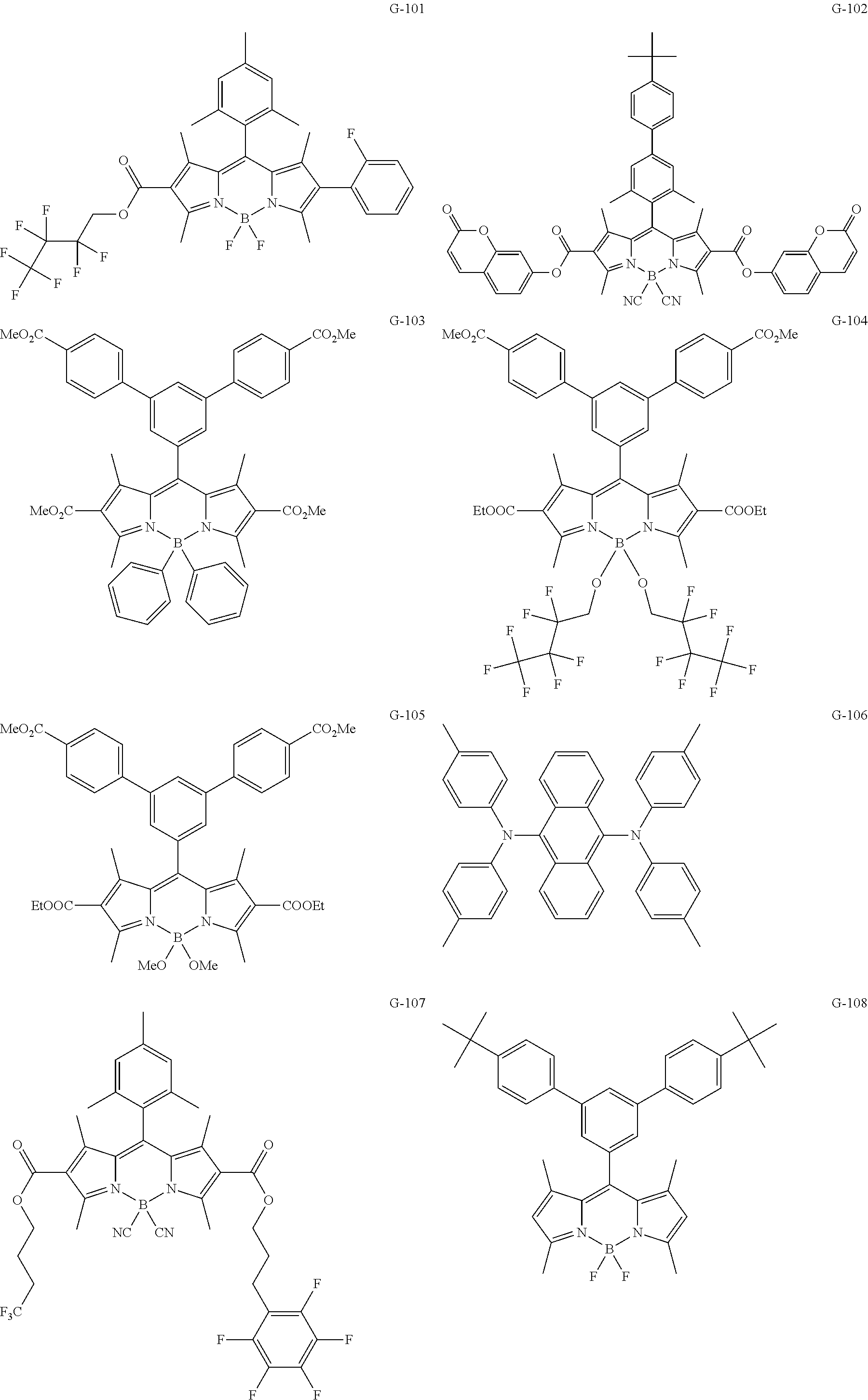

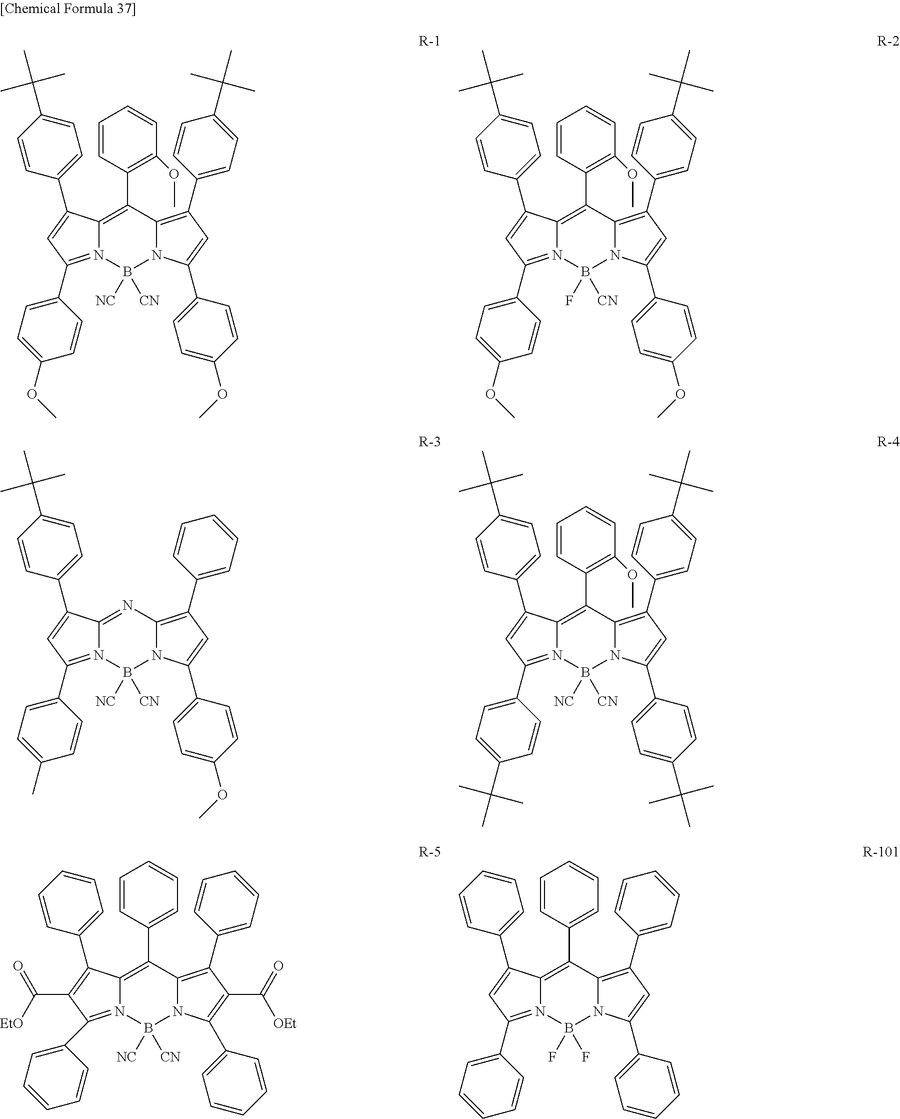

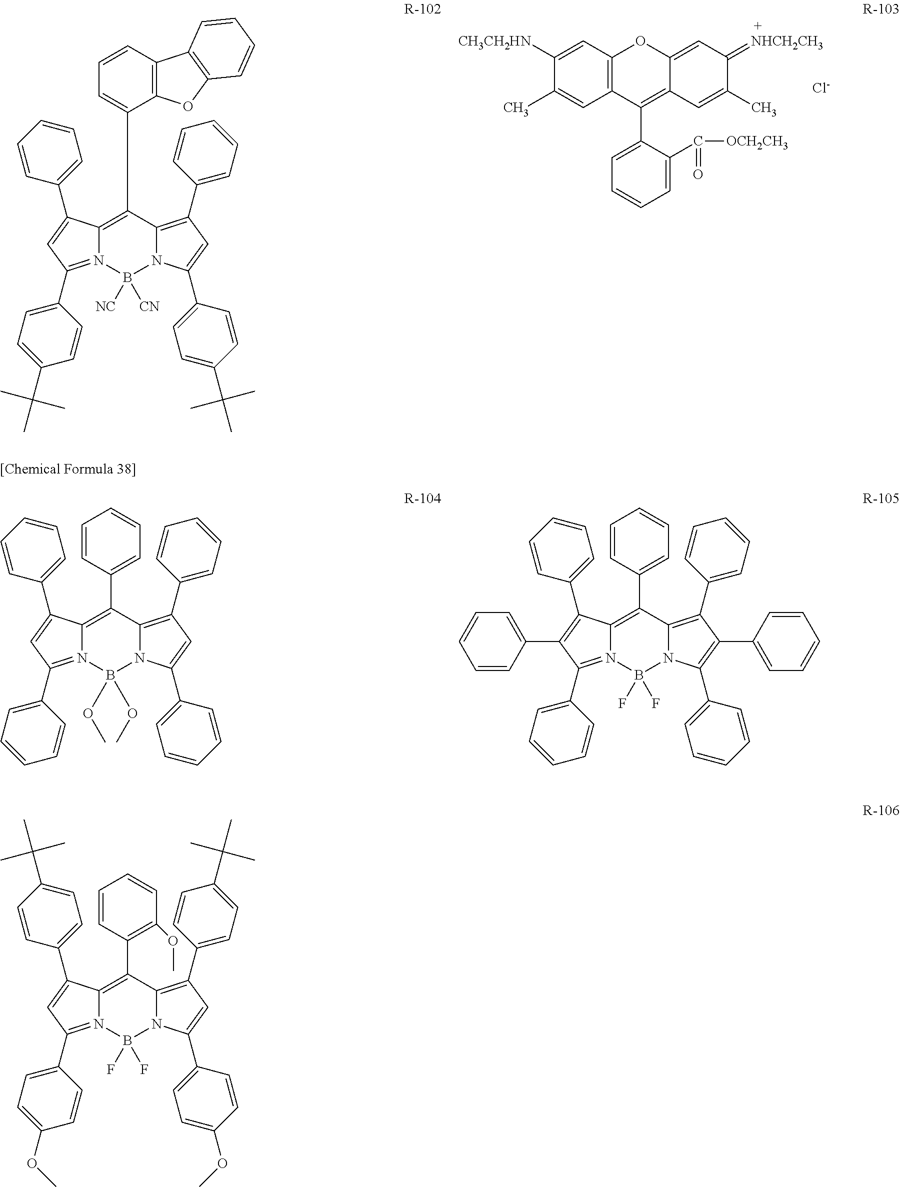

Furthermore, evaluation methods regarding the structural analysis in Examples and Comparative Examples are described below.

[symbol] Measurement of ¹H-NMR

[symbol]

¹H-NMR of the compound was measured in a deuterated chloroform solution using superconductive FTNMR EX-270 (manufactured by JEOL Ltd.).

[symbol] Measurement of Fluorescent Spectrum

[symbol]

A fluorescent spectrum of the compound was measured with spectrofluorophotometer F-2500 (manufactured by Hitachi, Ltd.). The compound was dissolved into toluene with a concentration of 1×10⁻⁶ mol/L and was excited at 460 nm wavelength, and a fluorescent spectrum was measured.

[symbol] Measurement of Emission Quantum Yield

[symbol]

The emission quantum yield of the compound was measured with absolute PL quantum yield spectrometer (Quantaurus-QY manufactured by Hamamatsu Photonics K.K.). The compound was dissolved into toluene with a concentration of 1×10⁻⁶ mol/L and was excited at 460 nm wavelength, and the emission quantum yield was measured.

### Synthetic Example 1

The method in which Compound G-18 was synthesized in Synthetic Example 1 of the present invention will be described below. In the method for synthesizing Compound G-18, 3,5-dibromobenzaldehyde (3.0 g), 4-methoxycarbonylphenylboronic acid (5.3 g), tetrakis(triphenylphosphine)palladium (0) (0.4 g) and potassium carbonate (2.0 g) were added into a flask, which was then purged with nitrogen. There were added degassed toluene (30 mL) and degassed water (10 mL), and the mixture was refluxed for 4 hours. Thereafter, the reaction solution was cooled to room temperature, and the organic layer was collected by liquid separation and was washed with a saturated saline solution. This organic layer was dried over magnesium sulfate and was filtered, and the solvent was distilled off. The reaction product thus obtained was purified by silica gel chromatography to give 3,5-bis(4-methoxycarbonylphenyl)benzaldehyde (3.5 g) as a white solid.

Next, 3,5-bis(4-methoxycarbonylphenyl)benzaldehyde (1.5 g) and 2,4-dimethylpyrrole (0.7 g) were added to the above reaction solution, and dehydrated dichloromethane (200 mL) and trifluoroacetic acid (1 drop) were added. The mixture was stirred in a nitrogen atmosphere for 4 hours. A solution of 2,3-dichloro-5,6-dicyano-1,4-benzoquinone (0.85 g) in dehydrated dichloromethane was added thereto, and the mixture was further stirred for 1 hour. After the completion of the reaction, boron trifluoride diethyl ether complex (7.0 mL) and diisopropylethylamine (7.0 mL) were added, and the mixture was stirred for 4 hours. Furthermore, water (100 mL) was added, followed by stirring, and the organic layer was collected by liquid separation. The organic layer was dried over magnesium sulfate and was filtered, and the solvent was distilled off. The reaction product thus obtained was purified by silica gel chromatography to give boron fluoride complex (0.4 g).

Next, the boron fluoride complex (0.4 g) obtained was added to a flask, and dichloromethane (5 mL), trimethylsilyl cyanide (0.67 mL) and boron trifluoride diethyl ether complex (0.20 mL) were added. The mixture was stirred for 18 hours. Thereafter, water (5 mL) was further added, and the mixture was stirred. The organic layer was collected by liquid separation. The organic layer was dried over magnesium sulfate and was filtered, and the solvent was distilled off. The reaction product thus obtained was purified by silica gel chromatography to give a compound (0.28 g). This compound obtained was analyzed by ¹H-NMR, the results being shown below, and was identified to be Compound G-18.

¹H-NMR (CDCl₃, ppm): 7.95 (s, 1H), 7.63-7.48 (m, 10H), 4.83 (q, 6H), 4.72 (t, 4H), 3.96 (s, 6H), 2.58 (s, 6H), 1.50 (s, 6H)

### Synthetic Example 2

The method in which Compound R-1 was synthesized in Synthetic Example 2 of the present invention will be described below. In the method for synthesizing Compound R-1, a mixture solution of 4-(4-t-butylphenyl)-2-(4-methoxyphenyl)pyrrole (300 mg), 2-methoxybenzoyl chloride (201 mg) and toluene (10 ml) was heated at 120° C. for 6 hours under a stream of nitrogen. The mixture solution after the heat treatment was cooled to room temperature and was thereafter evaporated. Thereafter, the residue was washed with ethanol (20 mL) and was vacuum dried to give 2-(2-methoxybenzoyl)-3-(4-t-butylphenyl)-5-(4-methoxyphenyl)pyrrole (260 mg).

Next, a mixture solution of 2-(2-methoxybenzoyl)-3-(4-t-butylphenyl)-5-(4-methoxyphenyl)pyrrole (260 mg) obtained above, 4-(4-t-butylphenyl)-2-(4-methoxyphenyl)pyrrole (180 mg), methanesulfonic anhydride (206 mg) and degassed toluene (10 mL) was heated at 125° C. for 7 hours under a stream of nitrogen. The mixture solution after the heat treatment was cooled to room temperature, water (20 mL) was poured to the mixture solution, and the organic layer was extracted with dichloromethane 30 ml. The organic layer obtained was washed twice with water (20 mL), evaporated and vacuum dried. Thus, a pyrromethene compound was obtained.

Next, a mixture solution of the pyrromethene compound obtained and toluene (10 mL) was stirred under a stream of nitrogen at room temperature for 3 hours together with diisopropylethylamine (305 mg) and boron trifluoride diethyl ether complex (670 mg). Thereafter, water (20 mL) was poured, and the organic layer was extracted with dichloromethane (30 mL). The organic layer obtained was washed twice with water (20 mL), dried over magnesium sulfate, and evaporated. The reaction product thus obtained was purified by silica gel column chromatography and was vacuum dried to give a boron fluoride complex as a reddish purple powder (0.27 g).

Next, the boron fluoride complex (0.27 g) obtained above was added to a flask, and dichloromethane (2.5 mL), trimethylsilyl cyanide (0.32 mL) and boron trifluoride diethyl ether complex (0.097 mL) were added. The mixture was stirred for 18 hours. Thereafter, water (2.5 mL) was further added and the mixture was stirred. The organic layer was collected by liquid separation. The organic layer was dried over magnesium sulfate and was filtered, and the solvent was distilled off. The reaction product thus obtained was purified by silica gel chromatography to give a compound (0.19 g). The compound obtained was analyzed by ¹H-NMR, the results being shown below, and was identified to be Compound R-1.

¹H-NMR (CDCl₃, ppm): 1.19 (s, 18H), 3.42 (s, 3H), 3.85 (s, 6H), 5.72 (d, 1H), 6.20 (t, 1H), 6.42-6.97 (m, 16H), 7.89 (d, 4H)

In Examples and Comparative Examples below, a backlight unit included a color conversion film, a blue LED device (emission peak wavelength: 445 nm) and a light guide plate. The color conversion film was stacked on one side of the light guide plate, and a prism sheet was stacked on the color conversion film. A current was then passed to illuminate the blue LED device, and the initial emission characteristics were measured with a spectroradiometer (CS-1000 manufactured by Konica Minolta, Inc.). Incidentally, the color conversion film was not inserted at the time of the measurement of the initial emission characteristics, and the initial value was set so that the brightness of light from the blue LED device was 800 cd/m². Thereafter, the blue LED device was illuminated continuously at room temperature, and the light durability was evaluated by measuring the time to a 5% drop in luminance.

### Example 1

Example 1 in the present invention is an example in which a pyrromethene boron complex according to the embodiment 1A described hereinabove was used as a light-emitting material (a color conversion material). In Example 1, an acrylic resin was used as a binder resin, and 100 parts by weight of the acrylic resin was mixed together with 0.25 parts by weight of Compound G-1 as a light-emitting material and 400 parts by weight of toluene as a solvent. Thereafter, the mixture was stirred and defoamed with planetary stirring defoamer “MAZERUSTAR KK-400” (manufactured by KURABO INDUSTRIES LTD.) at 300 rpm for 20 minutes. Thus, a color conversion composition was obtained.

Similarly, a polyester resin was used as a binder resin, and 100 parts by weight of the polyester resin was mixed together with 300 parts by weight of toluene as a solvent. Thereafter, the solution was stirred and defoamed with planetary stirring defoamer “MAZERUSTAR KK-400” (manufactured by KURABO INDUSTRIES LTD.) at 300 rpm for 20 minutes. Thus, an adhesive composition was obtained.

Next, the color conversion composition obtained above was applied onto “LUMIRROR” U48 (manufactured by TORAY INDUSTRIES, INC., thickness 50 μm) as a first substrate layer with use of a slit die coater, and was dried by being heated at 100° C. for 20 minutes. Thus, a layer (A) having an average film thickness of 16 μm was formed.

Similarly, the adhesive composition obtained above was applied onto the PET substrate layer side of light diffusion film “Chemical Matte” 125PW (manufactured by KIMOTO Co., Ltd., thickness 138 μm) as a second substrate layer with use of a slit die coater, and was dried by being heated at 100° C. for 20 minutes. Thus, a layer (B) having an average film thickness of 48 μm was formed.

Next, these two layers (A) and (B) were hot laminated in such a manner that the color conversion layer of the layer (A) and the adhesive layer of the layer (B) were in direct contact with each other. Thus, a color conversion film was fabricated which had a stack structure “first substrate layer/color conversion layer/adhesive layer/second substrate layer/light diffusion layer”.

Light from a blue LED device (blue light) was converted through this color conversion film, and a green emission region alone was extracted. The green emission obtained was of high color purity with a peak wavelength of 526 nm and a full width at half maximum of 27 nm in the emission spectrum at the peak wavelength. The emission intensity at the peak wavelength is a value relative to the quantum yield in Comparative Example 1 described later taken as 1.00. The quantum yield in Example 1 was 1.07.

Furthermore, the blue LED device was illuminated continuously at room temperature, and the time to a 5% drop in luminance was 200 hours. The light-emitting material and the evaluation results in Example 1 are described in Table 2-1 later.

### Examples 2 to 38 and Comparative Examples 1 to 8

In Examples 2 to 38 of the present invention and Comparative Examples 1 to 8 in comparison with the present invention, color conversion films were fabricated and evaluated in the same manner as in Example 1, except that the compounds described in Tables 2-1 to 2-3 later (Compounds G-2 to G-38, and G-101 to G-108) were used appropriately as the light-emitting materials. The light-emitting materials and the evaluation results in Examples 2 to 38 and Comparative Examples 1 to 8 are described in Tables 2-1 to 2-3. Incidentally, the quantum yields (relative values) in the tables are quantum yields at the peak wavelength and, similarly to Example 1, are values relative to the intensity in Comparative Example 1 taken as 1.00.

TABLE 2-1

| | | | Full | | |
|---|---|---|---|---|---|
| | | Peak | width | Quantum | |
| | Light- | wave- | at half | yield | Light |
| | emitting | length | maximum | (relative | durability |
| | material | (nm) | (nm) | value) | (h) |
| Ex. 1 | G-1 | 526 | 27 | 1.07 | 200 |
| Ex. 2 | G-2 | 527 | 28 | 1.09 | 330 |
| Ex. 3 | G-3 | 525 | 27 | 1.25 | 340 |
| Ex. 4 | G-4 | 529 | 28 | 1.09 | 350 |
| Ex. 5 | G-5 | 528 | 28 | 1.11 | 380 |
| Ex. 6 | G-6 | 542 | 29 | 1.01 | 470 |
| Ex. 7 | G-7 | 527 | 28 | 1.11 | 590 |
| Ex. 8 | G-8 | 527 | 28 | 1.10 | 700 |
| Ex. 9 | G-9 | 527 | 28 | 1.12 | 800 |
| Ex. 10 | G-10 | 528 | 28 | 1.14 | 800 |
| Ex. 11 | G-11 | 527 | 28 | 1.14 | 840 |
| Ex. 12 | G-12 | 529 | 27 | 1.14 | 840 |
| Ex. 13 | G-13 | 528 | 28 | 1.20 | 840 |
| Ex. 14 | G-14 | 527 | 27 | 1.15 | 830 |
| Ex. 15 | G-15 | 527 | 26 | 1.01 | 840 |
| Ex. 16 | G-16 | 529 | 28 | 1.15 | 860 |
| Ex. 17 | G-17 | 528 | 28 | 1.14 | 870 |
| Ex. 18 | G-18 | 527 | 27 | 1.30 | 1000 |
| Ex. 19 | G-19 | 527 | 28 | 1.35 | 1060 |
| Ex. 20 | G-20 | 529 | 28 | 1.32 | 1080 |
| Ex. 21 | G-21 | 530 | 27 | 1.33 | 1100 |

TABLE 2-2

| | | Peak | Full width | Quantum | |
|---|---|---|---|---|---|
| | Light- | wave- | at half | yield | Light |
| | emitting | length | maximum | (relative | durability |
| | material | (nm) | (nm) | value) | (h) |
| Ex. 22 | G-22 | 535 | 27 | 1.26 | 1300 |
| Ex. 23 | G-23 | 535 | 28 | 1.37 | 1420 |
| Ex. 24 | G-24 | 527 | 27 | 1.35 | 1380 |
| Ex. 25 | G-25 | 528 | 29 | 1.33 | 1620 |
| Ex. 26 | G-26 | 528 | 28 | 1.37 | 1650 |
| Ex. 27 | G-27 | 528 | 28 | 1.45 | 1670 |
| Ex. 28 | G-28 | 532 | 29 | 1.33 | 1720 |
| Ex. 29 | G-29 | 532 | 30 | 1.44 | 1780 |
| Ex. 30 | G-30 | 535 | 31 | 1.55 | 1830 |
| Ex. 31 | G-31 | 527 | 27 | 1.44 | 1940 |
| Ex. 32 | G-32 | 527 | 28 | 1.55 | 2100 |
| Ex. 33 | G-33 | 529 | 28 | 1.52 | 2250 |
| Ex. 34 | G-34 | 527 | 29 | 1.48 | 2280 |
| Ex. 35 | G-35 | 528 | 27 | 1.37 | 1570 |
| Ex. 36 | G-36 | 529 | 27 | 1.38 | 1560 |
| Ex. 37 | G-37 | 526 | 29 | 1.42 | 1660 |
| Ex. 38 | G-38 | 527 | 28 | 1.50 | 2090 |

TABLE 2-3

| | | | Full | | |
|---|---|---|---|---|---|
| | | Peak | width | Quantum | |
| | Light- | wave- | at half | yield | Light |
| | emitting | length | maximum | (relative | durability |
| | material | (nm) | (nm) | value) | (h) |
| Comp. | G-101 | 535 | 40 | 1.00 | 100 |
| Ex. 1 | | | | | |
| Comp. | G-102 | 530 | 30 | 0.88 | 120 |
| Ex. 2 | | | | | |
| Comp. | G-103 | 527 | 31 | 0.79 | 80 |
| Ex. 3 | | | | | |
| Comp. | G-104 | 528 | 27 | 1.11 | 120 |
| Ex. 4 | | | | | |
| Comp. | G-105 | 528 | 26 | 1.09 | 70 |
| Ex. 5 | | | | | |
| Comp. | G-106 | 540 | 58 | 1.13 | 20 |
| Ex. 6 | | | | | |
| Comp. | G-107 | 528 | 28 | 0.81 | 140 |
| Ex. 7 | | | | | |
| Comp. | G-108 | 532 | 27 | 0.89 | 40 |
| Ex. 8 | | | | | |

### Example 39

Example 39 in the present invention is an example in which a pyrromethene boron complex according to the embodiment 1B described hereinabove was used as a light-emitting material (a color conversion material). In Example 39, an acrylic resin was used as a binder resin, and 100 parts by weight of the acrylic resin was mixed together with 0.08 parts by weight of Compound R-1 as a light-emitting material and 400 parts by weight of toluene as a solvent. Thereafter, the mixture was stirred and defoamed with planetary stirring defoamer “MAZERUSTAR KK-400” (manufactured by KURABO INDUSTRIES LTD.) at 300 rpm for 20 minutes. Thus, a color conversion composition was obtained.

Similarly, a polyester resin was used as a binder resin, and 100 parts by weight of the polyester resin was mixed together with 300 parts by weight of toluene as a solvent. Thereafter, the solution was stirred and defoamed with planetary stirring defoamer “MAZERUSTAR KK-400” (manufactured by KURABO INDUSTRIES LTD.) at 300 rpm for 20 minutes. Thus, an adhesive composition was obtained.

Next, the color conversion composition obtained above was applied onto “LUMIRROR” U48 (manufactured by TORAY INDUSTRIES, INC., thickness 50 μm) as a first substrate layer with use of a slit die coater, and was dried by being heated at 100° C. for 20 minutes. Thus, a layer (A) having an average film thickness of 16 μm was formed.

Similarly, the adhesive composition obtained above was applied onto the PET substrate layer side of light diffusion film “Chemical Matte” 125PW (manufactured by KIMOTO Co., Ltd., thickness 138 μm) as a second substrate layer with use of a slit die coater, and was dried by being heated at 100° C. for 20 minutes. Thus, a layer (B) having an average film thickness of 48 μm was formed.

Next, these two layers (A) and (B) were hot laminated in such a manner that the color conversion layer of the layer (A) and the adhesive layer of the layer (B) were in direct contact with each other. Thus, a color conversion film was fabricated which had a stack structure “first substrate layer/color conversion layer/adhesive layer/second substrate layer/light diffusion layer”.

Light from a green LED device (green light) was converted through this color conversion film, and a red emission region alone was extracted. The red emission obtained was of high color purity with a peak wavelength of 630 nm and a full width at half maximum of 47 nm in the emission spectrum at the peak wavelength. The quantum yield at the peak wavelength is a value relative to the quantum yield in Comparative Example 9 described later taken as 1.00. The quantum yield in Example 39 was 1.11. Furthermore, the blue LED device was illuminated continuously at room temperature, and the time to a 5% drop in luminance was 600 hours. The light-emitting material and the evaluation results in Example 39 are described in Table 3 later.

### Examples 40 to 43 and Comparative Examples 9 to 13

In Examples 40 to 43 of the present invention and Comparative Examples 9 to 13 in comparison with the present invention, color conversion films were fabricated and evaluated in the same manner as in Example 39, except that the compounds described in Table 3 (R-2 to R-5, and R-101 to R-105) were used appropriately as the light-emitting materials. The light-emitting materials and the evaluation results in Examples 40 to 43 and Comparative Examples 9 to 13 are described in Table 3. Incidentally, the quantum yields (relative values) in the table are quantum yields at the peak wavelength and, similarly to Example 39, are values relative to the intensity in Comparative Example 9 taken as 1.00.

TABLE 3

| | | | Full | | |
|---|---|---|---|---|---|
| | | Peak | width | Quantum | |
| | Light- | wave- | at half | yield | Light |
| | emitting | length | maximum | (relative | durability |
| | material | (nm) | (nm) | value) | (h) |
| Ex. 39 | R-1 | 630 | 47 | 1.11 | 600 |
| Ex. 40 | R-2 | 632 | 46 | 1.10 | 570 |
| Ex. 41 | R-3 | 650 | 57 | 1.11 | 580 |
| Ex. 42 | R-4 | 642 | 53 | 1.09 | 590 |
| Ex. 43 | R-5 | 630 | 47 | 1.08 | 620 |
| Comp. | R-101 | 631 | 47 | 1.00 | 300 |
| Ex. 9 | | | | | |
| Comp. | R-102 | 640 | 56 | 0.57 | 450 |
| Ex. 10 | | | | | |
| Comp. | R-103 | 605 | 90 | 0.48 | 200 |
| Ex. 11 | | | | | |
| Comp. | R-104 | 633 | 47 | 0.87 | 270 |
| Ex. 12 | | | | | |
| Comp. | R-105 | 661 | 59 | 0.81 | 310 |
| Ex. 13 | | | | | |

### Example 44

In Example 44 of the present invention, a glass substrate having a 165 nm ITO transparent conductive film deposited thereon (manufactured by GEOMATEC Co., Ltd., 11Ω/□, sputtered product) was cut into 38×46 mm and was etched. The substrate thus obtained was ultrasonically washed with “Semico Clean 56” (product name, manufactured by Furuuchi Chemical Corporation) for 15 minutes and was washed with ultrapure water. Immediately before the fabrication of a light-emitting device, the substrate was treated with UV-ozone for 1 hour and was placed in a vacuum deposition apparatus. The apparatus was then evacuated to a degree of vacuum of not more than 5×10⁻⁴ Pa.

By a resistance heating method, first, Compound HAT-CN6 was deposited to form a hole injection layer with a thickness of 5 nm, and Compound HT-1 was deposited to form a hole transport layer with a thickness of 50 nm. Next, materials for forming an emission layer, namely, Compound H-1 as a host material and Compound G-3 (a compound represented by the general formula (1)) as a dopant material were deposited with a thickness of 20 nm so that the dopant concentration would be 1 wt %. Furthermore, Compound ET-1 was used as an electron transport layer, and Compound 2E-1 was used as a donor material, and Compound ET-1 and Compound 2E-1 were stacked with a thickness of 35 nm in such a manner that the ratio of their deposition rates would be 1:1. Next, Compound 2E-1 was deposited to form an electron injection layer with a thickness of 0.5 nm, and thereafter magnesium and silver were co-deposited with a thickness of 1000 nm to form a cathode. Thus, a 5×5 mm square light-emitting device was fabricated.

The characteristics of the light-emitting device at 1000 cd/m² showed an emission peak wavelength of 519 nm, a full width at half maximum of 27 nm, and an external quantum efficiency of 5.0%. Furthermore, the initial luminance was set at 4000 cd/m² and the light-emitting device was driven at a constant current. The time to a 20% drop in luminance was 500 hours. The materials and the evaluation results in Example 44 are described in Table 4 later. Incidentally, Compounds HAT-CN6, HT-1, H-1, ET-1 and 2E-1 are the compounds illustrated below.

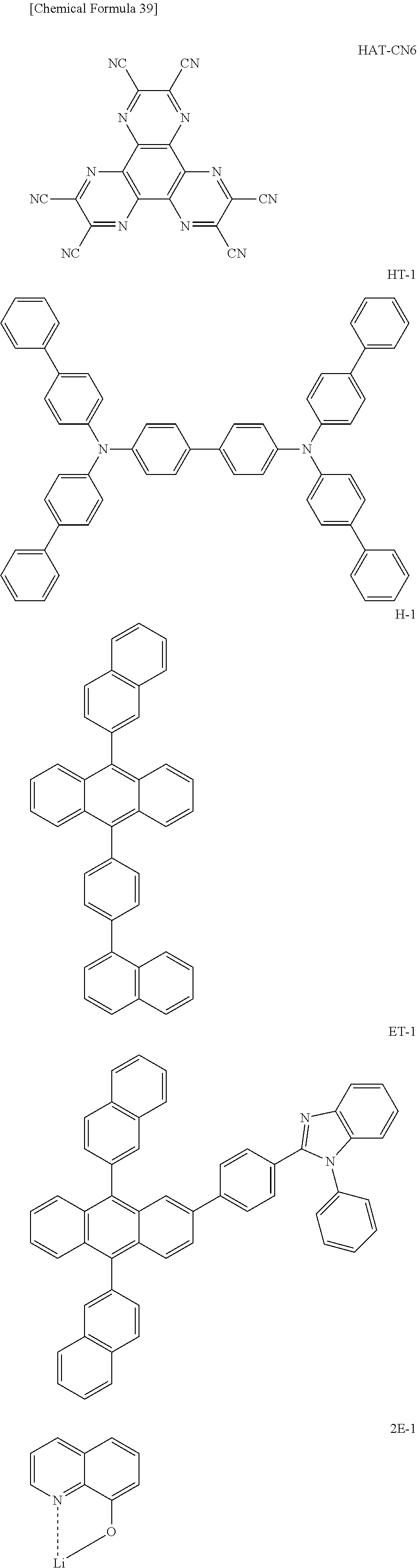

### Comparative Examples 14 and 15

In Comparative Examples 14 and 15 in comparison with the present invention, light-emitting devices were fabricated and evaluated in the same manner as in Example 44, except that the compounds described in Table 4 (Compounds G-106 and G-108) were used as the dopant materials. The materials and the evaluation results in Comparative Examples 14 and 15 are described in Table 4.

### Example 45

In Example 45 of the present invention, a glass substrate having a 165 nm ITO transparent conductive film deposited thereon (manufactured by GEOMATEC Co., Ltd., 11Ω/□, sputtered product) was cut into 38×46 mm and was etched. The substrate thus obtained was ultrasonically washed with “Semico Clean 56” (product name, manufactured by Furuuchi Chemical Corporation) for 15 minutes and was washed with ultrapure water. Immediately before the fabrication of a light-emitting device, the substrate was treated with UV-ozone for 1 hour and was placed in a vacuum deposition apparatus. The apparatus was then evacuated to a degree of vacuum of not more than 5×10⁻⁴ Pa.

By a resistance heating method, first, Compound HAT-CN6 was deposited to form a hole injection layer with a thickness of 5 nm, and Compound HT-1 was deposited to form a hole transport layer with a thickness of 50 nm. Next, materials for forming an emission layer, namely, Compound H-2 as a host material and Compound R-1 (a compound represented by the general formula (1)) as a dopant material were deposited with a thickness of 20 nm so that the dopant concentration would be 1 wt %. Furthermore, Compound ET-1 was used as an electron transport layer, and Compound 2E-1 was used as a donor material, and Compound ET-1 and Compound 2E-1 were stacked with a thickness of 35 nm in such a manner that the ratio of their deposition rates would be 1:1. Next, Compound 2E-1 was deposited to form an electron injection layer with a thickness of 0.5 nm, and thereafter magnesium and silver were co-deposited with a thickness of 1000 nm to form a cathode. Thus, a 5×5 mm square light-emitting device was fabricated.

The characteristics of the light-emitting device at 1000 cd/m² showed an emission peak wavelength of 625 nm, a full width at half maximum of 46 nm, and an external quantum efficiency of 5.1%. Furthermore, the initial luminance was set at 1000 cd/m² and the light-emitting device was driven at a constant current. The time to a 20% drop in luminance was 5200 hours. The materials and the evaluation results in Example 45 are described in Table 4. Incidentally, Compound H-2 is the compound illustrated below.

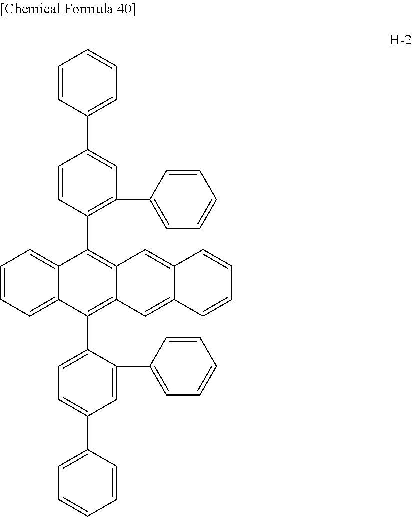 [SMILES: c1ccc(-c2ccc(-c3c4ccccc4c(-c4ccc(-c5ccccc5)cc4-c4ccccc4)c4cc5ccccc5cc34)c(-c3ccccc3)c2)cc1]

### Comparative Example 16

In Comparative Example 16 in comparison with the present invention, a light-emitting device was fabricated and evaluated in the same manner as in Example 45, except that the compound described in Table 4 (Compound R-106) was used as the dopant material. The materials and the evaluation results in Comparative Example 16 are described in Table 4.

TABLE 4

| | | | | Emission | Full | | |
|---|---|---|---|---|---|---|---|
| | Emission layer | | | peak | width at half | External | Light |
| | Host | Dopant | Emission | wavelength | maximum | quantum | durability |
| | material | material | color | (nm) | (nm) | efficiency (%) | (h) |
| Ex. 44 | H-1 | G-3 | Green | 519 | 27 | 5.0 | 500 |
| Comp. | H-1 | G-106 | Green | 550 | 69 | 1.7 | 160 |
| Ex. 14 | | | | | | | |
| Comp. | H-1 | G-108 | Green | 519 | 27 | 2.1 | 180 |
| Ex. 15 | | | | | | | |
| Ex. 45 | H-2 | R-1 | Red | 625 | 46 | 5.1 | 520 |
| Comp. | H-2 | R-106 | Red | 625 | 46 | 1.8 | 170 |
| Ex. 16 | | | | | | | |

### INDUSTRIAL APPLICABILITY

As described hereinabove, the pyrromethene boron complexes, the color conversion compositions, the color conversion films, the light source units, the displays, the illumination apparatuses and the light-emitting devices according to the present invention are suited for concurrent satisfaction of enhanced color reproducibility and high durability.

### REFERENCE SIGNS LIST

1A, 1B, 1C, 1D COLOR CONVERSION FILMS
10 SUBSTRATE LAYER
11 COLOR CONVERSION LAYER
12 BARRIER FILM

1. A pyrromethene boron complex comprising a compound represented by the general formula (1) below,
the pyrromethene boron complex satisfying at least one of condition (A) and condition (B) described below:
Condition (A): in the general formula (1), R¹ to R⁶ are each a group containing no fluorine atom, at least one of R¹, R³, R⁴, and R⁶ is a substituted or unsubstituted alkyl group or a substituted or unsubstituted cycloalkyl group, and R² and R⁵ are each a group including no fused bicyclic or polycyclic heteroaryl group;
Condition (B): in the general formula (1), at least one of R¹, R³, R⁴, and R⁶ is a substituted or unsubstituted aryl group or a substituted or unsubstituted heteroaryl group, and when X is C—R⁷, R⁷ is a group including no bicyclic or polycyclic heteroaryl group, 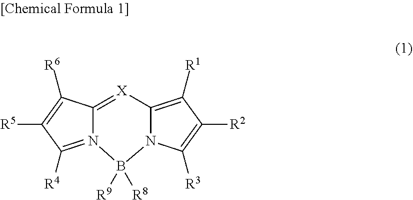
where in the general formula (1), X is C—R⁷ or N; and R¹ to R⁹ are the same as or different from one another and are each selected from the candidate group consisting of hydrogen atom, alkyl group, cycloalkyl group, heterocyclic group, alkenyl group, cycloalkenyl group, alkynyl group, hydroxy group, thiol group, alkoxy group, alkylthio group, aryl ether group, aryl thioether group, aryl group, heteroaryl group, halogen, cyano group, aldehyde group, carbonyl group, carboxy group, acyl group, ester group, amide group, carbamoyl group, amino group, nitro group, silyl group, siloxanyl group, boryl group, sulfo group, sulfonyl group, phosphine oxide group, and fused ring and aliphatic ring formed with an adjacent substituent; with the proviso that at least one of R⁸ and R⁹ is a cyano group, and R² and R⁵ are each a group selected from the groups belonging to the above-described candidate group excluding substituted or unsubstituted aryl groups and substituted or unsubstituted heteroaryl groups.

2. The pyrromethene boron complex according to claim 1, wherein in the general formula (1), the condition (A) is satisfied, and at least one of R¹ to R⁷ is an electron withdrawing group.

3. The pyrromethene boron complex according to claim 1,
wherein in the general formula (1), the condition (A) is satisfied, and at least one of R¹ to R⁶ is an electron withdrawing group.

4. The pyrromethene boron complex according to claim 1, wherein in the general formula (1), the condition (A) is satisfied, and at least one of R² and R⁵ is an electron withdrawing group.

5. The pyrromethene boron complex according to claim 1, wherein in the general formula (1), the condition (A) is satisfied, and R² and R⁵ are each an electron withdrawing group.

6. The pyrromethene boron complex according to claim 2, wherein the electron withdrawing group is a substituted or unsubstituted acyl group, a substituted or unsubstituted ester group, a substituted or unsubstituted amide group, a substituted or unsubstituted sulfonyl group, or a cyano group.

7. The pyrromethene boron complex according to claim 1, wherein in the general formula (1), the condition (B) is satisfied, and R⁷ is a substituted or unsubstituted aryl group.

8. The pyrromethene boron complex according to claim 1, wherein the compound represented by the general formula (1) is a compound represented by the general formula (2) below: 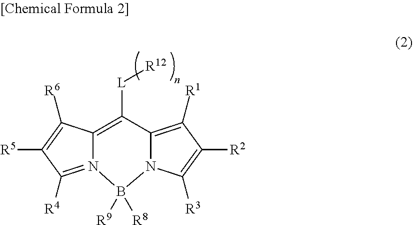
where in the general formula (2), R¹ to R⁶, R⁸, and R⁹ are the same as described in the general formula (1); R¹² is a substituted or unsubstituted aryl group, or a substituted or unsubstituted heteroaryl group; L is a substituted or unsubstituted arylene group, or a substituted or unsubstituted heteroarylene group; and n is an integer of 1 to 5.

9. The pyrromethene boron complex according to claim 1, wherein in the general formula (1), R⁸ and R⁹ are each a cyano group.

10. The pyrromethene boron complex according to claim 1, wherein in the general formula (1), R² and R⁵ are each a hydrogen atom.

11. The pyrromethene boron complex according to claim 1, wherein the compound represented by the general formula (1), when excited by excitation light, shows emission having a peak wavelength observed in a region of not less than 500 nm and not more than 580 nm.

12. The pyrromethene boron complex according to claim 1, wherein the compound represented by the general formula (1), when excited by excitation light, shows emission having a peak wavelength observed in a region of not less than 580 nm and not more than 750 nm.

13. A color conversion composition that converts incident light to light having a longer wavelength than the incident light, the color conversion composition comprising:
the pyrromethene boron complex as claimed in claim 1; and
a binder resin.

14. A color conversion film comprising:
a layer comprising the color conversion composition as claimed in claim 13, or a cured product of the color conversion composition.

15. A light source unit comprising:
a light source, and
the color conversion film as claimed in claim 14.

16. A display or an illumination apparatus, comprising:
the color conversion film as claimed in claim 14.

17. (canceled)

18. A light-emitting device comprising an organic layer present between an anode and a cathode, and emitting light using electric energy, wherein
the organic layer comprises the pyrromethene boron complex as claimed in claim 1.

19. The light-emitting device according to claim 18, wherein
the organic layer comprises an emission layer, and
the emission layer comprises the pyrromethene boron complex.

20. The light-emitting device according to claim 19, wherein
the emission layer comprises a host material and a dopant material, and
the dopant material comprises the pyrromethene boron complex.

21. The light-emitting device according to claim 20, wherein the host material comprises an anthracene derivative or a naphthacene derivative.
